(19) United States
(12) Patent Application Publication
(10) Pub. No.: US 2025/0365838 A1
(43) Pub. Date: Nov. 27, 2025

(54) LOAD CONTROL SYSTEM FOR CONTROLLING INTENSITY LEVEL AND COLOR OF ONE OR MORE LIGHTING LOADS

(71) Applicant: Lutron Technology Company LLC, Coopersburg, PA (US)

(72) Inventors: Gregory S. Altonen, Easton, PA (US); Jason C. Killo, Emmaus, PA (US); Matthew P. McDonald, Phoenixville, PA (US); Daniel L. Twaddell, Bethlehem, PA (US)

(73) Assignee: Lutron Technology Company LLC, Coopersburg, PA (US)

(21) Appl. No.: 19/217,523

(22) Filed: May 23, 2025

Related U.S. Application Data
(60) Provisional application No. 63/651,660, filed on May 24, 2024.

(51) Int. Cl. H05B 47/175; H05B 45/10; H05B 45/20

(52) U.S. Cl. CPC H05B 47/175; H05B 45/10; H05B 45/20

(57) ABSTRACT

A remote control device for use in a load control system including one or more load control devices for controlling one or more lighting loads may comprise a touch sensitive surface configured to received touch actuations by a user, a rotatable member having a circular shape and surrounding the touch sensitive surface and configured to be rotated by the user, and a control circuit responsive to the touch actuations of the touch sensitive surface and rotations of the rotatable member. When operating in an intensity-adjustment mode, the control circuit may be configured to generate first control data for adjusting a present intensity level of the lighting loads in response to rotations of the rotatable member. When operating in a color-temperature-adjustment mode, the control circuit may be configured to generate second control data for adjusting a present color temperature of the lighting loads in response to rotations of the rotatable member.

### CROSS-REFERENCE TO RELATED APPLICATIONS

This application claims priority from Provisional U.S. Patent Application No. 63/651,660, filed May 24, 2024, the entire disclosure of which is hereby incorporated by reference herein in its entirety.

### BACKGROUND

During the installation of typical load control systems, standard mechanical switches, such as traditional toggle switches or decorator paddle switches, may be replaced by more advanced load control devices, such as dimmer switches, that control the amount of power delivered from an alternating current (AC) power source to one or more electrical loads. Such an installation procedure typically requires that the existing mechanical switch be disconnected from the electrical wiring and removed from a wallbox in which it is mounted, and that the load control device then be connected to the electrical wiring and installed in the wallbox. An average consumer may not feel comfortable performing the electrical wiring required in such an installation. Accordingly, such a procedure may typically be performed by an electrical contractor or other skilled installer. However, hiring an electrical contractor may be cost prohibitive to the average consumer.

Controllable light sources, such as controllable screw-in light-emitting diode (LED) lamps, may provide an easier solution for providing advanced control of lighting. For example, an older incandescent lamp may simply be unscrewed from a socket and the controllable light source may be screwed into the socket. The controllable light sources may be controlled by remote control devices. However, the sockets in which the controllable light sources are installed may be controlled by an existing wall-mounted light switch. When the wall-mounted light switch is operated to an off position, power to the controllable light source may be cut, such that the controllable light source may no longer respond to commands transmitted by the remote control devices. Accordingly, it is desirable to prevent operation of such a wall-mounted light switch to ensure that the delivery of power to the controllable light source continues uninterrupted.

### SUMMARY

Described herein are systems, methods, and non-transitory computer-readable storage mediums that include instructions for performing the methods described herein. The system may be a load control system that includes any combination of a remote control device, one or more load control devices, and one or more lighting loads.

As described herein, a remote control device for use in a load control system including one or more load control devices for controlling one or more respective lighting loads may comprise a touch sensitive surface configured to received touch actuations by a user, a rotatable member having a circular shape and surrounding the touch sensitive surface and configured to be rotated by the user, and a control circuit responsive to the touch actuations of the touch sensitive surface and rotations of the rotatable member. The control circuit may operate in one of a plurality of adjustment modes in response to a touch actuation of the touch sensitive surface, where the plurality of adjustment modes comprises an intensity-adjustment mode and a color-temperature-adjustment mode. When operating in the intensity-adjustment mode, the control circuit may be configured to generate first control data (e.g., a first command) for adjusting a present intensity level of each of the one or more lighting loads in response to rotations of the rotatable member. When operating in the color-temperature-adjustment mode, the control circuit may be configured to generate second control data (e.g., a second command) for adjusting a present color temperature of each of the one or more lighting loads in response to rotations of the rotatable member.

In addition, the plurality of adjustment modes may also comprise a full-color-adjustment mode. The control circuit may be configured to, when operating in the full color adjustment mode, generate third control data for adjusting a present color of each of the one or more lighting loads. One or more of the load control devices of the load control system may be configured to operate in one of a plurality of color control modes, where the color control modes comprise a color-temperature-control mode and a full-color-control mode. The control circuit may be configured to transmit a first command for adjusting the present intensity level of each of the one or more lighting loads in response to the generated first control data when operating in the intensity-adjustment mode, transmit a second command for adjusting the present color temperature of each of the one or more lighting loads in response to the generated second control data when operating in the color-temperature-adjustment mode, and transmit a third command for adjusting the present color of each of the one or more lighting loads in response to the generated third control data where operating in the full-color-adjustment mode.

In some examples, the control circuit is configured to press detect a press actuation of the touch sensitive surface. For example, the press actuation may comprise a press-and-hold actuation of the touch sensitive surface and/or an actuation of the touch sensitive surface that causes the touch sensitive surface to move. In response to detecting a press actuation of the touch sensitive surface to select the color temperature-adjustment mode, the control circuit may be configured to enter the color-temperature-adjustment mode and transmit the second command for adjusting the present color temperature of each of the one or more lighting loads independent of the color control mode of each of the load control devices that receives the second command. In response to detecting a press actuation of the touch sensitive surface to select the full-color-temperature-adjustment mode, the control circuit may be configured to enter the full-color-adjustment mode and transmit the third command for adjusting the present color temperature of each of the one or more lighting loads independent of the color control mode of each of the load control devices that receives the second command.

Further, the remote control device may further comprise a light bar extending around the touch sensitive surface between the touch sensitive surface and the rotatable member. The control circuit may configured to illuminate the light bar to indicate at least one of the present intensity level or the present color temperature of the one or more lighting loads. When in the color-temperature-adjustment mode, the control circuit is configured to generate the second control data for adjusting the present color temperature of each of the one or more lighting loads across a range from a warm-white color temperature to a cool-white color temperature, illuminate a segment of the light bar to indicate the present color temperature of the one or more lighting loads, and adjust a position of the segment around a circumference of the light bar based on the present color temperature within the range from the warm-white color temperature to the cool-white color temperature.

A load control device for controlling a lighting load is also described herein. The load control device may comprise a load control circuit configured to receive power from a power source and control an intensity level of the lighting load, a communication circuit configured to receive message, and a control circuit configured to control the load control circuit to adjust the intensity level of the lighting load between a low-end intensity level and a high-end intensity level. The control circuit may be configured to receive a message including a command for adjusting the intensity level of the lighting load. The control circuit may configured to determine a commanded intensity level from the received command, determine a controlled intensity level that is based on the commanded intensity level and is limited by the low-end intensity level and the high-end intensity level, and control the load control circuit to adjust the intensity level of the lighting load to the controlled intensity level.

Further, the control circuit may be configured to control a color temperature of the lighting load. The load control device may further comprise a memory configured to store at least one of a stored intensity level or a stored color temperature. The control circuit may be further configured to receive in a message including an undo command, and to control the load control circuit to adjust the at least one of the intensity level or the color temperature of the lighting load to the stored intensity level or a stored color temperature, respectively.

The load control device may be configured to operate in one of a plurality of color control modes, such as a color-temperature-control mode and a full-color-control mode. The load control device may be responsive to a received color temperature-adjustment command when the load control device is operating in the color temperature-control mode, and responsive to a received full color adjustment command when the respective load control device is presently operating in the full-color-control mode.

The control circuit may be configured to receive a first command for adjusting the intensity level of the lighting load, wherein the first command comprises first control data, and determine the commanded intensity level based on the first control data. The control circuit may be configured to receive a second command for adjusting the color temperature of the lighting load, wherein the second command comprises second control data; determine a commanded color temperature based on the second control data; and control the load control circuit to adjust the intensity level of the lighting load to the commanded color temperature. In some examples, the control circuit may be configured to receive the second command for adjusting the color temperature of each of the one or more lighting loads independent of the color control mode of the load control device.

The control circuit may be configured to receive a third command for adjusting the color of the lighting load, wherein the third command comprises third control data, determine a commanded color of the lighting load based on the third control data, and control the load control circuit to adjust the color of the lighting load to the commanded color. The control circuit may be configured to receive the third command for adjusting the color temperature of the lighting load independent of the color control mode of the load control device. In some instance, the third command may include an indication of that the load control device should change to the full-color-control mode. The control circuit may be configured to receive a fourth command that causes the lighting load to revert to a previous state.

### BRIEF DESCRIPTION OF THE DRAWINGS

FIG. 1 depicts an example load control system that includes one or more example remote control devices.

FIG. 2A is a perspective view of an example remote control device without icons illuminated on a user interface surface of the remote control device.

FIG. 2B is a side view of the remote control device of FIG. 2A.

FIG. 3 is a front view of the remote control device of FIG. 2A with icons illuminated on the user interface surface.

FIGS. 4A-4D are top views of the remote control device of FIG. 2A showing a light bar of the remote control device illuminated to indicate a present color temperature of one or more lighting loads that may be controlled in response to messages transmitted by the remote control device.

FIGS. 5A and 5B are plots illustrating present intensity levels with respect to time of first and second lighting loads controlled by first and second load control devices, respectively, in response to receiving intensity-adjustment commands.

FIGS. 6A-6E are exploded views of an example control device, such as the remote control device shown in FIG. 2A.

FIG. 7 is a side cross-section view of the control device shown in FIGS. 6A-6E (e.g., taken through the line shown in FIG. 2B).

FIG. 8 is a block diagram of an example control device, such as the remote control device shown in FIG. 2A.

FIG. 9 is a block diagram of an example load control device for controlling a lighting load.

FIG. 10 is a flowchart of an example procedure for receiving an input (e.g., a touch actuation) of a touch sensitive surface of a control device, such as the remote control device of FIG. 2.

FIG. 11 is a flowchart of an example procedure for receiving an input (e.g., a press actuation) from a touch sensitive surface of a control device, such as the remote control devices of FIG. 2.

FIG. 12 is a flowchart of an example procedure for receiving an input from rotatable member (e.g., a rotary knob) of a control device, such as the remote control device of FIG. 2A.

FIG. 13 is a flowchart of an example procedure for controlling a lighting load (e.g., an intensity level of the lighting load) by a load control device.

FIG. 14 is a flowchart of an example procedure for controlling a lighting load (e.g., a color temperature of the lighting load) by a load control device.

FIG. 15 is a flowchart of an example procedure for controlling a lighting load by a load control device (e.g., for providing full color control of the lighting load).

FIG. 16 is a flowchart of an example procedure for controlling a lighting load at a load control device to return the lighting load to a previous state.

### DETAILED DESCRIPTION

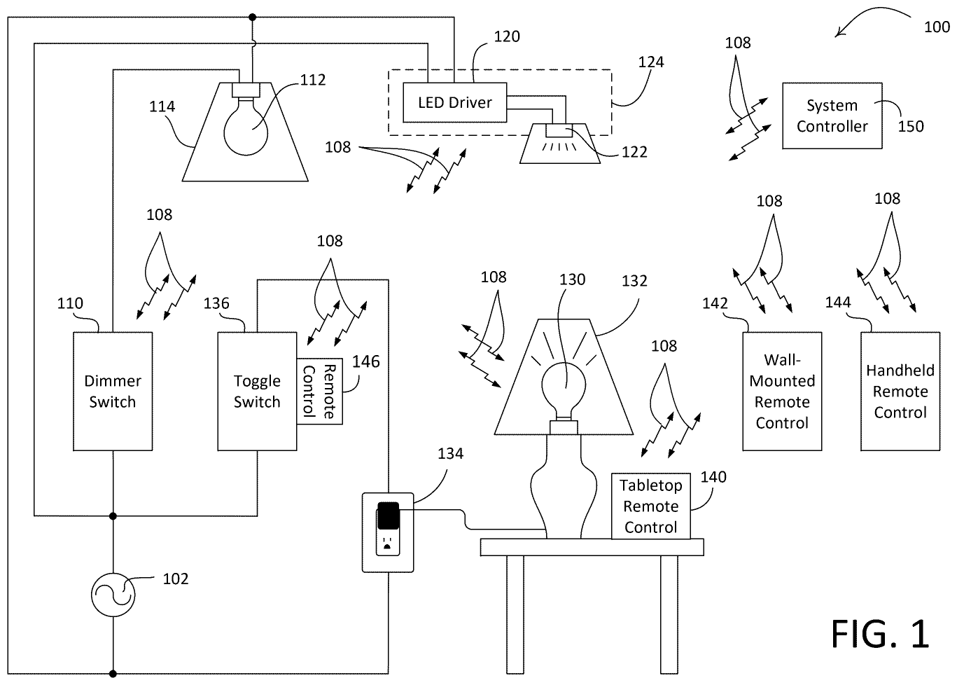

FIG. 1 is a simplified block diagram of an example load control system 100 (e.g., a lighting control system). The load control system 100 may comprise one or more load control devices (e.g., such as lighting control devices) for controlling one or more electrical loads (e.g., such as lighting loads). For example, the load control devices of the load control system 100 may comprise a wall-mounted load control device, such as a dimmer switch 110, which may be electrically coupled between a power source 102 and a light source, such a lighting load 112 (e.g., an external lighting load). The power source 102 may comprise, for example, an alternating-current (AC) power source (e.g., as shown in FIG. 1) and/or a direct-current (DC) power source. The lighting load 112 may comprise a dimmable light source (e.g., such as an incandescent lamp, a halogen lamp, and/or a dimmable light-emitting diode (LED) light source) installed in a lighting fixture 114, such as a ceiling-mounted downlight fixture. The dimmer switch 110 may be configured to control the lighting load 112 using a phase-control dimming technique (e.g., the lighting load 112 may be responsive to a phase-control signal generated by the dimmer switch 110). For example, the dimmer switch 110 may be configured to adjust an intensity level (e.g., a brightness) of the lighting load 112 using the phase-control dimming technique. The dimmer switch 110 may be configured to adjust the intensity level of the lighting load 112 between a low-end intensity level (e.g., a minimum intensity level) and a high-end intensity level (e.g., a maximum intensity level).

The lighting load 112 may be configured to adjust the intensity level of light emitted by the lighting load 112 in response to a firing angle of the phase-control signal received from the dimmer switch 110. In some examples, the lighting load 112 may be configured to also adjust a color (e.g., color temperature and/or full color) of the light emitted by the lighting load 112 in response to the phase-control signal according to a relationship between the color temperature and the intensity level set by the phase-control signal (e.g., according to a warm-dim curve). The dimmer switch 110 may comprise a user interface, including one or more buttons configured to be actuated by a user for controlling the lighting load 112. In addition, the dimmer switch 110 may be configured to receive messages (e.g., digital messages) via communication signals, such as wireless signals, e.g., radio-frequency (RF) signals 108. For example, the message may include commands for causing the dimmer switch 110 to control the lighting load 112. In some examples, in addition to generating the phase-control signal, the dimmer switch 110 may be configured to transmit messages including commands for controlling the lighting load 112 (e.g., and/or other lighting loads in the load control system 100). For example, the lighting load 112 may be configured to adjust the intensity level and/or the color (e.g., color temperature and/or full color) of the light emitted by the lighting load 112 in response to the commands received in the messages (e.g., from the dimmer switch 110) via the RF signals 108.

The load control devices of the load control system 100 may also comprise a remote load control device, such as an LED driver 120, for controlling a lighting load, such as LED light source 122 (e.g., an external lighting load). The LED driver 120 may be electrically coupled to the power source 102 for receiving power and may be configured to control the amount of power delivered to the LED light source 122 for controlling an intensity level and/or color (e.g., full color and/or color temperature) of the LED light source 122. For example, the integral LED light source may comprise one more LED circuits of different colors that may be mixed together to control a cumulative light emitted by the integral LED light source. The LED light source 122 may comprise, for example, an LED light engine that is external to a housing of the LED driver 120 and installed with the LED driver 120 in a lighting fixture 124, such as a ceiling-mounted downlight fixture. For example, the LED driver 120 may be a multi-channel LED driver having multiple channels (e.g., outputs) for controlling the differently-colored LED circuits of the LED light source 122. The LED driver 120 may be configured to control the magnitude of drive currents conducted through each of the LED circuits of the LED light source 122 to control the intensity level and/or color of the light emitted by the LED light source 122. The LED driver 120 may be configured to adjust the intensity level of the LED light source 122 between a low-end intensity level (e.g., a minimum intensity level) and a high-end intensity level (e.g., a maximum intensity level). The LED driver 120 may be configured to receive messages (e.g., digital messages) via the RF signals 108. For example, the message may include commands for causing the LED driver 120 to control the LED light source 122. The LED driver 120 may be configured to adjust the intensity level and/or the color (e.g., color temperature and/or full color) of the light emitted by the LED light source 122 in response to the commands received in the messages via the RF signals 108. In some examples, the LED driver 120 may be integrated into the LED light source 122, and the LED light source 122 may be responsive to the command received in the messages via the RF signals 108.

In addition, the load control devices of the load control system 100 may comprise a controllable light source 130 (e.g., such as a smart lamp or smart bulb). The controllable light source 130 may comprise an integral lighting load (e.g., an integral LED light source) included in the same housing as a load control circuit (e.g., an LED driver circuit) for controlling the integral LED light source. For example, the integral LED light source may comprise one more LED circuits of different colors that may be mixed together to control a cumulative light emitted by the integral LED light source. The controllable light source 130 may be installed into, for example, a table lamp 132 that may be plugged into an electrical outlet 134 (e.g., an electrical receptacle), which may receive power from the power source 102 for powering the controllable light source 130. For example, the electrical outlet 134 may be electrically coupled to the power source 102 via a toggle switch 136 (e.g., a mechanical switch). When the toggle switch 136 is on (e.g., is in a conductive state), the controllable light source 130 may receive power from the power source 102 (e.g., be powered). When the toggle switch 136 is off (e.g., is in a non-conductive state), the controllable light source 130 may be disconnected from the power source 102 (e.g., be unpowered). The load control circuit of the controllable light source 130 may be configured to control an intensity level (e.g., a brightness) and/or a color (e.g., color temperature and/or full color) of the cumulative light emitted by the integral lighting load. The controllable light source 130 may be configured to receive messages (e.g., digital messages) via the wireless signals, e.g., the RF signals 108. For example, the message may include commands for causing the controllable light source 130 to control the integral lighting load. The controllable light source 130 may be configured to adjust the intensity level and/or the color (e.g., color temperature and/or full color) of the light emitted by the integral LED light source in response to the commands received in the messages via the RF signals 108.

The lighting loads of the load control system 100 (e.g., the lighting load 112 controlled by the dimmer switch 110, the LED light source 122 controlled by the LED driver 120, and/or the LED light source of the controllable light source 130) may be capable of multiple means of control. For example, one or more of the lighting loads may be intensity-control capable when the lighting loads are capable of being controlled in response to intensity-adjustment commands. In addition, one or more of the lighting loads may be color-temperature-control capable when the lighting loads are capable of being controlled in response to color-temperature-adjustment commands. Further, one or more of the lighting loads may be full-color-control capable when the lighting loads are capable of being controlled in response to full-color-adjustment commands. For example, the lighting load 112 controlled by the dimmer switch 110 may be intensity-control capable (e.g., only intensity-control capable) when the lighting load 112 may be controlled via a phase-control signal (e.g., only via a phase-control signal). In addition, the LED light source 122 controlled by the LED driver 120 and the LED light source of the controllable light source 130 may be intensity-control capable as well as color-temperature-control capable and/or full-color-control capable. For example, some lighting loads may be color-temperature-control capable (e.g., only color-temperature-control capable) when the color of the light emitted by the lighting load may be controlled (e.g., only be controlled) to colors (e.g., white colors) along the black body curve. In addition, some lighting loads may be color-control capable when color of the light emitter by the lighting load may be controlled to multiple colors (e.g., as determined by an x-chromaticity coordinate and a y-chromaticity coordinate) within a gamut in the color space (e.g., not limited to white colors on the black body curve). Typically, those lighting loads that are full-color-control capable are also color-temperature-control capable. A load control device that is controlling a lighting load that is both color-temperature-control capable and full-color-control capable may operate (e.g., only operate) in one or the other of the color-temperature-control mode or the full-color-control mode at a time.

The load control system 100 may include one or more input control devices for controlling the load control devices (e.g., controlling the intensity levels of the lighting load 112 controlled by the dimmer switch 110, the LED light source 122 controlled by the LED driver 120, and/or the LED light source of the controllable light source 130). For example, the input control devices of the load control system 100 may comprise, a tabletop remote control device 140, a wall-mounted remote control device 142, a handheld remote control device 144, and/or a retrofit remote control device 146 as shown in FIG. 1. The load control devices (e.g., the dimmer switch 110, the LED driver 120, and/or the controllable light source 130) may be controlled substantially in unison, or be controlled individually. The input control devices may be configured to control the load control devices to turn on and off the lighting load 112 controlled by the dimmer switch 110, the LED light source 122 controlled by the LED driver 120, and/or the controllable light source 130. The input control devices may be configured to control the intensity levels of the lighting load 112 controlled by the dimmer switch 110, the LED light source 122 controlled by the LED driver 120, and/or the controllable light source 130. The input control devices may be configured to control the color of light emitted by the lighting load 112 and/or the controllable light source 130 (e.g., by controlling a color temperature of the lighting loads or by applying full color control to the lighting loads). The input control devices may be configured to control the intensity level and/or the color temperature of each of the lighting load 112, the LED light source 122, and the controllable light source 130 to an absolute level (e.g., to a particular intensity level, such as to 50%), and/or by a relative amount (e.g., by a particular amount, such as by 10%). The input control devices may be configured to use full color control to control color of each of the lighting load 112, the LED light source 122, and the controllable light source 130 to an absolute level (e.g., to a particular full color).

The input control device may be configured to be responsive to an input and transmit control data in one or more messages via the RF signals 108 for controlling the lighting load 112, the LED light source 122, and/or the controllable light source 130 based on the input. For example, the input may comprise a detection of an actuation of a button of the input control device by a user. The control data may include commands and/or other information (e.g., such as identification information) for controlling the lighting load 112, the LED light source 122, and/or the controllable light source 130. In some examples, the dimmer switch 110 may be configured to transmit messages via the RF signals 108 for controlling other lighting loads, such as the LED light source 122 and/or the integral LED light source of the controllable light source 130.

The input control devices (e.g., the tabletop remote control device 140, the wall-mounted remote control device 142, the handheld remote control device 144, and/or the retrofit remote control device 146) may be configured to receive an input and may generate and transmit a message (e.g., including control data, such as commands) for controlling the lighting load 112, the LED light source 122, and/or the controllable light source 130 in response to the input. The tabletop remote control device 140, the wall-mounted remote control device 142, the handheld remote control device 144, and/or the retrofit remote control device 146 may be powered by a direct-current (DC) power source (e.g., a battery or an external DC power supply plugged into an electrical outlet). In some examples, the wall-mounted remote control device 142 may be configured to be electrically connected to the power source 102 for receiving power (e.g., when the wall-mounted remote control device 142 is mounted to the electrical wallbox. The tabletop remote control device 140 may be configured to be placed on a surface (e.g., a table). The wall-mounted remote control device 142 may be configured to be mounted to a wall (e.g., directly to a wall) and/or to an electrical wallbox. The handheld remote control device 144 may be sized to fit into a user's hand. The retrofit remote control device 146 may be configured to be mounted to a light switch, such as the toggle switch 136 (e.g., which may be pre-existing in the load control system 100). As an example, a consumer may replace an existing lamp with the controllable light source 130, adjust the toggle switch 136 that is coupled to the controllable light source 130 to the on position, install (e.g., mount) the retrofit remote control device 146 onto the toggle switch 136, and associate the retrofit remote control device 146 with the controllable light source 130. As shown, the toggle switch 136 is coupled (e.g., via a series electrical connection) between the power source 102 and the electrical outlet 134 into which the table lamp 132 in which the controllable light source 130 is installed may be plugged (e.g., as shown in FIG. 1). Alternatively, the toggle switch 136 may be coupled between the power source 102 and one or more lighting loads without the electrical outlet 134.

The load control system 100 may comprise a system controller 150. For example, the system controller 150 may operate as an intermediary device and/or a central processing device for one or more other devices in the load control system 100. The system controller 150 may be configured to communicate messages (e.g., digital messages) to and from the control devices (e.g., the input control devices and the load control devices of the load control system 100). The system controller 150 may be configured to receive messages from the input control devices (e.g., the tabletop remote control device 140, the wall-mounted remote control device 142, the handheld remote control device 144, and/or the retrofit remote control device 146) and transmit messages to the load control devices (e.g., the dimmer switch 110, the LED driver 120, and/or the controllable light source 130) in response to the messages received from the input control devices. The system controller 150 may route the messages based on the association information stored thereon. The messages from the input control devices and/or to the load control devices may be communicated via the RF signals 108.

The system controller 150 may be configured to transmit messages to the load control devices for controlling the lighting loads (e.g., the lighting load 112, the LED light source 122, and/or the LED light source of the controllable light source 130) in response to the messages received from the input control devices (e.g., via the RF signals 108). For example, the system controller 150 may receive a message indicating an actuation of a button from an input control device (e.g., such as the tabletop remote control device 140, the wall-mounted remote control device 142, the handheld remote control device 144, and/or the retrofit remote control device 146), and transmit a message to one or more of the load control devices for controlling the lighting loads. For example, the input control devices may be configured to control (e.g., indirectly control) the lighting loads (e.g., the lighting load 112, the LED light source 122, and/or the LED light source of the controllable light source 130) by transmitting messages to the system controller 150 that cause the system controller 150 to transmit messages including commands for controlling the lighting loads to the load control devices. Though the system controller 150 is described as communicating messages between devices in the load control system 100, messages may be communicated directly between devices (e.g., between the input control devices and/or the load control devices). The messages may include configuration data for configuring the input control devices and/or the load control devices, and/or the messages may include control data (e.g., one or more commands) for controlling the lighting loads. The system controller 150 may be coupled to a network, such as a wireless or wired local area network (LAN), e.g., for access to the Internet. The system controller 150 may be wirelessly connected to the network, e.g., using WI-FI technology. The system controller 150 may be coupled to the network via a network communication bus (e.g., an Ethernet communication link).

The load control devices (e.g., the dimmer switch 110, the LED driver 120, and/or the controllable light source 130) may be configured to be controlled by one or more of the input control devices (e.g., the tabletop remote control device 140, the wall-mounted remote control device 142, the handheld remote control device 144, and/or the retrofit remote control device 146) and/or the system controller 150. For example, one or more of the load control devices may be associated with one of the input control devices during a configuration procedure of the load control system 100. During normal operation of the load control system 100, the load control devices may be responsive to messages received from the input control devices to which the respective load control devices are associated.

The input control devices and/or the system controller 150 may be configured to activate a scene (e.g., a preset) associated with the lighting loads (e.g., the lighting load 112, the LED light source 122, and/or the LED light source of the controllable light source 130). A scene may be associated with one or more predetermined settings of the lighting loads, such as an intensity level and/or a color (e.g., a color temperature and/or a full color) of the lighting loads. The scenes may be configured via the input control devices and/or the system controller 150. The input control devices may be configured to switch between different operational modes. An operational mode may be associated with controlling different types of electrical loads or different operational aspects of one or more electrical loads of the load control system 100 (e.g., electrical loads including and/or other than the lighting loads shown in FIG. 1). Examples of operational modes may include a lighting control mode for controlling one or more lighting loads (e.g., which in turn may include an intensity-adjustment mode, a color-temperature-adjustment mode, and/or a full-color-adjustment mode), an entertainment system control mode (e.g., for controlling music selection and/or the volume of an audio system), an heating, ventilation, and air-conditioning (HVAC) system control mode, a winter treatment device control mode (e.g., for controlling one or more shades), and/or the like.

The load control devices (e.g., the dimmer switch 110, the LED driver 120, and/or the controllable light source 130) may be configured to control the respective lighting loads (e.g., the lighting load 112, the LED light source 122, and/or the LED light source of the controllable light source 130) in response to scenes selected by the input control devices and/or the system controller 150 For example, the messages transmitted by the input control devices in response to a scene being selected may include an indication of the selected scene. The load control devices may have stored in memory thereon the particular intensity levels, colors (e.g., full colors), and/or color temperatures to which to control the respective lighting loads in response to the selected scenes. For example, the load control devices may be configured to provide absolute control of the intensity level, color (e.g., full color), and/or color temperature (e.g., to control the intensity level, color, and/or color temperature to absolute levels) in response to the selection of scenes. In response to the selection of a particular scene, the load control devices may be configured to control either color (e.g., full color) and/or the color temperature of a particular lighting load that is a part of the scene. For example, the LED driver 120 and/or the controllable light source 130 may be configured to operate in a color-temperature-control mode to control the color temperature of the integral lighting load, or may operate in a full-color-control mode to control the color of the integral lighting load (e.g., as determined by an x-chromaticity coordinate and a y-chromaticity coordinate).

The load control devices may be configured to control the respective lighting loads in response to an actuation of a variable adjustment actuator (e.g., such as a linear slider or a rotary knob) of one of the input control devices. For example, the input control devices may include a rotary knob control device that includes a rotary knob for controlling the intensity level, the color, and/or the color temperature of one or more of the lighting loads. The rotary knob control device may be configured to operate in an intensity-adjustment mode to allow for control of a present intensity level L_{PRES} of one or more of the lighting loads in response to rotations of the rotary knob. For example, the control unit 210 may be configured to control the present intensity level L_{PRES} of the one or more lighting loads across a dimming range between a low-end intensity level L_{LE} (e.g., a minimum intensity level, such as approximately 1%) and a high-end intensity level L_{HE} (e.g., a maximum intensity level, such as approximately 100%). The rotary knob control device may be configured to operate in a color-temperature-adjustment mode to allow for control of a present color temperature T_{PRES} of one or more of the lighting loads in response to rotations of the rotary knob. For example, the control unit 210 may be configured to control the present color temperature T_{PRES} of the one or more lighting loads across a color temperature range between a warm-white color temperature T_{WW} (e.g., approximately 1500 K) and a cool-white color temperature T_{CW} (e.g., approximately 7000 K). The rotary knob control device may be configured to operate in a full-color-adjustment mode to allow for control of a present color (e.g., a full color) of one or more of the lighting loads (e.g., as defined by an x-chromaticity coordinate and a y-chromaticity coordinate) in response to rotations of the rotary knob.

When the rotary knob control device is in the full-color-adjustment mode, the rotary knob control device may be configured to transmit messages including commands (e.g., full-color-adjustment commands) for providing absolute control of the color (e.g., full color) of the lighting loads controlled by the load control devices to which the rotary knob control device is associated. For example, the rotary knob control device may be configured to transmit a message including a full-color-adjustment command for controlling the lighting loads to a commanded color (e.g., which may be defined by an absolute level for the x-chromaticity coordinate and an absolute level for the y-chromaticity coordinate of the particular color). The commanded color included in the full-color-adjustment command may be, for example, a last-selected color of the rotary knob control device. For example, the load control devices may each be responsive to a received full-color-adjustment command when the respective load control device is presently operating in the full-color-control mode (e.g., the load control device may not be responsive to the full-color-adjustment command when the load control device is presently operating in the color-temperature-control mode). In some examples, the load control devices may each be responsive to a received full-color-adjustment command when the load control device is presently operating in the color-temperature-control mode (e.g., the load control device may be responsive to the full-color-adjustment command when the load control device is operating in either the full-color-control mode or the color-temperature-control mode). For example, the full-color-adjustment command may include an indication that the load control devices should change from the color-temperature-control mode to the full-color-control mode.

When the rotary knob control device is in the intensity-adjustment mode or the color-temperature-adjustment mode, the rotary knob control device may be configured to transmit messages including commands for providing relative control of the intensity level or the color temperature, respectively, of the lighting loads controlled by the load control devices to which the rotary knob control device is associated. For example, the rotary knob control device may be configured to transmit a message including an intensity-adjustment command for adjusting the intensity levels of the lighting loads by an intensity-adjustment amount (e.g., a relative amount), and/or a message including a color-temperature-adjustment command for adjusting the color temperatures of the lighting loads by a color-temperature-adjustment amount (e.g., a relative amount). The intensity-adjustment amount included in the intensity-adjustment command and/or the color-temperature-adjustment amount included in the color-temperature-adjustment command may be determined based on a direction and/or an amount of rotation of the rotary knob of the rotary knob control device. For example, the load control devices that are associated with the rotary knob may each be responsive to a received intensity-adjustment command. In addition, the load control devices may each be responsive a received color-temperature-adjustment command when the respective load control device is presently operating in the color-temperature-control mode (e.g., the load control device may not be responsive to the color-temperature-adjustment command when the load control device is presently operating in the full-color-control mode). In some examples, the load control devices may each be responsive a received color-temperature-adjustment command when the load control device is presently operating in the full-color-control mode (e.g., the load control device may be responsive to the color-temperature-adjustment command when the load control device is operating in either the color-temperature-control mode or the full-color-control mode). For example, the color-temperature-adjustment command may include an indication that the load control devices should change from the full-color-control mode to the color-temperature-control mode.

Prior to the receipt of an intensity-adjustment command, the present intensity levels L_{PRES} of a plurality of lighting loads may be at different values (e.g., due to a prior selection of a scene). For example, the present intensity level L_{PRES} of one of the lighting loads may be separated (e.g., different) from the present intensity level L_{PRES} of one or more of the other lighting loads by one or more respective offsets (e.g., as set by the selected scene). When providing relative control of the lighting loads in response to the intensity-adjustment commands, the load control devices may each be configured to adjust the present intensity level L_{PRES} of the respective lighting load to maintain the offsets (e.g., relative differences) between the present intensity level L_{PRES} of the respective lighting load and the present intensity levels L_{PRES} of the other lighting loads. Each of the load control devices may be configured to limit the present intensity level L_{PRES} to the respective lighting load to the low-end intensity level L_{LE} (e.g., the minimum intensity level) and the high-end intensity level L_{HE} (e.g., the maximum intensity level). As a result, while one or more of the lighting loads are controlled to the low-end intensity level L_{LE} or the high-end intensity level L_{HE}, the load control devices may not be able to maintain the offsets between the present intensity level L_{PRES} of the respective lighting load and the present intensity levels L_{PRES} of the present intensity level L_{PRES} (e.g., since the one or more of the lighting loads are being limited to the low-end intensity level L_{LE} or the high-end intensity level L_{HE}). However, after the present intensity levels L_{PRES} of those one or more lighting loads are controlled above the low-end intensity level L_{LE} or below the high-end intensity level L_{HE}, the load control devices may be configured to control the respective lighting loads to restore the offsets between the present intensity levels L_{PRES} of the lighting loads (e.g., the offsets as set by the prior selection of the scene) as will be described in greater detail below. Similarly, the load control devices may be configured to control the respective lighting loads to restore offsets between the present color temperatures T_{PRES} of the lighting loads (e.g., offsets as set by a prior selection of a scene) after limiting the present color temperatures T_{PRES} of the lighting loads to either the warm-white color temperature T_{WW} or the cool-white color temperature T_{CW}.

After adjustments of the present intensity levels L_{PRES}, the present color temperatures T_{PRES}, and/or the present color of the lighting loads controlled by the load control devices that are responsive to the rotary remote control device, each of the load control devices may be configured to return the respective lighting load to a previous state. For example, the rotary remote control may be configured to transmit a message including an undo command, and the load control devices may be configured to return the respective lighting load to the previous state in response to receiving the message including the undo command. For example, each of the load control devices may be configured to store the previous state of the respective lighting load (e.g., a stored intensity level L_{STRD}, a stored color temperature T_{STRD}, and/or a stored color, for example, as defined by a stored x-chromaticity coordinate X_{STRD} and a stored y-chromaticity coordinate Y _{STRD}). The previous state (to which the lighting load may be restored) may be, for example, an intensity level, a color temperature, and/or a color set by the last selected scene.

In addition, the previous state may be a last stable state of the lighting load. The last stable state may be the intensity level, the color temperature, and/or the color of the lighting load after which no changes are made for a predetermined undo timeout period. For example, after a change to the intensity level, the color temperature, and/or the color of the lighting load, the load control devices may each start an undo timer to keep track of the undo timeout period. After the expiration of the undo timeout period (e.g., when no changes are made to the intensity level, the color temperature, and/or the color of the lighting load during the undo timeout period), the load control devices may each store the present state as the previous state (to which the lighting load may be restored).

As a result of the undo functionality, a user may adjust the intensity level, the color temperature, and/or the color of each of the lighting loads using the rotary remote control device to observe the resulting effect on the lighting in the space in which the lighting loads are installed, and then undo the changes to the lighting loads if the resulting effect is undesirable. Additionally or alternatively, other devices of the load control system 100 (e.g., other than the load control devices themselves, such as the rotary remote control device and/or the system controller 150) may be configured to store the previous state of each of the lighting loads (to which the respective lighting load may be restored), and may be configured to transmit messages including commands for restoring the lighting loads to the previous states.

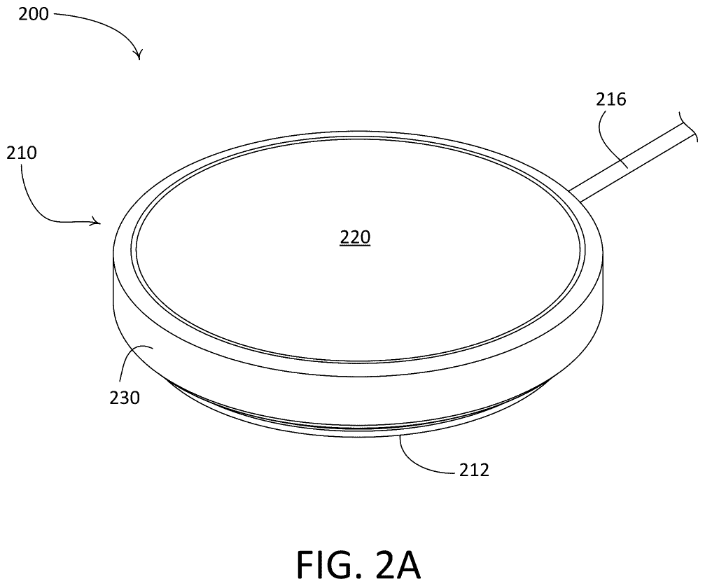

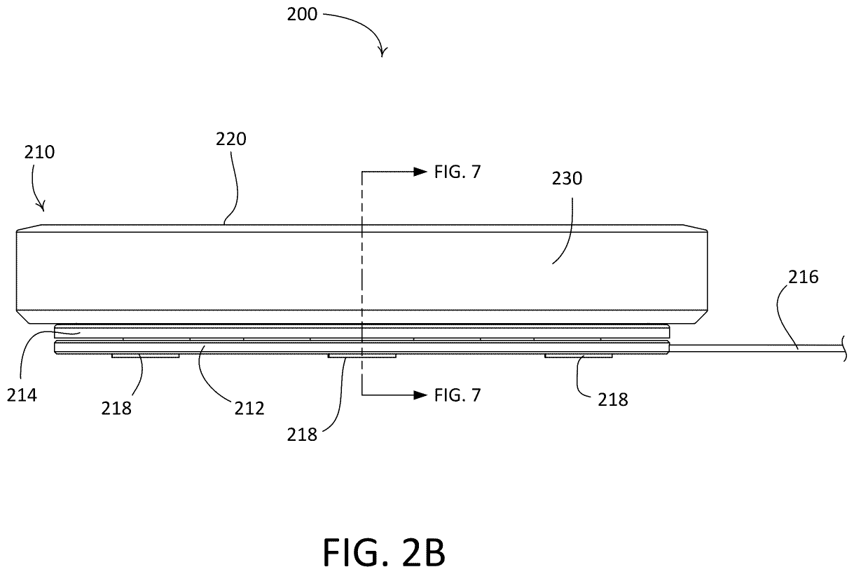

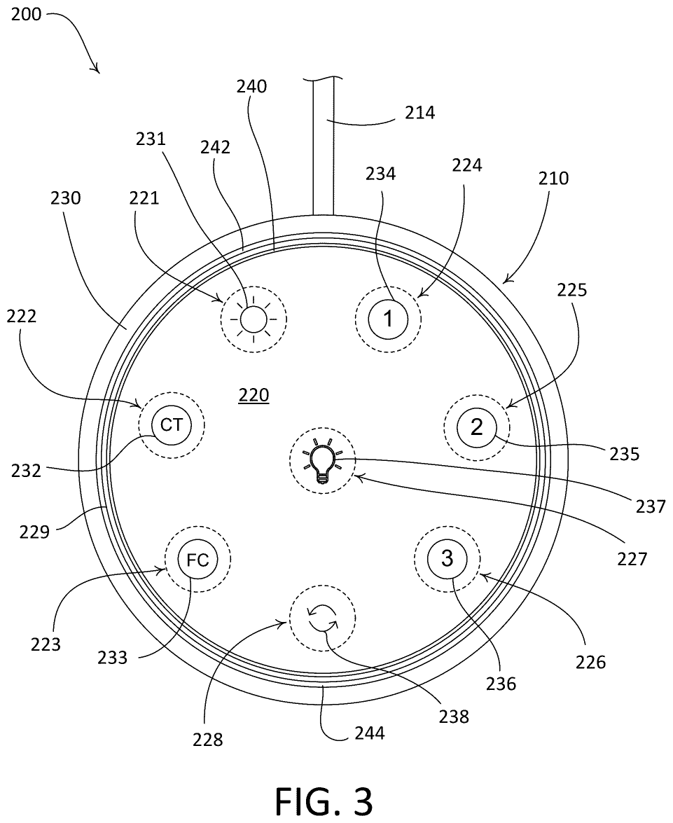

FIGS. 2A-3 depict an example input control device, such as a remote control device 200 that may be deployed as the tabletop remote control device 140, the wall-mounted remote control device 142, the handheld remote control device 144, and/or the retrofit remote control device 146 in the load control system 100. FIG. 2A is a perspective view and FIG. 2B is a side view of the example remote control device 200. FIG. 3 is a top view of the example remote control device 200. The remote control device 200 may be configured to transmit messages to one or more load control devices (e.g., the dimmer switch 110, the LED driver 120, and/or the controllable light source 130) for controlling respective lighting loads (e.g., the lighting load 112, the LED light source 122, and/or the LED light source of the controllable light source 130).

The remote control device 200 may comprise a control unit 210 configured to be supported by a base 212. The control unit 210 may be configured to transmit and receive messages (e.g., digital messages) via wireless signals, such as radio-frequency (RF) signals (e.g., the RF signals 108). The control unit 210 may be configured to transmit messages including control data, such as one or more commands, for controlling the lighting loads. For example, the control unit 210 may be configured to transmit messages having commands for adjusting a present intensity level L_{PRES} of each of the lighting loads. In addition, the control unit 210 may be configured to transmit messages having commands for adjusting a color of each of the lighting loads, for example, to provide adjustment of a color temperature (e.g., a correlated color temperature) and/or to provide full color adjustment (e.g., to adjust an x-chromaticity coordinate and/or a y-chromaticity coordinate of the color) of each of the lighting loads. For example, the control unit 210 may be configured to be associated with one or more of the load control devices during a configuration procedure of the remote control device 200 and transmit message including commands for controlling respective lighting loads controlled by one or more of the plurality of load control devices during normal operation.

The remote control device 200 (e.g., the control unit 210) may comprise a user interface surface 220 and a rotatable member 230 (e.g., a circular rotatable member or a rotary knob). For example, the user interface surface 220 may be a touch sensitive surface (e.g., a capacitive touch surface), which may be actuated to allow the control unit 210 to receive inputs (e.g., touch actuations and/or touch inputs). For example, the user interface surface 220 may be circular in shape and may define a circular perimeter 329. The rotatable member 230 may be configured to surround the user interface surface 220 and/or rotate about the user interface surface 220. The rotatable member 230 may also be circular in shape (e.g., to match the circular perimeter 329 of the user interface surface 220).

The control unit 210 may also comprise a support plate 214 that may rest on the base 212. For example, the support plate 214 may be circularly shaped. The user interface surface 220 and the rotatable member 230 may be supported by the support plate 214. The rotatable member 230 may be rotatable with respect to the support plate 214 and the user interface surface 220. The control unit 210 may be configured to receive power via the base 212. For example, the base 212 may be electrically coupled to a power source, such as a direct-current (DC) power source, via an electrical cord 216, and the control unit 210 may be configured to charge via the base 212. The base 212 may comprise feet 218 that may rest on a horizontal surface (e.g., a table top). For example, feet 218 may comprise a rubber material such that the base 212 and the support plate 214 of the control unit 210 do not move when the rotatable member 230 is rotated.

As shown in FIG. 3, the user interface surface 220 may comprise one or more actuators 221-228 (e.g., virtual actuators), which may each comprise a portion of the user interface surface 220. Each of the actuators 221-228 may be identified by a respective indicia, e.g., such as icons 231-238, respectively. The icons 231-238 may indicate positions of the respective actuators 221-228 on the user interface surface 220. For example, the control unit 210 may be configured to illuminate the user interface surface 220 to display the icons 231-238. The control unit 210 may comprise, for example, one or more light sources (e.g., light-emitting diodes) located behind the icons 231-238 (e.g., behind the actuators 221-228), respectively, for illuminating (e.g., selectively illuminating) the icons 231-238. When the icons 231-238 are not illuminated, the icons 231-238 may disappear from view (e.g., as shown in FIG. 2). The control unit 210 may be configured to cease illuminating the icons 231-238 when the control unit 210 is in an idle state (e.g., after a predetermined amount of time since the user interface surface 220 and/or the rotatable member 230 were last actuated). The control unit 210 may be configured to illuminate the icons 231-238 to indicate the positions of the actuators 221-228 when the control unit 210 is in the idle state and the user interface surface 220 and/or the rotatable member 230 is actuated and/or when a user's finger moves in close proximity to the user interface surface 220. The control unit 210 may comprise one or more capacitive touch pads located behind the user interface surface 220 for receiving “touch” actuations (e.g., taps) of the actuators 221-228. For example, the touch actuations (e.g., taps) may be actuations of the user interface surface 220 (e.g., the actuators 221-228) that do not cause the user interface surface 220 to move (e.g., be pressed in towards the base 212, pivot, and/or otherwise move). For example, the control unit 210 may comprise a respective capacitive touch pad behind each of the actuators 221-228.

The control unit 210 may comprise, for example, an intensity-adjustment mode actuator 221 (e.g., identified by an intensity-adjustment mode icon 231), a color-temperature-adjustment mode actuator 222 (e.g., identified by a color-temperature-adjustment mode icon 232), and a full-color-adjustment mode actuator 223 (e.g., identified by a full-color-adjustment mode icon 233) for adjusting an adjustment mode (e.g., an operating mode) of the control unit 210 (e.g., as will be described in greater detail below). In addition, the control unit 210 may comprise a first scene actuator 224 (e.g., identified by a first scene icon 234), a second scene actuator 225 (e.g., identified by a second scene icon 235), and a third scene actuator 226 (e.g., identified by a third scene icon 236) for selecting first, second, and third scenes (e.g., lighting scenes), respectively, for controlling the lighting loads in unison. The control unit 210 may also comprise a toggle actuator 227 (e.g., identified by a toggle icon 237) for turning the lighting loads (e.g., all of the lighting loads) on and off. Further, the control unit 210 may comprise an undo actuator 228 (e.g., identified by an undo icon 238) for undoing changes to the intensity levels and/or colors of the lighting loads (e.g., as will be described in greater detail below). In some examples, the user interface surface 220 of the control unit 210 may not comprise a touch sensitive surface, and the actuators 221-228 may comprise physical buttons on which the respective icons 231-238 may be located (e.g., printed and/or formed).

The control unit 210 may be configured to generate control data (e.g., one or more commands) in response to rotation of the rotatable member 230 and transmit messages including the control data (e.g., the one or more commands). For example, the control unit 210 may be configured to transmit messages including one or more commands for adjusting the intensity level and/or the color (e.g., color temperature and/or full color) of the lighting loads in response to rotations of the rotatable member 230 (e.g., depending upon the adjustment mode of the control unit 210). A user may select one of the adjustment modes (e.g., by tapping one of the intensity-adjustment mode actuator 221, the color-temperature-adjustment mode actuator 222, and/or the full-color-adjustment mode actuator 223) prior to rotating the rotatable member 230. For example, the user may actuate (e.g., tap to provide a touch actuation of) the intensity-adjustment mode actuator 221 to cause the control unit 210 to enter an intensity-adjustment mode, and then rotate the rotatable member 230 to cause the control unit 210 to transmit message(s) including at least one command, such as an intensity-adjustment command for controlling the intensity levels of one or more of the lighting loads. In addition, the user may actuate (e.g., tap to provide a touch actuation of) the color-temperature-adjustment mode actuator 222 to cause the control unit 210 to enter the color-temperature-adjustment mode, and then rotate the rotatable member 230 to cause the control unit 210 to transmit message(s) including at least one command, such as a color-temperature-adjustment command for controlling the color temperature of one or more of the lighting loads. Further, the user may actuate (e.g., tap to provide a touch actuation of) the full-color-adjustment mode actuator 223 to cause the control unit 210 to enter the full-color-adjustment mode, and then rotate the rotatable member 230 to cause the control unit 210 to transmit message(s) including at least one command, such as a full-color-adjustment command for controlling the color (e.g., full color) of one or more of the lighting loads. When one of the adjustment modes is selected, the control unit 210 may be configured to illuminate (e.g., only illuminate) the one of icons 231-233 that indicates the selected adjustment mode (e.g., and not illuminate the icons 231-233 of the adjustment modes that are not selected and/or the other icons 234-238).

The remote control device 200 (e.g., the control unit 210) may be configured to determine a direction and/or an amount of rotation of the rotatable member 230 and to transmit messages including adjustment amounts for adjusting the intensity level and/or the color temperature of one or more of the lighting loads. For example, when in the intensity-adjustment mode, the control unit 210 may be configured to transmit an intensity-adjustment amount ΔL for adjusting a present intensity level L_{PRES} of each of the lighting loads. In addition, when in the color-temperature-adjustment mode, the control unit 210 may be configured to transmit a color-temperature-adjustment amount ΔT for adjusting a present color temperature T_{PRES} of each of the lighting loads. For example, the control unit 210 may be configured to periodically transmit the messages including the adjustment amounts (e.g., the intensity-adjustment amount ΔL and/or the color-temperature-adjustment amount ΔT). The control unit 210 may be configured to transmit messages including the adjustment amounts (e.g., including different adjustment amounts) multiple times during a single rotation of the rotatable member 230. The adjustment amount included in each of the messages may be dependent upon the direction and the amount of rotation of the rotatable member 230. For example, the adjustment amount (e.g., the intensity-adjustment amount ΔL and/or the color-temperature-adjustment amount ΔT) may be a function of the amount of rotation of the rotatable member 230 since the start of the rotation and/or since the last transmission of a message including an adjustment amount during the same rotation of the rotatable member 230. The adjustment amount (e.g., the intensity-adjustment amount ΔL and/or the color-temperature-adjustment amount ΔT) may be, for example, positive when the direction of rotation is clockwise (e.g., to increase the present intensity level L_{PRES} of each of the lighting loads) and negative when the direction of rotation is counter-clockwise (e.g., to decrease the present intensity level L_{PRES} of each of the lighting loads), or vice versa.

The load control devices that receive the message(s) including the adjustment amount (e.g., the intensity-adjustment amount ΔL and/or the color-temperature-adjustment amount ΔT) may adjust the respective present intensity levels L_{PRES} and/or the respective present color temperature T_{PRES} by the received adjustment amount. Accordingly, in response to rotations of the rotatable member 230, the load control devices associated with the remote control device 200 may adjust the present intensity level L_{PRES} of the respective lighting load by the intensity-adjustment amount ΔL and/or adjust the present color temperature T_{PRES} by the color-temperature-adjustment amount ΔT (e.g., depending on the adjustment mode of the remote control device 200). The load control devices may be configured to provide relative control of the intensity levels and/or the color temperatures the respective lighting loads in response to rotations of the rotatable member 230. For example, prior to a rotation of the rotatable member 230, the intensity levels and/or the color temperatures of the lighting loads may be at different levels (e.g., separated by offsets). As a result of providing relative control, the load control devices may adjust the present intensity level L_{PRES} and/or the present color temperature T_{PRES} of each of the lighting loads to maintain the same offsets between the respective present intensity levels L_{PRES} and/or respective present color temperatures T_{PRES}.

When the remote control device 200 (e.g., the control unit 210) is in the full-color-adjustment mode, the rotary knob control device may be configured to transmit messages including commands (e.g., full-color-adjustment commands) for providing absolute control of the color (e.g., full color) of the lighting loads controlled by the load control devices to which the rotary knob control device is associated. The rotary knob control device may be configured to transmit a message including a full-color-adjustment command for controlling the lighting loads to a commanded color. For example, the commanded color may be defined by a commanded x-chromaticity coordinate (e.g., an absolute level for the x-chromaticity coordinate) and a commanded y-chromaticity coordinate (e.g., an absolute level for the y-chromaticity coordinate of the particular color). The commanded color included in the full-color-adjustment command may be, for example, a last-selected color of the rotary knob control device. As a result of providing absolute control, the load control devices may adjust the present color (e.g., a full color) of the respective lighting loads (e.g., as defined by an x-chromaticity coordinate and a y-chromaticity coordinate) to the same color.

After a touch actuation of one of the intensity-adjustment mode actuator 221, the color-temperature-adjustment mode actuator 222, and/or the full-color-adjustment mode actuator 223 on the user interface surface 220, the remote control device 200 (e.g., the control unit 210) may be configured to transmit a message including one of an intensity-adjustment command, a color-temperature-adjustment command, or a full-color-adjustment command, respectively, to one or more of the load control devices in response to a rotation of the rotatable member 230. For example, the load control devices that are associated with the control may be responsive to (e.g., always responsive to) received intensity-adjustment commands. The load control devices may be responsive to the received color control commands (e.g., a color-temperature-adjustment command and/or a full-color-adjustment command) depending upon whether the load control device is capable of color control or not (e.g., is color-temperature-control capable and/or full-color-control capable) and/or depending on the color control mode in which the load control device is presently operating (e.g., the color-temperature-control mode or the full-color-control mode). For example, the load control devices may each be responsive to a received color-temperature-adjustment command when the respective load control device is presently operating in the color-temperature-control mode (e.g., the load control device may not be responsive to the color-temperature-adjustment command when the load control device is presently operating in the full-color-control mode). In addition, the load control devices may each be responsive to a received full-color-adjustment command when the respective load control device is presently operating in the full-color-control mode (e.g., the load control device may not be responsive to the full-color-adjustment command when the load control device is presently operating in the color temperature control mode).

The remote control device 200 (e.g., the control unit 210) may also be responsive to “press” actuations of the intensity-adjustment mode actuator 221, the color-temperature-adjustment mode actuator 222, and/or the full-color-adjustment mode actuator 223 on the user interface surface 220. For example, a press actuation may comprise a press-and-hold actuation of one of the intensity-adjustment mode actuator 221, the color-temperature-adjustment mode actuator 222, and/or the full-color-adjustment mode actuator 223 for a predetermined amount of time (e.g., three seconds). In addition, a press actuation may comprise an actuation (e.g., a tactile actuation) of the user interface surface 220 that causes the user interface surface 220 to move (e.g., pivot and/or be depressed towards the base 212). The control unit 210 may be configured to detect a touch actuation (e.g., a tap) of one of the actuators 221-228 prior to detecting a press actuation of one of the actuators 221-228. In response to a press actuation of one of the color-temperature-adjustment mode actuator 222 and/or the full-color-adjustment mode actuator 223, the remote control device 200 (e.g., the control unit 210) may provide control of the load control devices, such that all of the load control devices that are capable of color control (e.g., either color-temperature-control capable or full-color-control capable) may be responsive to both a color-temperature-adjustment command or a full-color-adjustment command (e.g., independent of whether the load control device is operating in the color-temperature-control mode or the full-color-control mode prior to receiving the command).

In response to a press actuation of the color-temperature-adjustment mode actuator 222 or the full-color-adjustment mode actuator 223, the remote control device 200 (e.g., the control unit 210) may be configured to include with the transmitted command (e.g., either a color-temperature-adjustment command or a full-color-adjustment command) an indication that the load control devices should change to the color-temperature-control mode or to the full-color-control mode. For example, when the control unit 210 detects a press actuation of the color-temperature-adjustment mode actuator 222, the control unit 210 may be configured to transmit a message including a color-temperature-adjustment command along with an indication that the load control devices should change to the color-temperature-control mode (e.g., if the control unit 210 is presently operating in the full-color-control mode). As a result, the load control devices that receive such a message may each be responsive to the received color-temperature-adjustment command even when the load control device is presently operating in the full-color-control mode. In addition, when the control unit 210 detects a press actuation of the full-color-adjustment mode actuator 223, the control unit 210 may be configured to transmit a message including a full-color-adjustment command along with an indication that the load control devices should change to the full-color-control mode (e.g., if the control unit 210 is presently operating in the color-temperature-control mode). As a result, the load control devices that receive such a message may each be responsive to the received full-color-adjustment command even when the load control device is presently operating in the color-temperature-control mode.

In response to a touch actuation (e.g., a tap) of one of the first scene actuator 224, the second scene actuator 225, and the third scene actuator 226, the remote control device 200 (e.g., the control unit 210) may be configured to transmit a message including a scene command including an indication of the selected scene. For example, the control unit 210 may be configured to transmit a message including a scene command indicating the first scene in response to detecting a touch actuation of the first scene actuator 224, a message including a scene command indicating the second scene in response to detecting a touch actuation of the second scene actuator 225, and a message including a scene command indicating the third scene in response to detecting a touch actuation of the third scene actuator 226. Each of the load control devices may be configured to store an intensity level, a color temperature, and/or a color (e.g., full color) for each of the scenes to which the load control device is responsive. Upon receiving the message including the scene command, each load control device may be configured to retrieve the stored values for the intensity level, the color temperature, and/or the color (e.g., full color) for the selected scene, and control the respective lighting load according to the retrieved values.

In response to detecting a touch actuation (e.g., a tap) of the toggle actuator 227, the control unit 210 may be configured to control the load control devices to cause one or more of the lighting loads to toggle their states (e.g., turn from off to on, or vice versa). For example, in response to detecting a touch actuation of the toggle actuator 227, the control unit 210 may be configured to transmit a query message to the one or more load control devices that are associated with the remote control device 200 to determine the present states of the lighting loads. In one example, the control unit 210 may be configured to determine the state one of the lighting loads based on a first response message received in response to the transmission of the query message, and to control the load control devices in response to the determined state of that lighting load. For example, the control unit 210 may be configured to transmit a message including an on command for turning all of the lighting loads on in response to determining that the first response message indicates that the lighting load is off, and to transmit a message including an off command for turning all of the lighting loads off in response to determining that the first response message indicates that the lighting load is on. In another example, the control unit 210 may wait for response messages from a plurality (e.g., all or most) of the load control devices to which the remote control device 200 is associated, and determine how to control the load control devices based on the response messages from the plurality of the load control devices from which the response messages were received. For example, the control unit 210 may be configured to transmit a message including an on command for turning all of the lighting loads on in response to determining that all of the lighting loads controlled by the plurality of load control devices are off, and to transmit a message including an off command for turning all of the lighting loads off in response to determining that at least one of the lighting loads controlled by the plurality of load control devices is on. In some examples, the control unit 210 may be configured to transmit a message including an indication of the actuation of the toggle actuator 227 to an external device (e.g., such as the system controller 150) and the external device may be configured to determine whether to transmit an on command or an off command to the load control devices. Further, the control unit 210 may be configured to transmit a message including a toggle command for causing the load control devices to change the state of the respective lighting loads (e.g., turn from off to on, or vice versa).

In response to detecting a touch actuation (e.g., a tap) of the undo actuator 228, the control unit 210 may be configured to control the load control devices for causing the load control devices to undo changes to the present intensity level L_{PRES}, the present color temperature T_{PRES}, and/or the present color (e.g., full color). For example, the control unit 210 may be configured to transmit a message including control data indicating the actuation of the undo actuator 228 (e.g., an undo command) in response to detecting a touch actuation of the undo actuator 228. Upon receiving the message including the control data indicating the actuation of the undo actuator 228 (e.g., the undo command), each of the load control devices may be configured to revert to a previous state. For example, the previous state may be the state of the lighting load according to the last selected scene. In addition, the previous state may be the last state of the lighting load after which no changes were made to the present intensity level L_{PRES}, the present color temperature T_{PRES}, and/or the present color (e.g., full color) of the lighting load for a predetermined undo timeout period T_{UNDO}. Each of the load control devices may maintain an undo timer to determine when an end of the undo timeout period T_{UNDO} has occurred. Each load control device may be configured to reset the undo timer (e.g., start over the undo timeout period T_{UNDO}) whenever a change is made to the present intensity level L_{PRES}, the present color temperature T_{PRES}, and/or the present color (e.g., full color) of the respective lighting load. At the end of the undo timeout period T_{UNDO} (e.g., when the undo timer expires), each of the load control devices may be configured to store the present intensity level L_{PRES}, the present color temperature T_{PRES}, and/or the present color (e.g., full color) of the respective lighting load to be recalled later in response to an actuation of the undo actuator 228.

The remote control device 200 (e.g., the control unit 210) may also comprise a light bar 240 surrounding the actuators 221-228 on the user interface surface 220. For example, the light bar 240 may be circular in shape (e.g., the light bar 240 may be a circle). The light bar 240 may be located on the user interface surface 220 adjacent to the circular perimeter 329 of the user interface surface 220. The control unit 210 may comprise one or more light sources (e.g., light-emitting diodes) for illuminating the light bar 240. For example, the control unit 210 may comprise a number N_{LED} of light sources (e.g., approximately 20 light sources) surrounding the perimeter of the user interface surface 220 (e.g., behind the user interface surface 220) for illuminating the light bar 240. In some examples, the control unit 210 may be configured to illuminate a gap 242 located between the user interface surface 220 (e.g., the circular perimeter 329 of the user interface surface 220) and the rotatable member 230 (e.g., the gap 242 may operate as a light bar and the light bar 240 on the user interface surface 220 may be omitted). In addition, the control unit 210 may comprise a light pipe (e.g., a diffuser) that may be located within the gap 242 and may be illuminated by the light sources. Further, the control unit 210 may be configured to simply illuminate the gap 242 between the user interface surface 220 and the rotatable member 230 (e.g., the control unit 210 may not comprise a light pipe within the gap 242). The control unit 210 may be configured to illuminate the light bar 240 to provide an indication of the present intensity level L_{PRES}, the present color temperature T_{PRES}, and/or the present color (e.g., full color) of one or more of the lighting loads.

The remote control device 200 (e.g., the control unit 210) may be configured to illuminate the light bar 240 to provide an indication of one of the present intensity level L_{PRES}, the present color temperature T_{PRES}, and/or the present color (e.g., full color) of one or more of the lighting loads depending upon the present adjustment mode of the remote control device 200 (e.g., one of the intensity-adjustment mode, the color-temperature-adjustment mode, and/or the full-color-adjustment mode). When the control unit 210 is in the intensity-adjustment mode, the control unit 210 may be configured to illuminate a portion of the light bar 240 to indicate the present intensity level L_{PRES} of the one or more lighting loads. The control unit 210 may adjust a length of the illuminated portion of the light bar 240 to indicate the present intensity level L_{PRES} of the one or more lighting loads. The length of the illuminated portion of the light bar 240 may be, for example, a function of the present intensity level L_{PRES} (e.g., proportional to the present intensity level L_{PRES}). For example, the illuminated portion of the light bar 240 may start at a bottom-center point 244 of the light bar 240 and extend around the light bar 240 in a clockwise direction. The control unit 210 may be configured to illuminate the portion of the light bar 240 to a single color (e.g., white) when indicating the intensity level of the one or more lighting loads.

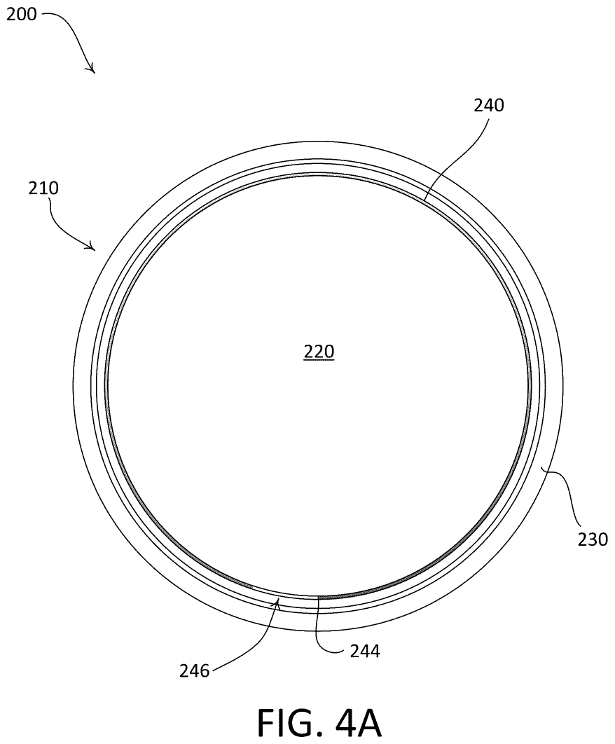

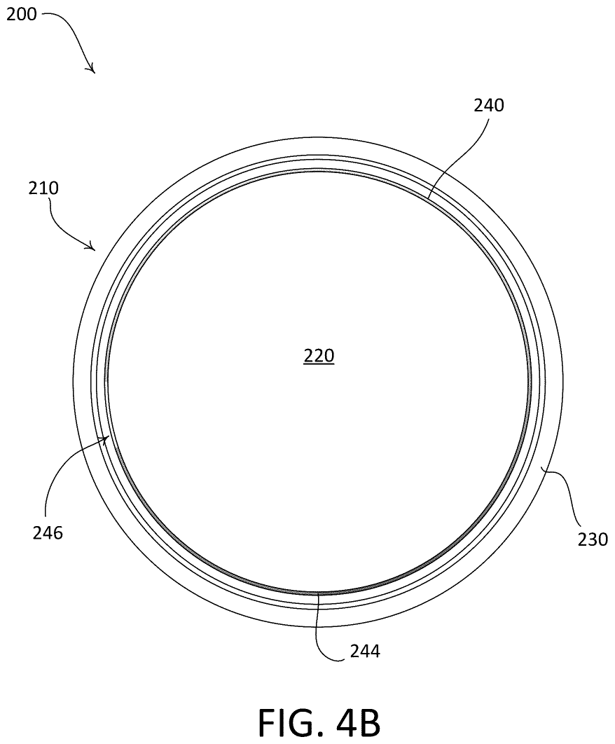

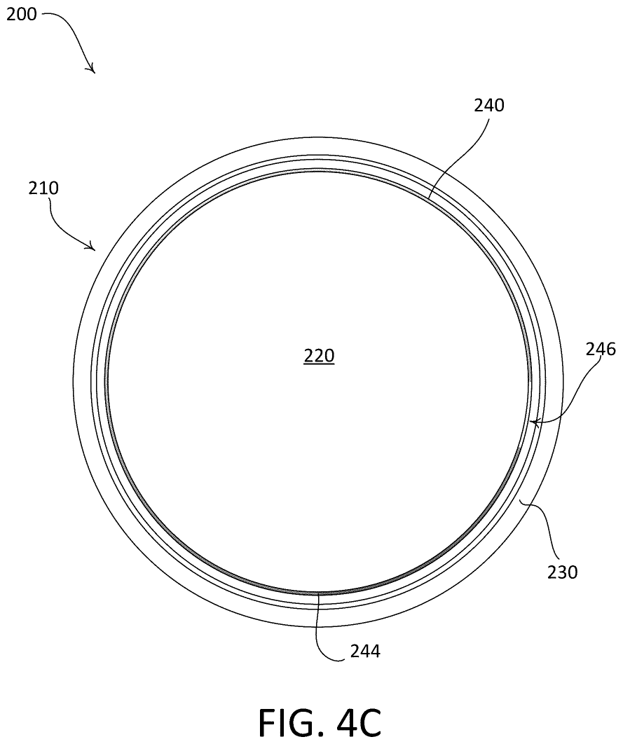

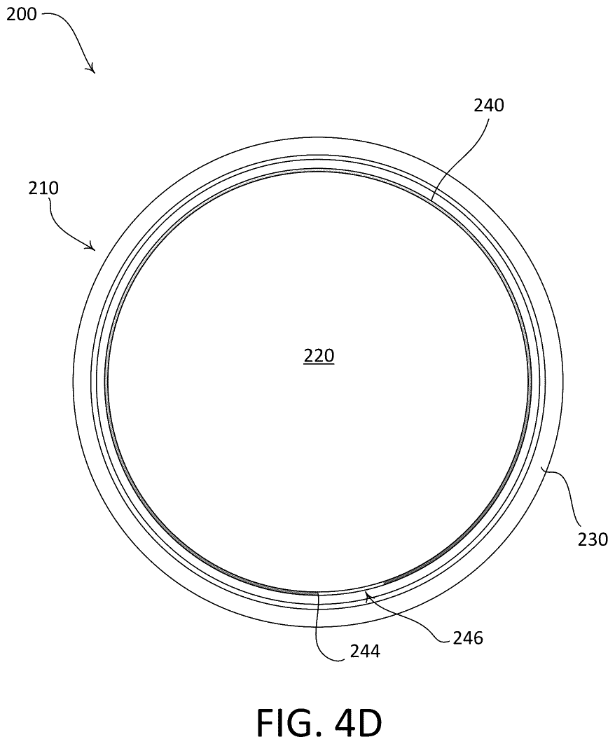

When the control unit 210 is in the color-temperature-adjustment mode, the control unit 210 may be configured to illuminate a segment (e.g., a short segment) of the light bar 240 to indicate the present color temperature T_{PRES} of the one or more lighting loads. For example, the control unit 210 may be configured to illuminate one of the light sources around the perimeter of the user interface surface 220 to illuminate the segment of the light bar 240. As previously mentioned, the control unit 210 may be configured to control the present color temperature T_{PRES} of the one or more lighting loads across the color temperature range between the warm-white color temperature T_{WW} (e.g., approximately 1500 K) and the cool-white color temperature T_{CW} (e.g., approximately 7000 K). The control unit 210 may adjust the position of the illuminated segment around the circumference of the light bar 240 starting from the bottom-center point 244 and ending at the bottom-center point 244 to indicate the present color temperature T_{PRES} of the one or more lighting loads as the present color temperature T_{PRES} ranges from the warm-white color temperature T_{WW} to the cool-white color temperature T_{CW}. In addition to illuminating the segment of the light bar 240 to indicate the present color temperature T_{PRES}, the control unit 210 may also be configured to illuminate the light bar 240 to indicate the color temperature range from the warm-white color temperature T_{WW} to the cool-white color temperature T_{CW} (e.g., behind the segment as will be described in greater detail below with reference to FIGS. 4A-4D).

The control unit 210 may be configured to determine the intensity level to indicate when in the intensity-adjustment mode or the color temperature to indicate when in the color-temperature-adjustment mode based on the present intensity level L_{PRES} or the present color temperature T_{PRES} of each of the lighting loads. For example, the control unit 210 may be configured to transmit a query message to the one or more load control devices that are associated with the remote control device 200 to determine the present intensity level L_{PRES} and/or the present color temperature T_{PRES} of each of the lighting loads. In one example, the control unit 210 may be configured to determine the present intensity level L_{PRES} and/or the present color temperature T_{PRES} of one of the lighting loads based on a first response message received in response to the transmission of the query message, and to illuminate the light bar 240 to indicate the present intensity level L_{PRES} or the present color temperature T_{PRES} as indicated in the first response message. In another example, the control unit 210 may wait for response messages from a plurality (e.g., all or most) of the load control devices to which the remote control device 200 is associated, and determine the present intensity level L_{PRES} or the present color temperature T_{PRES} to indicate based on the response messages from the plurality of the load control devices from which the response messages were received. For example, the control unit 210 may be configured to illuminate the light bar 240 to indicate a maximum value, a minimum value, or an average value of the values in the plurality of response messages. In some examples, the control unit 210 may be configured to maintain the present intensity level L_{PRES} and/or the present color temperature T_{PRES} of each of the lighting loads controlled by the load control devices associated with the remote control device 200, and may be configured to determine the present intensity level L_{PRES} and/or the present color temperature T_{PRES} to indicate based on the stored values (e.g., without transmitting query messages to the load control devices). In addition, an external device (e.g., the system controller 150) may be configured to maintain the present intensity level L_{PRES} and/or the present color temperature T_{PRES} of each of the lighting loads controlled by the load control devices, and the control unit 210 may be configured to determine the present intensity level L_{PRES} and/or the present color temperature T_{PRES} to indicate based on a message received from the external device.

When the control unit 210 is in the full-color-adjustment mode, the control unit 210 may be configured to illuminate at least a portion of the light bar 240 to indicate the present color (e.g., full color) of the one or more lighting loads. For example, the control unit 210 may be configured to illuminate the entire light bar 240 to the present full color (e.g., according the present x-chromaticity coordinate and the present y-chromaticity coordinate). The control unit 210 may be configured to illuminate the light bar 240 to indicate the last-selected color of the control unit 210 (e.g., as retrieved from memory), which may be the same as the color to which the control unit 210 is presently controlling one or more of the lighting loads.

FIGS. 4A-4D are top views of the remote control device 200 showing the light bar 240 illuminated to indicate the present color temperature T_{PRES} of one or more lighting loads that may be controlled in response to the messages transmitted by the control unit 210. The control unit 210 may be configured to control the light sources around the perimeter of the user interface surface 220 to illuminate the light bar 240 to indicate the color temperature range from the warm-white color temperature T_{WW} to the cool-white color temperature T_{CW}. The color temperature range indicated on the light bar 240 may start and stop at the center-bottom point 244. The control circuit may be configured to indicate the color temperature range by illuminating the light bar 240 to a gradient of colors that starts at a first color (e.g., a red color that represents the warm-white color temperature T_{WW}), ends at a second color (e.g., a blue color that represents the cool-white color temperature T_{CW}), and ranges from the warm-white color to the cool-white color through a white color (e.g., in the clockwise direction). The control unit 210 may be configured to illuminate one of the light sources around the perimeter of the user interface surface 220 to provide an illuminated segment 246 having a position around the circumference of the light bar 240 that indicates the present color temperature T_{PRES} of one or more lighting loads (e.g., while the remaining light sources may be illuminated to illustrate the color temperature range from the warm-white color temperature T_{WW} to the cool-white color temperature T_{CW}). The one of the light sources that is illuminated to provide the illuminated segment 246 may be illuminated a particular color, for example, white. The one of the light sources that is illuminated to provide the illuminated segment 246 that indicates the present color temperature T_{PRES} may be illuminated to a brighter level than the light sources that are illuminated to illustrate the color temperature range. As a result, the illuminated segment 246 may be illuminated bright white on top of the of the color temperature range that is illustrated on the light bar 240.

The control unit 210 may be configured to adjust the position of the illuminated segment 246 around the light bar 240 to indicate the present color temperature T_{PRES} of one or more lighting loads. For example, a number of possible positions of the illuminated segment 246 around the circumference of the light bar 240 may be equal to a number of the light sources arranged around the perimeter of the user interface surface 220. As shown in FIG. 4A, the control unit 210 may be configured to control the position of the illuminated segment 246 to a warm-white indication position to the left of the bottom-center point 244 when the present color temperature T_{PRES} is at the warm-white color temperature T_{WW}. As the present color temperature T_{PRES} of one or more lighting loads increases towards the cool-white color temperature T_{CW} (e.g., in response to clockwise rotation of the rotation member 230), the control unit 210 may be configured to adjust the position of the illuminated segment 246 in the clockwise direction around the light bar 240 (e.g., as shown in FIGS. 4B and 4C). As shown in FIG. 4D, the control unit 210 may be configured to control the position of the illuminated segment 246 to a cool-white indication position to the right of the bottom-center point 244 when the present color temperature T_{PRES} is at the cool-white color temperature T_{CW}. For example, when the present color temperature T_{PRES} is at the warm-white color temperature T_{WW} and the rotatable member 230 is rotated in the clockwise direction, the control unit 210 may adjust the position of the illuminated segment 246 in the clockwise direction from the warm-white indication position as shown in FIG. 4A to the cool-white indication position to the right of the bottom-center point 244 as shown in FIG. 4D. Similarly, when the present color temperature T_{PRES} is at the cool-white color temperature T_{CW} and the rotatable member 230 is rotated in the counter-clockwise direction, the control unit 210 may adjust the position of the illuminated segment 246 in the counter-clockwise direction from the cool-white indication position as shown in FIG. 4D to the warm-white indication position to the right of the bottom-center point 244 as shown in FIG. 4A. The control unit 210 may not be configured to control the present color temperature T_{PRES} below the warm-white color temperature T_{WW} or above the cool-white color temperature T_{CW}, such that the illuminated segment 246 may not be controlled through the bottom-center position 244 in response to continued rotation of the rotatable member 230.

While FIGS. 4A-4B shown the light bar 240 having a circular shape for displaying the indication of the present color temperature T_{PRES}, the light bar 240 could also have a linear shape and similarly display an indication of the present color temperature T_{PRES}. For example, the light bar 240 could extend linearly across the user interface surface 220 of the control unit 210. When the remote control device 200 is mounted to a vertical surface, the light bar 240 could extend linearly in a vertical direction or a horizontal direction across the user interface surface 220 of the control unit 210. The illuminated segment 246 could be controlled to a warm-white indication position at a first end of the light bar 240 when the present color temperature T_{PRES} is at the warm-white color temperature T_{WW} and to a cool-white indication position at a second end of the light bar 240 (e.g., opposite the first end) when the present color temperature T_{PRES} is at the cool-white color temperature T_{CW}. The control circuit may be configured to indicate the color temperature range by illuminating the light bar 240 to a gradient of colors that starts at a first color (e.g., a red color that represents the warm-white color temperature T_{WW}) at the first end, ends at a second color (e.g., a blue color that represents the cool-white color temperature T_{CW}) at the second end, and ranges from the warm-white color to the cool-white color through a white color (e.g., at a center of the light bar 240). The position of the illuminated segment 246 between the first end of the light bar 240 and the second end of the light bar 240 may indicate the present color temperature T_{PRES} of one or more lighting loads.

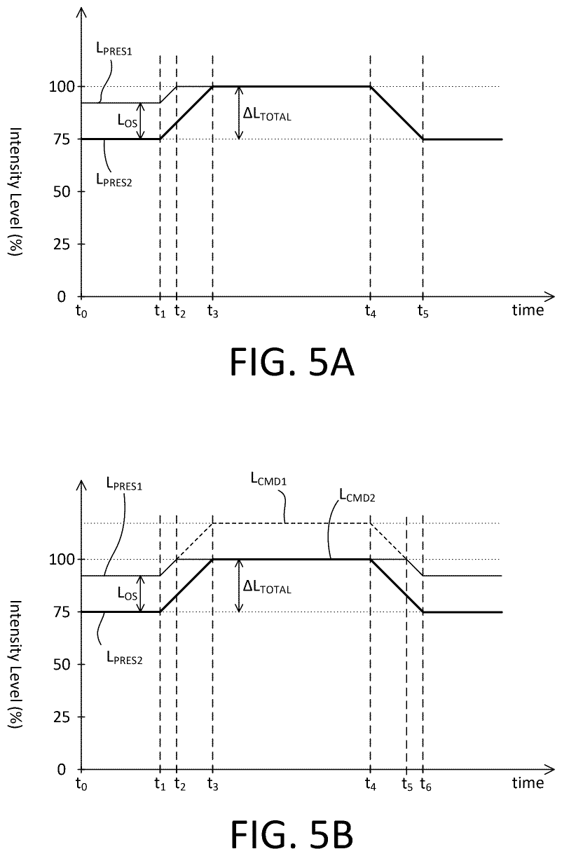

FIGS. 5A and 5B are plots illustrating present intensity levels L_{PRES1}, L_{PRES2} with respect to time of first and second lighting loads controlled by first and second load control devices, respectively, in response to receiving intensity-adjustment commands. For example, when the lighting loads are controlled in response to the selection of a scene (e.g., in response to an actuation of one of the first scene actuator 224, the second scene actuator 225, or the third scene actuator 226), the first load control device may be configured to control the present intensity level L_{PRES1} of the first lighting load to a first initial intensity level L_{INIT1}, such as approximately 90%, and the second load control device may be configured to the present intensity level L_{PRES2} of the second lighting load to a second initial intensity level L_{INIT2}, such as approximately 75% (e.g., as shown at time to in FIG. 5A). The selected scene may establish an offset Los between the present intensity level L_{PRES1} and the present intensity level L_{PRES2}.

The first and second load control devices may control the respective lighting loads in response to receiving one or more intensity-adjustment commands, which may be transmitted by a rotary remote control device (e.g., the remote control device 200) in response to a rotation of a rotatable member (e.g., the rotatable member 230) from time t₁ to time t₃ resulting in a total intensity-adjustment amount ΔL_{TOTAL} of approximately 25%. In response to receiving the one or more intensity-adjustment commands, the first and second load control devices may be configured to begin increasing the present intensity level L_{PRES1} and the present intensity level L_{PRES2}, respectively, at time t₁ (e.g., the provide relative control of the present intensity level L_{PRES1} and the present intensity level L_{PRES2}). The first and second load control devices may be configured to adjust the present intensity level L_{PRES1} and the present intensity level L_{PRES2}, respectively, with respect to time at a predefined rate (e.g., the same rate), such the offset Los between the present intensity level L_{PRES1} and the present intensity level L_{PRES2} is maintained as the present intensity level L_{PRES1} and the present intensity level L_{PRES2} both increase. However, after having controlled the present intensity level L_{PRES1} of the first lighting load to the high-end intensity level L_{HE} (e.g., approximately 100%) at time t₂, the first load control device may then maintain the present intensity level L_{PRES1} of the first lighting load at the high-end intensity level L_{HE} after time t₂ even though the second load control device continues to increase the present intensity level L_{PRES2} of the second lighting load between the times t₂ and t₃ (e.g., such that the offset L_{OS} between the present intensity level L_{PRES1} and the present intensity level L_{PRES2} is not maintained). At the end of the rotation of a rotatable member at time t₃, the second load control device may control the present intensity level L_{PRES2} of the second lighting load to the high-end intensity level L_{HE}. Since the rotatable member is not being rotated after time t₃, the first and second lighting control devices may maintain both the present intensity level L_{PRES1} of the first lighting load and the present intensity level L_{PRES2} of the second lighting load at the high-end intensity level L_{HE}.

The first and second load control devices may control the respective lighting loads in response to receiving one or more additional intensity-adjustment commands, which may be transmitted by the rotary remote control device in response to a rotation of the rotatable member from time t₄ to time t₅ resulting in a total intensity-adjustment amount ΔL_{TOTAL} of approximately −25%. Since the first and second load control devices are controlling both of the present intensity level L_{PRES1} of the first lighting load and the present intensity level L_{PRES2} of the second lighting load to the high-end intensity L_{HE} prior to time t₄, the first and second load control devices may begin to adjust the present intensity level L_{PRES1} and the present intensity level L_{PRES2} together with respect to time at the predefined rate (e.g., the same rate) from the high-end intensity L_{HE} at time t₄ to approximately 75% at time t₅. After the end of the rotation of a rotatable member at time t₅, the first and second load control devices may both maintain the present intensity level L_{PRES1} of the first lighting load and the present intensity level L_{PRES2} of the second lighting load at approximately 75% (e.g., the second initial intensity level L_{INIT2}), such that the offset L_{OS} between the present intensity level L_{PRES1} and the present intensity level L_{PRES2} is not maintained (e.g., the present intensity level L_{PRES1} and the present intensity level L_{PRES2} are not at the first initial intensity level L_{INIT1} and the second initial intensity level L_{INIT2}, respectively, to which the first and second lighting loads were controlled at time t₀). While FIG. 5A illustrates the present intensity level L_{PRES1} of the first lighting load and the present intensity level L_{PRES2} of the second lighting load being limited by the high-end intensity level L_{HE}, a similar scenario may occur near the low-end intensity level L_{LE}, where the present intensity level L_{PRES1} and the present intensity level L_{PRES2} may be limited by the low-end intensity L_{LE}.

In some examples, the first and second load control devices may be configured to adjust the present intensity level L_{PRES1} of the first lighting load and the present intensity level L_{PRES2} of the second lighting load, respectively, such that the offset Los between the present intensity level L_{PRES1} and the present intensity level L_{PRES2} (e.g., as set by a selected scene) is maintained through adjustments of the present intensity level L_{PRES1} and the present intensity level L_{PRES2} in response to intensity-adjustment commands. As shown in FIG. 5B, the first load control device may control the present intensity level L_{PRES1} of the first lighting load to a first initial intensity level L_{INIT1}, such as approximately 90%, and the second load control device may control the present intensity level L_{PRES2} of the second lighting load to a second initial intensity level L_{INIT2}, such as approximately 75% in response to the selection of a scene (e.g., as shown at time t₀), such that an offset L_{OS} exists between the present intensity level L_{PRES1} and the present intensity level L_{PRES2}.

The first and second load control devices may control the respective lighting loads in response to receiving one or more intensity-adjustment commands. The first and second load control devices may each be configured to maintain (e.g., in memory) a commanded intensity level L_{CMD}, which may be an intensity level determined from the received intensity-adjustment command (e.g., an intensity level to which the respective load control device is commanded to control the respective intensity level). In addition, the first and second load control devices may be configured to determine a controlled intensity level L_{CNTL}, which may be an intensity level to which the lighting load is controlled (e.g., is actually controlled). The first and second load control devices may be configured to determine the controlled intensity level L_{CNTL} based on the commanded intensity level L_{CMD}. The controlled intensity level L_{CNTL} may be, for example, the same as the commanded intensity level L_{CMD}, but may be limited by the high-end intensity level L_{HE} and the low-end intensity level L_{LE}. The first load control device may be configured to maintain a first commanded intensity level L_{CMD1} and a first controlled intensity level L_{CNTL1}, and the second load control device may be configured to maintain a second commanded intensity level L_{CMD2} and a second controlled intensity level L_{CNTL2}. For example, at time to of FIG. 5B, the present intensity level L_{PRES1} of the first lighting control device may be equal to the first controlled intensity level L_{CNTL1} (e.g., the first initial intensity level LI_{NIT1}), and the present intensity level L_{PRES2} of the second lighting control device may be equal to the second controlled intensity level L_{CNTL2} (e.g., the second initial intensity level L_{INIT2}). Since the present intensity level L_{PRES1} of the first lighting load and the present intensity level L_{PRES2} of the second lighting load are not being limited by the high-end intensity level L_{HE} at time t₀, the first controlled intensity level L_{CNTL1} may be equal to the first commanded intensity level L_{CMD1}, and the second controlled intensity level L_{CNTL2} may be equal to the second commanded intensity level L_{CMD2} at time t₀.

The first and second load control devices may receive one or more intensity-adjustment commands from the rotary remote control device (e.g., the remote control device 200) in response to a rotation of the rotatable member (e.g., the rotatable member 230) from time t₁ to time t₃ resulting in a total intensity-adjustment amount ΔL_{TOTAL} of approximately 25%. When a first one of the one or more intensity-adjustment commands is received at approximately time t₁, the first and second load control devices may determine the first commanded intensity level L_{CMD1} and the second commanded intensity level L_{CMD2}, respectively, based on an intensity-adjustment amount ΔL of the received intensity-adjustment command. For example, at time t₁, the first load control device may be configured to determine the first commanded intensity level L_{CMD1} by adding the intensity-adjustment amount ΔL to the present value of the first commanded intensity level L_{CMD1} (e.g., L_{CMD1}=L_{CMD1}+ΔL) and the second load control device may be configured to determine the second commanded intensity level L_{CMD2} by adding the intensity-adjustment amount ΔL to the present value of the second commanded intensity level L_{CMD2} (e.g., L_{CMD2}=L_{CMD2}+ΔL). Since the updated values of the first commanded intensity level L_{CMD1} and the second commanded intensity level L_{CMD2} may both be less than the high-end intensity level L_{HE} at time t₁, the first controlled intensity level L_{CNTL1} and the second controlled intensity level L_{CNTL2} may be equal to the first commanded intensity level L_{CMD1} and the second commanded intensity level L_{CMD2}, respectively.

Based on the updated values of the first commanded intensity level L_{CMD1} and the second commanded intensity level L_{CMD2}, respectively, the first and second load control devices may be configured to begin increasing the present intensity level L_{PRES1} and the present intensity level L_{PRES2}, respectively, at time t₁ (e.g., based on the first controlled intensity level L_{CNTL1} and the second controlled intensity level L_{CNTL2}). Between time t₁ and time t₂, the first commanded intensity level L_{CMD1} and the second commanded intensity level L_{CMD2} may both be less than the high-end intensity level L_{HE}, such that the first controlled intensity level L_{CNTL1} and the second controlled intensity level L_{CNTL2} may remain equal to the first commanded intensity level L_{CMD1} and the second commanded intensity level L_{CMD2}, respectively. The first and second load control devices may be configured to adjust the present intensity level L_{PRES1} and the present intensity level L_{PRES2}, respectively, between time t₁ and time t₂ with respective to time at the predefined rate (e.g., the same rate), such the offset L_{OS} between the present intensity level L_{PRES1} and the present intensity level L_{PRES2} is maintained as the present intensity level L_{PRES1} and the present intensity level L_{PRES2} both increase.

At time t₂, the present intensity level L_{PRES1} of the first lighting load (e.g., and the first commanded intensity level L_{CMD1}) may become equal to the high-end intensity level L_{HE}. Between time t₂ and time t₃, the first load control device may be configured to limit the first controlled intensity level L_{CNTL1} to the high-end intensity level L_{HE}, but may continue to increase the first commanded intensity level L_{CMD1} in response to the one or more received intensity-adjustment commands (e.g., above the high-end intensity level L_{HE}) as shown in FIG. 5B. In addition, the second load control device may continue to increase both the second commanded intensity level L_{CMD2} and the second controlled intensity level L_{NTL2} with respect to time between time t₂ and time t₃ since the second commanded intensity level L_{CMD2} is less than the high-end intensity level L_{HE}. After the end of the rotation of the rotatable member of the rotary remote control device at time t₃, the first and second load control devices may maintain both of the present intensity level L_{PRES1} of the first lighting load and the present intensity level L_{PRES2} of the second lighting load at the high-end intensity level L_{HE} even though the first commanded intensity level L_{CMD1} may be greater than the second commanded intensity level L_{CMD2}. For example, the offset L_{OS} may be maintained between the first commanded intensity level L_{CMD1} and the second commanded intensity level L_{CMD2} after time t₃ even though the first controlled intensity level L_{CNTL1} may be equal to the second controlled intensity level L_{CNTL2} (e.g., with both equal to the high-end intensity level L_{HE}).

The first and second load control devices may receive one or more additional intensity-adjustment commands from the rotary remote control device in response to a rotation of the rotatable member from time t₄ to time t₆ resulting in a total intensity-adjustment amount ΔL_{TOTAL} of approximately −25%. When a first one of the additional one or more intensity-adjustment commands is received at approximately time t₄, the first and second load control devices may determine the first commanded intensity level L_{CMD1} and the second commanded intensity level L_{CMD2}, respectively, based on an intensity-adjustment amount ΔL of the received intensity-adjustment command (e.g., which may be negative). Between time t₄ and time t₅, the first load control device may continue to limit the first controlled intensity level L_{CNTL1} to the high-end intensity level L_{HE}, while decreasing the first commanded intensity level L_{CMD1} in response to the one or more received intensity-adjustment commands (e.g., as shown in FIG. 5B). In addition, the second load control device may decrease both the second commanded intensity level L_{CMD2} and the second controlled intensity level L_{NTL2} with respect to time between time t₄ and time t₅ since the second commanded intensity level L_{CMD2} is less than the high-end intensity level L_{HE}.

After time t₅, the present intensity level L_{PRES1} of the first lighting load (e.g., and the first commanded intensity level L_{CMD1}) may be less than the high-end intensity level L_{HE}, such that the first load control device may begin decreasing the first controlled lighting intensity L_{CNTL1} (e.g., and the present intensity level L_{PRES1} of the first lighting load) with respect to time below the high-end intensity level L_{HE}. Between time t₅ and time t₆, the first commanded intensity level L_{CMD1} and the second commanded intensity level L_{CMD2} may both be less than the high-end intensity level L_{HE}, such that the first controlled intensity level L_{CNTL1} and the second controlled intensity level L_{CNTL2} may remain equal to the first commanded intensity level L_{CMD1} and the second commanded intensity level L_{CMD2}, respectively. The first and second load control devices may be configured to adjust the present intensity level L_{PRES1} and the present intensity level L_{PRES2}, respectively, with respect to time between time t₅ and time t₆ at the predefined rate (e.g., the same rate), such the offset L_{OS} between the present intensity level L_{PRES1} and the present intensity level L_{PRES2} is maintained as the present intensity level L_{PRES1} and the present intensity level L_{PRES2} both decrease.

After the end of the rotation of the rotatable member at time t₆, the first and second load control devices may stop adjusting the present intensity level L_{PRES1} of the first lighting load and the present intensity level L_{PRES2} of the second lighting load, respectively. Since the first commanded intensity level L_{CMD1} is allowed to rise above the high-end intensity level L_{HE} (e.g., between time t₂ and time t₅), the present intensity level L_{PRES1} of the first lighting load and the present intensity level L_{PRES2} of the second lighting load may be returned to the first initial intensity level L_{INIT1} and the second initial intensity level L_{INIT2}, respectively, and the offset Los between the present intensity level L_{PRES1} of and the present intensity level L_{PRES2} may be maintained through the adjustment of the present intensity level L_{PRES1} of and the present intensity level L_{PRES2}. While FIG. 5B illustrates the present intensity level L_{PRES1} of the first lighting load and the present intensity level L_{PRES2} of the second lighting load being limited by the high-end intensity level L_{HE}, the first and second load control devices may be configured to operate such that a similar scenario may occur near the low-end intensity level L_{LE}, where the present intensity level L_{PRES1} and the present intensity level L_{PRES2} may be limited by the low-end intensity L_{LE}.

As described with reference to FIG. 5B, the first and second load control devices may be configured to control the present intensity level L_{PRES1} of the first lighting load and the present intensity level L_{PRES2} of the second lighting load according to the first controlled intensity level L_{CNTL1} and the second controlled intensity level L_{CNTL2}, which may be based on the first commanded intensity level L_{CMD1} and the second commanded intensity level L_{CMD2}. A similar control technique could be used to allow the first and second load control devices to control a present color temperature T_{PRES1} of the first lighting load and a present color temperature T_{PRES2} of the second lighting load according to a first controlled color temperature T_{CNTL1} and a second controlled color temperature T_{CNTL2}, which may be based on a first commanded color temperature T_{CMD1} and the second commanded color temperature T_{CMD2}. For example, each of the first and second load control devices may be configured to limit each of the first and second controlled color temperatures T_{CNTL1}, T_{CNTL2} to the warm-white color temperature T_{WW} and the cool-white color temperature T_{CW} (e.g., and not limit the commanded intensity level L_{CMD1} and the second commanded intensity level L_{CMD2}).

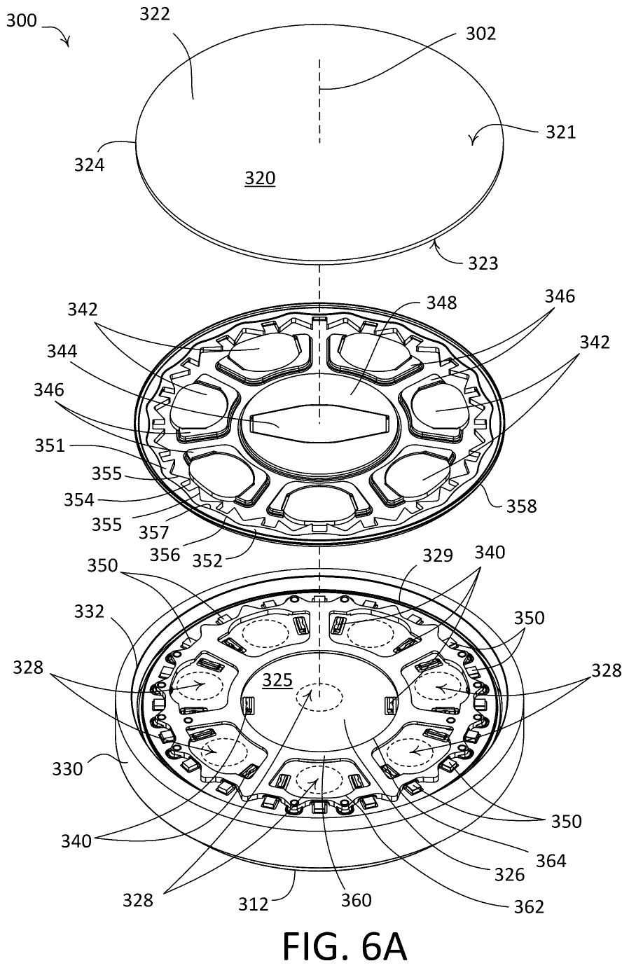

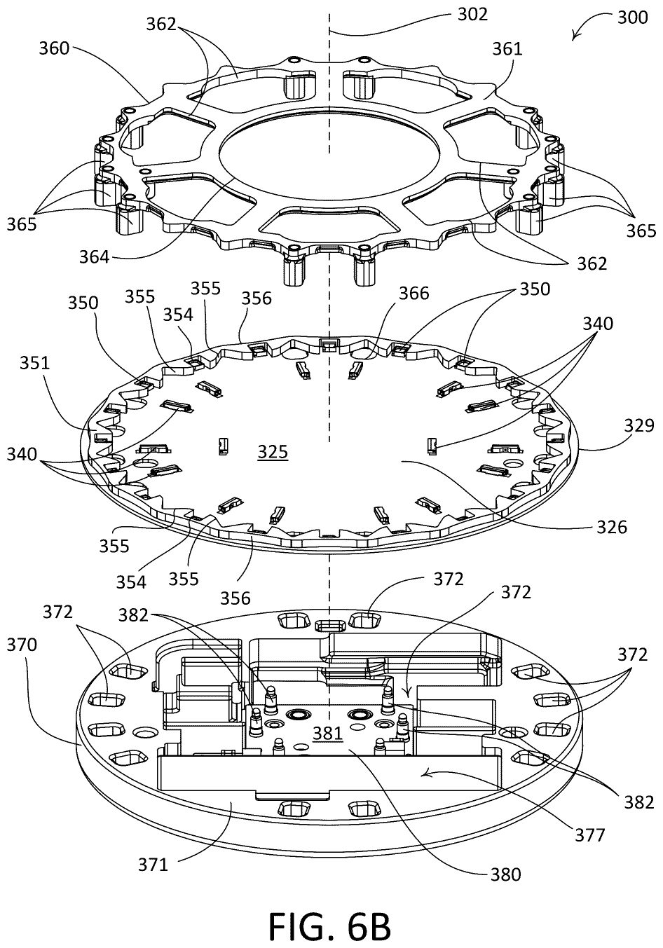

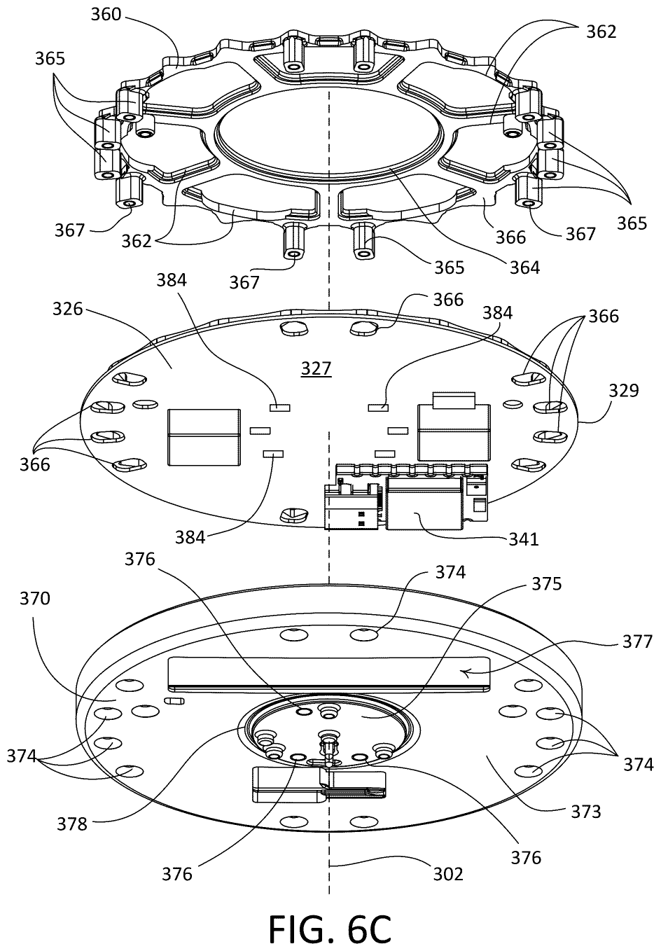

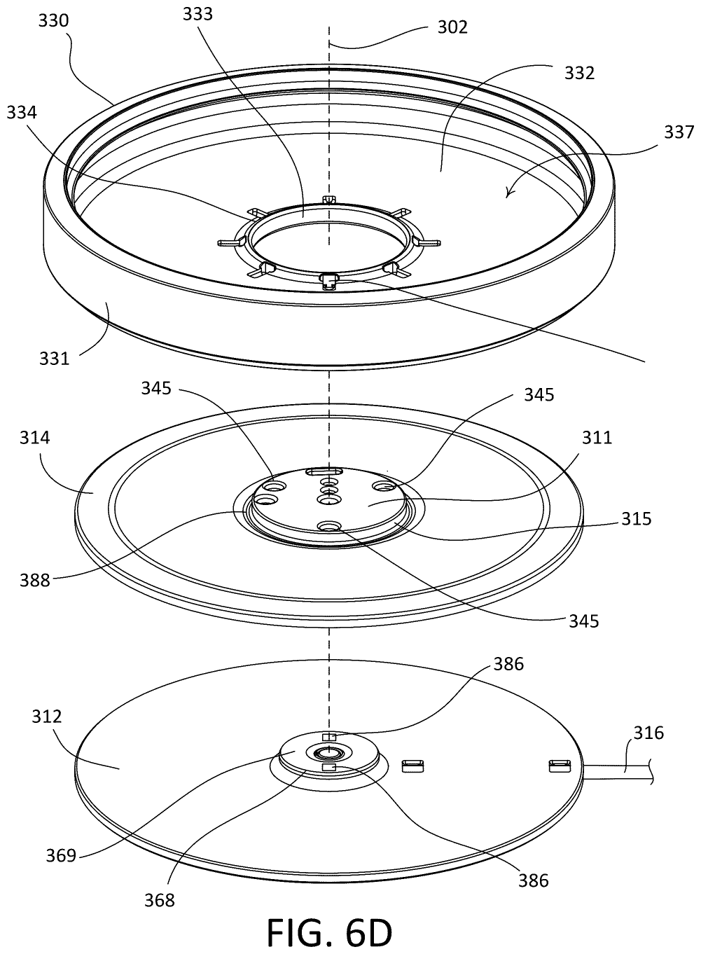

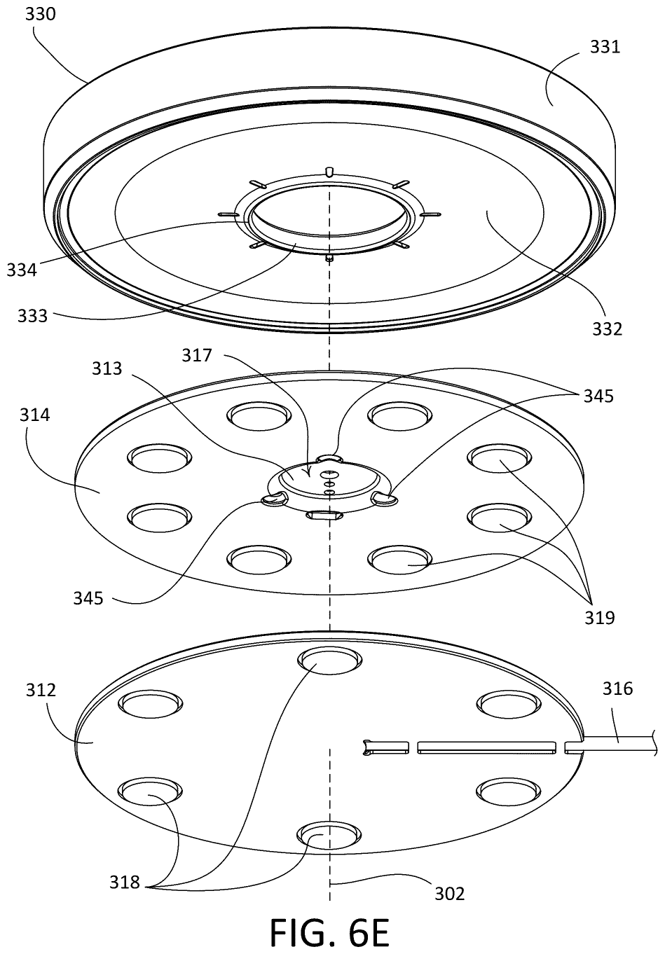

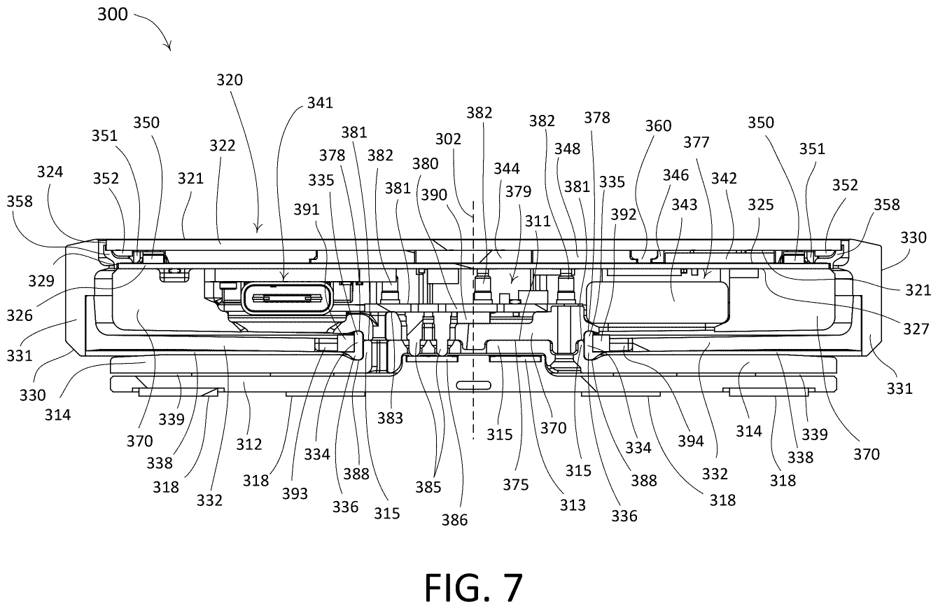

FIGS. 6A-7 illustrate an example control device 300 (e.g., a remote control device), which may be deployed as one of the input control devices of the load control system 100 of FIG. 1 (e.g., the tabletop remote control device 140, the wall-mounted remote control device 142, the handheld remote control device 144, and/or the retrofit remote control device 146) and/or the remote control device 200 of FIGS. 2-3. FIG. 6A is a partially exploded view of the control device 300. FIG. 7 is a side cross-section view of the control device 300 (e.g., taken through the line shown in FIG. 2B). The remote control device 300 may be configured to transmit messages to one or more load control devices (e.g., the dimmer switch 110, the LED driver 120, and/or the controllable light source 130) for controlling respective lighting loads (e.g., the lighting load 112, the LED light source 122, and/or the LED light source of the controllable light source 130). The remote control device 300 may operate in a similar manner as the remote control device 200 described above.

The remote control device 300 may comprise a control unit 310 configured to be supported by a base 312. The remote control device 300 (e.g., the control unit 310) may comprise a user interface surface 320 and a rotatable member 330 (e.g., a circular rotatable member or a rotary knob). The remote control device 300 (e.g., the control unit 310) may define an axis 302 (e.g., a central axis) that may extend through a center of the user interface surface 320 and the rotatable member 330. For example, the user interface surface 320 may be circular in shape (e.g., define a circular periphery). The user interface surface 320 may comprise a plate 322 (e.g., a circular plate), which may be made of, for example, plastic. The user interface surface 320 (e.g., the plate 322) may define a perimeter 324 (e.g., a circular perimeter 324). The rotatable member 330 may be circular in shape (e.g., to match the circular periphery of the user interface surface 320). The rotatable member 330 may be rotatable with respect to the user interface surface 320 (e.g., the rotatable member 330 may be configured to rotate about the user interface surface 320). The rotatable member 330 may be configured to surround the user interface surface 320 (e.g., around the perimeter 324 of the plate 322).

The control unit 310 may also comprise a support plate 314 that may rest on the base 312 (e.g., as shown in FIG. 7). The control unit 310 may be configured to receive power via the base 312. For example, the base 312 may be electrically coupled to a power source, such as a direct-current (DC) power source, via an electrical cord 316 (e.g., such as the electrical cord 216), and the control unit 310 may be configured to charge via the base 312. The base 312 may comprise feet 318 that may rest on a horizontal surface (e.g., a table top). For example, feet 318 may comprise a rubber material such that the base 312 and the support plate 314 of the control unit 310 do not move when the rotatable member 330 is rotated.

The user interface surface 320 may be, for example, a touch sensitive surface (e.g., a capacitive touch surface), which may be actuated to allow the control unit 310 to receive inputs (e.g., touch actuations and/or touch inputs). The user interface surface 320 may be configured to provide one or more actuators (e.g., virtual actuators, such as the actuators 221-228 shown in FIG. 3) on a top surface 321 of the plate 322. The control unit 310 may comprise a first printed circuit board (PCB) 326 having one or more capacitive touch pads 328 that may be located on a front side 325 of the first printed circuit board 326 behind the user interface surface 320 for receiving “touch” actuations (e.g., taps) of the actuators provided on the user interface surface 320. The first printed circuit board 326 may be oriented in a plate that is substantially parallel to a plane of the plate 322 of the user interface surface 320. The first printed circuit board 326 may have a diameter that approximately equal to a diameter of the plate 322 of the user interface surface 320. For example, the touch actuations (e.g., taps) may be actuations of the user interface surface 320 (e.g., the actuators) that do not cause the user interface surface 320 to move (e.g., be pressed in towards the base 312, pivot, and/or otherwise move). For example, the control unit 310 may comprise a respective one of the capacitive touch pads 328 behind each of the actuators.

The position of each of the actuators on the user interface surface 320 may be identified by a respective icon (e.g., such as the icons 231-238 shown in FIG. 3). The control unit 310 may be configured to illuminate the user interface surface 320 to display the icons. For example, the plate 322 may be made of a transparent or translucent material, and a rear surface 323 of the plate 322 may be painted to produce an opaque layer of paint (e.g., black paint) on the rear surface 323. The icons may be cut (e.g., etched) into the opaque layer of paint on the rear surface 323 of the plate 322 and may be illuminated from below the plate 322 to make the icons appear on the user interface surface 320. When the icons are not illuminated, the icons may disappear from view (e.g., as shown in FIG. 2A). The control unit 310 may be configured to cease illuminating the icons when the control unit 310 is in an idle state (e.g., after a predetermined amount of time since the user interface surface 320 and/or the rotatable member 330 were last actuated). The control unit 310 may be configured to illuminate the icons to indicate the positions of the actuators on the user interface surface 320 when the control unit 310 is in the idle state and the user interface surface 320 and/or the rotatable member 330 is actuated and/or when a user's finger moves in close proximity to the top surface 321 of the user interface surface 320.

The control unit 310 may comprise, for example, one or more light sources 340 (e.g., light-emitting diodes) mounted to the first printed circuit board 326 (e.g., to the front side 325 of the first printed circuit board 326) adjacent to the capacitive touch pads 328 for illuminating (e.g., selectively illuminating) the icons on the user interface surface 320. For example, the light sources 340 may comprise side-firing LEDs. The control unit 310 may also comprise one or more light pipes 342 that are located behind the actuators on the user interface surface 320 that are arranged along the perimeter 324 of the user interface surface 320 (e.g., the actuators 221-226 and 228) and a light pipe 344 that is located behind the actuator at the center of the user interface surface 320 (e.g., the toggle actuator 227). For example, the light pipes 342, 344 may be made of a transparent or translucent material, and may be configured to conduct light from the light sources 340 to the illuminate the icons on the user interface surface 320 above the respective light pipes 342, 344. The light pipes 342, 344 may be located above the respective capacitive touch pads 328. The light pipes 342, 344 may each be illuminated by two of the light sources 340. For example, the light sources 340 may be configured to illuminate the light pipes 342, 344 from the sides for illuminating the icons on the user interface surface 320 above the respective light pipes 342, 344.

The control unit 310 may also comprise one or more caps 346 located overtop of the light sources 340 and adjacent to the light pipes 342. The one or more caps 346 may be located behind the actuators arranged along the perimeter 324 of the user interface surface 320. The control unit 310 may also comprise a cap 348 located overtop of the light sources 340 adjacent to the light pipe 344 located behind the actuator in the center of the user interface surface 320. The caps 346, 348 may be configured to ensure that the light emitted by the light sources 340 shines on the light pipes 342, 344 for illuminating the icons on the user interface surface 320 (e.g., to prevent light emitted by the light sources 340 from shing directly up to the user interface surface 320 and generating bright spots on the user interface surface 320).

The remote control device 300 (e.g., the control unit 310) may also comprise a light bar (e.g., such as the light bar 240) located adjacent to the perimeter 324 of the user interface surface 320. For example, the light bar may be circular in shape and may be displayed on the user interface surface 320. The light bar may be, for example, cut (e.g., etched) into the opaque layer of paint on the rear surface 323 of the plate 322 and may be illuminated from below the plate 322 to make the light bar appear on the user interface surface 320. The control unit 310 may comprise one or more light sources 350 (e.g., light-emitting diodes) mounted to the first printed circuit board 326 (e.g., to the front side 325 of the first printed circuit board 326) for illuminating the light bar. The light sources 350 may comprise, for example, side-firing LEDs. For example, the control unit 310 may comprise a number N_{LED} of light sources (e.g., approximately 20 light sources) surrounding a perimeter 329 of the first printed circuit board 326 (e.g., behind the user interface surface 320) for illuminating the light bar. The control unit 310 may be configured to illuminate the light bar to provide an indication of a present intensity level L_{PRE}S, a present color temperature T_{PRES}, and/or a present color (e.g., full color) of one or more of the lighting loads.

The control unit 310 may comprise a light pipe structure 351 located behind the user interface surface 320 between the light sources 350 and the perimeter 329 of the first printed circuit board 326. For example, the light pipe structure 351 may be made of a transparent or translucent material. As shown in FIG. 6A, the light pipe structure 351 may form a circle around the perimeter 329 of the first printed circuit board 326. As shown in FIG. 7, the control unit 310 may comprise a diffuser 352 located behind the user interface surface 320 between the light pipe structure 351 and the perimeter 329 of the first printed circuit board 326. While not shown in the drawings, the diffuser 352 may also form a circle around the perimeter 329 of the first printed circuit board 326. For example, the diffuser 352 may be made of a diffusive material. The diffuser 352 may be configured to conductive light from the light pipe structure 351 to illuminate the light bar on the user interface surface 320. The light pipe structure 351 may comprise a number (e.g., the number N_{LED}) of notches 354 in which the light sources 350 may be located, such that the light sources 350 shine towards the light pipe structure 351. The light pipe structure 351 may also comprise angled surfaces 355 on each side of each of the notches 354. The angled surfaces 355 may be configured to reflect light from the light source 350 in the adjacent notch 354 towards the diffuser 352. The light pipe structure 351 may also comprise curved surfaces 356 located adjacent to each of the notches 354 on the other side of the light pipe structure 351. The diffuser 352 may comprise curved surfaces 357 that interface with (e.g., abut) the curved surfaces 356 of the light pipe structure 351. The curved surfaces 356 of the light pipe structure 351 and the curved surfaces 357 of the diffuser 352 may each be configured to spread the light from the light source 350 in the adjacent notch 354 to even out the distribution of light received by the diffuser 352.

The control unit 310 may further comprise a light blocking member 358 that may be configured to prevent light from the light sources 350 from shining into a gap between the perimeter 324 of the plate 322 of the user interface surface 320 and the rotatable member 330 (e.g., such as the gap 242). For example, the light blocking member 358 may form a circle around the perimeter 324 of the plate 322 of the user interface surface 320. As shown in FIG. 7, the light blocking member 358 may extend from the light pipe structure 351 under the diffuser 352 and around the perimeter 324 of the plate 322 of the user interface surface 320. For example, the light blocking member 358 may be supported by the first printed circuit board 326. In some examples, the control unit 210 may be configured to illuminate the gap between the user interface surface 320 and the rotatable member 330 (e.g., the gap may operate as a light bar, the diffuser 352 and the light blocking member 358 may be omitted, and the light bar may not be etched into the opaque layer of paint on the rear surface 323 of the plate 322). In addition, the control unit 310 may also comprise a light pipe (e.g., a diffuser) that may be located within the gap between the user interface surface 320 and the rotatable member 330 and may be illuminated by the light sources 350. In some examples, the control unit 310 may be configured to simply illuminate the gap between the user interface surface 320 and the rotatable member 330.

The user interface surface 320 and the rotatable member 330 may be supported by the support plate 314 of the control unit 310. The control unit 310 may comprise a support frame 360 and a carrier 370. FIG. 6B is a partial front exploded view and FIG. 6C is a partial rear exploded view of the remote control device 300 showing the support frame 360, the first printed circuit board 326, and the carrier 370. The support frame 360 may be located over the first printed circuit board 326. The user interface surface 320 (e.g., the rear surface 323 of the plate 322) may be attached (e.g., adhered) to a front surface 361 of the support frame 360 (e.g., using an adhesive, such as double-sided tape). The support frame 360 may comprise openings 362 that may be located above the capacitive touch pads 328 behind the actuators arranged along the perimeter 324 of the user interface surface 320. The light pipes 342 and the caps 346 may be located in the openings 362 of the support frame 360. The support frame 360 may also comprise an opening 364 (e.g., a central opening) located above the capacitive touch pad 328 behind the actuator at the center of the user interface surface 320. The light pipe 344 and the cap 348 may be located in the opening 364 of the support frame 360.

The support frame 360 may be connected to (e.g., may be supported by) the carrier 370. The support frame 360 may comprise posts 365 that extend from a rear surface 363 of the support plate 314 towards the carrier 370. The posts 365 may extend through respective openings 366 in the first printed circuit board 326 and respective recesses 372 in the carrier 370 (e.g., in a front surface 371 of the carrier 370). For example, the support frame 360 may be connected to the carrier 370 via fasteners (e.g., screws—not shown) that may be received through openings 374 in the carrier 370 (e.g., in a rear surface 373 of the carrier 370) and bores 367 (e.g., threaded bores) in the posts 365 (e.g., when the posts 365 are received in the recesses 372). The first printed circuit board 326 may be captured between the support frame 360 and the carrier 370 (e.g., as shown in FIG. 7). For example, the first printed circuit board 326 may be configured to contact the front surface 371 of the carrier 370. Control circuitry of the control unit 310 may be mounted to the first printed circuit board 326. For example, the control unit 310 may comprise a communication module 341 mounted to a rear side 327 of the first printed circuit board 326 (e.g., such that the communication module 341 is located between the first printed circuit boards 326 and the carrier 370).

The support plate 314 may support (e.g., contact) the carrier 370. The carrier 370 may define an interface portion 375 (e.g., located in a center of the rear surface 373 of the carrier 370). The support plate 314 may define a raised portion 315 (e.g., a cylindrical drum) having a front surface 311 (e.g., a central front surface). For example, the interface portion 375 of the carrier 370 may have a circular shape and may have a diameter that is approximately equal to a diameter of the raised portion 315. For example, the interface portion 375 of the carrier 370 may rest on the front surface 311 of the raised portion 315 of the support plate 314. The carrier 370 (e.g., the interface portion 375) may be connected to the support plate 314 (e.g., the raised portion 315). For example, the carrier 370 may be connected to the support plate 314 via fasteners (e.g., screws—not shown) that may be received through openings 345 in the support plate 314 and openings 376 in the carrier 370.

The control unit 310 may comprise a second printed circuit board 380 that is supported by the carrier 370 and is located between the first printed circuit board 326 and the carrier 370. The second printed circuit board 380 may be electrically connected to the first printed circuit board 326, for example, via two or more electrical connectors 382 (e.g., pogo pins). For example, the electrical connectors 382 may be mechanically and electrically connected to a front side 381 of the second printed circuit board 380. The electrical connectors 382 may extend from the second printed circuit board 380 towards the first printed circuit board 326 and may be configured to contact electrical pads 386 on the rear side 327 of the first printed circuit board 326. The control unit 310 (e.g., the carrier 370) may comprise a compartment 377 configured to receive a battery 343. The battery 343 may be configured to be electrically connected to the second printed circuit board 380. As shown in FIG. 7, the second printed circuit board 380 may be located in a cavity 379 of the carrier 370 between the communication module 341 and the battery 343 (e.g., the compartment 377 in the carrier 370).

FIG. 6D is a front partial exploded view and FIG. 6E is a rear partial exploded view of the remote control device 300 showing the base 312, the support plate 314, and the rotatable member 330. The support plate 314 of the control unit 310 may be supported by (e.g., mounted on) the base 312. The base 312 may comprise a raised portion 368 (e.g., a cylindrical drum) that defines a front surface 369 (e.g., a raised front surface). The support plate 314 may define a depression 317 in which a rear surface 313 (e.g., a rear central surface) of the support plate 314 is located. For example, the rear surface 313 of the support plate 314 may be configured contact (e.g., rest on) a front surface 311 (e.g., a central front surface) of the base 312. The support plate 314 may comprise feet 319 that rest on the base 312 when the control unit 310 is mounted to the base 312.

The second printed circuit board 380 may be electrically connected to the base 312 via two or more electrical connectors 385 (e.g., pogo pins) when the control unit 310 is mounted to the base 312. For example, the electrical connectors 385 may be mechanically and electrically connected to a rear side 383 (FIG. 7) of the second printed circuit board 380 and may extend towards the base 312. When the control unit 310 is mounted to the base 312, the electrical connectors 385 may contact one or more electrical pads 386 on the front surface 369 of the raised portion 368 of the base 312, such that the battery 343 may be configured to charge via the base 312 (e.g., from the power source through the electrical cord 316). When the control unit 310 is removed from the base 312, the second printed circuit board 380 may be disconnected from the base 312 (e.g., from the power source) and the electrical connectors 385 (e.g., the pogo pins) may be configured to extend. When the control unit 310 is placed on the base 312, the electrical connectors 385 (e.g., the pogo pins) may contract when the electrical connectors 385 contact the electrical pads 386.

The rotatable member 330 may be captured between the carrier 370 and the support plate 314, and may be rotatable with respect to the carrier 370 and the support plate 314. The rotatable member 330 may be circular in shape. The rotatable member 330 may define an outer rim 331 (e.g., a circular rim) that may be actuated by a user for rotating the rotatable member 330. The rotatable member 330 may comprise a disc portion 332 that may extend from the outer rim 331 towards the axis 302 (e.g., the center of the control unit 310). The disc portion 332 may terminate at an inner rim 334 (e.g., a circular ring) that defines a central opening 333 (e.g., a circular central opening) of the rotatable member 330. The inner rim 334 may encircle the axis 302 of the control unit 310. The inner rim 334 may define a first lip 335 (e.g., a front circular lip) and a second lip 336 (e.g., a rear circular lip), which may both also encircle the axis 302. The first lip 335 and the second lip 336 may define circularly-shaped cross-sections (e.g., as shown in FIG. 7). The outer rim 311 and the disc portion 332 of the rotatable member 330 may define a cavity 337 in which the user interface surface 320, the first printed circuit board 326, the support frame 360, the carrier 370, and the second printed circuit board 380 may be contained.

The support plate 314 may define a groove 388 (e.g., a circular track or channel) that is located adjacent to and encircles the raised portion 315 of the support plate 314, and is centered about the axis 302. The carrier 370 may also comprise a groove 378 (e.g., a circular track or channel) that is located in the rear surface 373 and is centered about the axis 302. The groove 388 of the support plate 314 and the groove of the 378 of the carrier 370 may both define curved cross-sections (e.g., as shown in FIG. 7). The first lip 335 of the inner rim 334 of the rotatable member 330 may be received in the circular groove 378 of the carrier 370 (e.g., the groove 378 may be a front groove). The second lip 336 of the inner rim 334 of the rotatable member 330 may be received in the groove 388 of the support plate 314 (e.g., the groove 378 may be a rear groove). The inner rim 334 of the rotatable member 330 may be captured (e.g., clamped) between the groove 388 of the support plate 314 and the groove 378 of the carrier 370, such that the inner rim 334 of the rotatable member 330 contacts (e.g., only contacts) the carrier 370 and the support plate 314 at the first lip 335 and the second lip 336, respectively. The rotatable member 330 may be supported by the support plate 314 and the carrier 370 at (e.g., only at) the inner rim 334 of the rotatable member 330, such that a first gap 338 is defined between the support plate 314 and the disc portion 332 of the rotatable member 330 and a second gap 339 is defined between the carrier 370 and the disc portion 332 of the rotatable member 330 (e.g., as shown in FIG. 7). The second lip 336 of the inner rim 334 of the rotatable member 330 may be configured to slide through the groove 388 of the support plate 314 and the first lip 335 of the inner rim 334 of the rotatable member 330 may be configured to slide through the groove 378 of the carrier 370. For example, the groove 388 of the support plate 314 and the circular groove 378 of the carrier 370 may be filled with a lubricant (e.g., grease) to facilitate sliding of the first lip 335 and the second lip 336 of the inner rim 334 of the rotatable member 330.

As shown in FIG. 7, the control unit 310 may further comprise a magnetic sensor 390 that may be used by the control unit 310 (e.g., the control circuitry mounted to the first printed circuit board 326) to determine a direction and/or an amount of rotation of the rotatable member 330. For example, the magnetic sensor 390 may be mounted to the rear side 383 of the second printed circuit board 380 and may be electrically coupled to the control circuitry on the first printed circuit board 326 via the electrical connectors 384. The control unit 310 may also comprise a first magnet 391 and a second magnet 392 that are both attached to the rotatable member 330. For example, the first magnet 391 may be located in a first cavity 393 adjacent to the inner rim 334 on one side of the rotatable member 330, and the second magnet 392 may be located in a second cavity 394 adjacent to the inner rim 334 on the other side of the rotatable member 330. For example, the first magnet 391 may be a positive pole magnet (e.g., a north pole magnet) and the second magnet 392 may be a negative pole magnet (e.g., a south pole magnet). The magnetic sensor 390 may be configured to detect the changing magnetic field generated by the first and second magnets 391, 392 as the rotatable member 330 rotates. The control circuitry of the control unit 310 may be configured to determine the direction and/or the amount of rotation of the rotatable member 330 in response to the changing magnetic field generated by the first and second magnets 391, 392 (e.g., in response to the magnetic sensor 390).

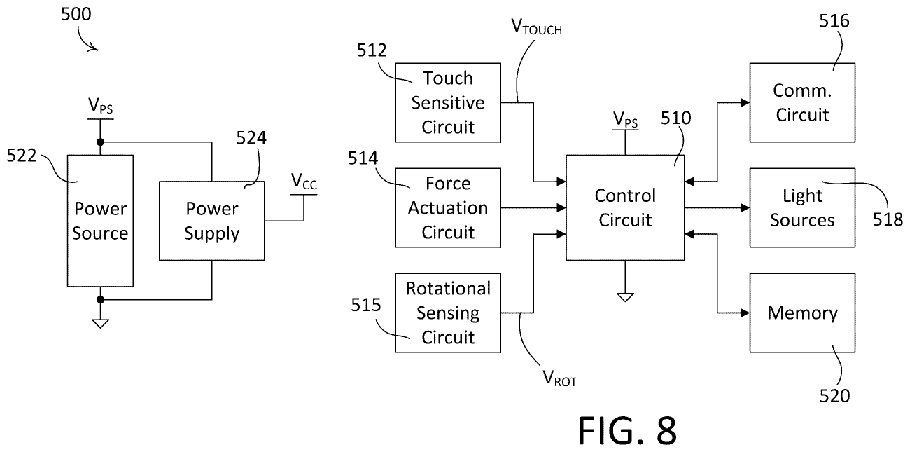

FIG. 8 is a block diagram of an example control device 500 (e.g., a remote control device), which may be deployed as one of the input control devices of the load control system 100 of FIG. 1 (e.g., the tabletop remote control device 140, the wall-mounted remote control device 142, the handheld remote control device 144, and/or the retrofit remote control device 146), the remote control device 200 of FIGS. 2A-3, and/or the control device 300 of FIGS. 6-7. The control device 500 may comprise a control circuit 510 be configured to generate control data (e.g., commands) for controlling one or more load control devices and/or lighting loads (e.g., the lighting load 112 controlled by the dimmer switch 110, the LED light source 122 controlled by the LED driver 120, and/or the LED light source of the controllable light source 130 of the load control system 100). The control circuit 510 may include one or more of a processor (e.g., a microprocessor), a microcontroller, a programmable logic device (PLD), a field programmable gate array (FPGA), an application specific integrated circuit (ASIC), or any suitable controller or processing device.

The control device 500 may comprise a touch sensitive circuit 512 that may be responsive to actuations (e.g., touch actuations) of a touch sensitive surface (e.g., the touch sensitive surface of the control unit 210 of the remote control device 200). The touch sensitive circuit 512 may comprise, for example, a capacitive or resistive touch element that may be arranged behind the touch sensitive surface (e.g., such as the capacitive touch pads 328 on the first printed circuit board 326 of the control unit 310). The touch sensitive surface may define one or more portions that may each define an actuator that may be actuated (e.g., tapped) by a user (e.g., such as the actuators 221-228). The touch sensitive circuit 512 may be configured to detect actuations (e.g., touch actuations) of the actuators on the touch sensitive surface. The touch sensitive circuit 512 may generate one or more touch-input signals V_{TOUCH} that indicate a location of the actuation on the touch sensitive surface and/or an actuated one of the actuators on the touch sensitive surface. The control circuit 510 may receive the one or more touch-input signals V_{TOUCH} from the touch sensitive circuit 512 such that the control circuit 510 is responsive to the actuations of the touch sensitive surface. For example, the control circuit 510 may be configured to operate in an adjustment mode (e.g., an intensity-adjustment mode, a color-temperature-adjustment mode, and/or a full-color-adjustment mode of the control unit 210) in response to actuation of one of the actuators of the touch sensitive surface (e.g., one of the intensity-adjustment mode actuator 221, the color-temperature-adjustment mode actuator 222, and/or the full-color-adjustment mode actuator 223).

The control circuit 510 may be configured to detect “press” actuations of one or more of the actuators on the touch sensitive surface. For example, the press actuation may comprise a press-and-hold actuation of one of the actuators on the touch sensitive surface, which the control circuit 510 may be configured to detect in response to the one or more touch-input signals V_{TOUCH} generated by the touch sensitive circuit 512. In addition, the press actuation may comprise an actuation (e.g., a tactile actuation) of the touch sensitive surface that causes the touch sensitive surface to move. In some examples, the control device 500 may also comprise a force actuation circuit 514, which may allow the control circuit 510 to detect an actuation of the touch sensitive surface that causes the touch sensitive surface to move. For example, the force actuation circuit 514 may comprise a force-sensitive resistor that has a resistance that changes in response to a press actuation of the touch sensitive surface, and the control circuit 510 may be configured to detect the press actuation of the touch sensitive surface in response to the changing resistance of the force-sensitive resistor. In addition, the force actuation circuit 514 may comprise one or more mechanical switches (e.g., tactile switches) configured to be actuated in response to the press actuation of the touch sensitive surface.

The control device 500 may comprise a rotational sensing circuit 515 (e.g., the magnetic sensor 390) that is responsive to rotations of a rotatable member (e.g., the rotatable member 230) of the control device. The rotational sensing circuit 515 may be configured to translate a force applied to a rotatable member into one or more rotational sensing signals V_{ROT}. The rotational sensing circuit 515 may include, for example, one or more magnetic sensors (e.g., such as Hall-effect sensors (HES), tunneling magnetoresistance (TMR) sensors, anisotropic magnetoresistance (AMR) sensors, giant magnetoresistance (GMR) sensors, reed switches, or other mechanical magnetic sensors), a mechanical encoder, an optical encoder, and/or a potentiometer (e.g., a polymer thick film or other resistive trace on a printed circuit board). The control circuit 510 may receive the one or more rotational sensing signals V_{ROT} from the rotational sensing circuit 515 such that the control circuit 510 is responsive to the rotations of the rotatable member. The control circuit 510 may determine control data (e.g., commands) for controlling the lighting loads (e.g., via the load control devices) in response to the rotational sensing signals V_{ROT} generated by the rotational sensing circuit 515 (e.g., depending on the adjustment mode of the control device 500). For example, when operating in the intensity-adjustment mode, the control circuit 510 may be configured to determine an intensity-adjustment amount ΔL for adjusting a present intensity level L_{PRES} of each of the lighting loads in response to the rotational sensing signals V_{ROT} generated by the rotational sensing circuit 515. In addition, when operating in the color-temperature-adjustment mode, the control circuit 510 may be configured to determine a color-temperature-adjustment amount ΔT for adjusting a present color temperature T_{PRES} of each of the lighting loads in response to the rotational sensing signals V_{ROT} generated by the rotational sensing circuit 515. Further, when operating in the full-color-adjustment mode, the control circuit 510 is configured to determine a commanded color for controlling a present color of each of the lighting loads (e.g., as defined by a commanded x-chromaticity coordinate and a y-chromaticity coordinate) in response to the rotational sensing signals V_{ROT} generated by the rotational sensing circuit 515.

The control device 500 may comprise a communication circuit 516 configured to communicate (e.g., transmit and/or receive) messages (e.g., digital messages). For example, the communication circuit 516 may comprise a wired communication circuit and/or a wireless communication circuit. The communication circuit 516 may be implemented as an external integrated circuit (IC) or as an internal circuit of the control circuit 510. For example, the communication circuit 516 may include for example, a radio-frequency (RF) transceiver coupled to an antenna for transmitting and/or receiving RF signals. The communication circuit 516 may also include an RF transmitter for transmitting RF signals, an RF receiver for receiving RF signals, or an infrared (IR) transmitter and/or receiver for transmitting and/or receiving IR signals. The communication circuit 516 may be configured to transmit messages including control data (e.g., one or more commands) for controlling the lighting load. The control data may include a command and/or identification information (e.g., such as a unique identifier) associated with the control device 500. Additionally or alternatively, the control circuit 510 may cause the communication circuit 516 to transmit a message to a central controller of the lighting control system, which may transmit the message including control data (e.g., a command) for controlling the lighting load. In addition, the control circuit 510 may be configured to receive messages including status information of the lighting load via the communication circuit 516.

The control circuit 510 may be configured to generate the control data (e.g., commands) to be transmitted via the communication circuit 516 in response to user inputs (e.g., touch actuations of the touch sensitive surface, press actuations of the touch sensitive surface, and/or rotations of the rotatable member). For example, the control circuit 510 may be configured to transmit messages including one or more commands for adjusting an intensity level and/or a color of the lighting load (e.g., an intensity-adjustment command, a color-temperature-adjustment command, and/or a full-color-adjustment command) in response to rotations of the rotatable member depending upon the adjustment mode of the control device 500 (e.g., the intensity-adjustment mode, the color-temperature-adjustment mode, and/or the full-color-adjustment mode). In response to a touch actuation of the touch sensitive surface to select one of the adjustment modes, the control circuit 510 may be configured to transmit a color-temperature-adjustment command and/or a full-color-adjustment command without an indication for the receiving load control device to change color control modes (e.g., such that only those load control devices operating in the color-temperature-control mode will respond to the color-temperature-adjustment commands, and/or only those load control devices operating in the full-color-control mode will respond to the full-color-adjustment commands). In response to a press actuation of the touch sensitive surface to select one of the adjustment modes, the control circuit 510 may be configured to transmit a color-temperature-adjustment command and/or a full-color-adjustment command with an indication for the receiving load control device to change color control modes (e.g., such that all of the load control devices that are color control capable will respond to either the color-temperature-adjustment command and/or the full-color-adjustment command). In addition, the control circuit 510 may be configured to transmit a message having a scene command including an indication of a selected scene in response to an actuation of one of the actuators of the touch sensitive surface (e.g., one of the first scene actuator 224, the second scene actuator 225, and the third scene actuator 226). Further, the control circuit 510 may be configured to transmit a message including a command to cause one or more of the lighting loads to toggle their states (e.g., turn from off to on, or vice versa) in response to an actuation of one of the actuators of the touch sensitive surface (e.g., the toggle actuator 227).

The control device 500 may comprise a plurality of light sources 518. The control circuit 510 may control the light sources to illuminate one or more visible indicators of the control device 500 to provide feedback about various conditions. The control circuit 510 may be configured to control an intensity level (e.g., a brightness) and/or a color (e.g., color temperature and/or full color) of each of the light sources 518. For example, the light sources 518 may comprise light-emitting diodes (LEDs). The light source 518 may comprise a first subset of light sources (e.g., the light sources 340) configured to illuminate icons (e.g., the icons 231-238) on the touch sensitive surface to indicate locations of the actuators of the touch sensitive surface. For example, the light sources 518 of the first subset may each be located behind a respective one of the icons on the touch sensitive surface. In response to an actuation of one of the actuators of the touch sensitive surface to select one of the adjustment modes (e.g., one of the intensity-adjustment mode actuator 221, the color-temperature-adjustment mode actuator 222, and/or the full-color-adjustment mode actuator 223), the control circuit 510 may be configured to control the first subset of light sources 518 to illuminate (e.g., only illuminate) the one of icons that indicates the selected adjustment mode.

The light sources 518 may also comprise a second subset of light sources (e.g., the light sources 350) configured to illuminate a light bar of the control device 500 (e.g., the light bar 240 of the control unit 210). For example, the second subset of the light sources 518 may comprise a number N_{LED} of light sources (e.g., approximately 20 light sources) surrounding the perimeter of the touch sensitive surface for illuminating the light bar. The control circuit 510 may be configured to illuminate the light bar to indicate the status of one or more of the lighting loads (e.g., the intensity level, the color temperature, and/or the full color of one or more of the lighting loads) depending upon the present adjustment mode of the control device 500 (e.g., one of the intensity-adjustment mode, the color-temperature-adjustment mode, and/or the full-color-adjustment mode). For example, when in the intensity-adjustment mode, the control circuit 510 may be configured to adjust a length of an illuminated portion of the light bar to indicate the present intensity level L_{PRES} of the one or more lighting loads. In addition, when in the color-temperature-adjustment mode, the control circuit 510 may be configured to adjust a position of an illuminated segment (e.g., the illuminated segment 246) of the light bar to indicate the present color temperature T_{PRES} of the one or more lighting loads (e.g., as shown in FIGS. 4A-4D). Further, when in the full-color-adjustment mode, the control circuit 510 may be configured to illuminate at least a portion of the light bar to indicate the present color (e.g., full color) of the one or more lighting loads, for example, by illuminating the entire light bar to the present full color (e.g., according a present x-chromaticity coordinate and a present y-chromaticity coordinate). The control circuit 510 may be also configured to control the second subset of the light sources 518 to illuminate the light bar to indicate a detected user input, to indicate a status and/or operating mode of the control device 500, and/or to assist with configuration of the control device 500.

The control device 500 may further comprise a memory 520 that may be communicatively coupled to the control circuit 510 for the storage and/or retrieval of, for example, operational settings, such as, association information (e.g., unique identifiers of load control devices to which the control device 500 is associated), present intensities levels and/or colors of the lighting loads controlled by the load control devices to which the control device 500 is associated, etc. The memory 520 may be implemented as an external integrated circuit (IC) or as an internal circuit of the control circuit 510. The memory 520 may comprise a computer-readable storage media or machine-readable storage media that maintains computer-executable instructions for performing one or more procedure and/or functions as described herein. For example, the memory 520 may comprise computer-executable instructions or machine-readable instructions that when executed by the control circuit configure the control circuit to provide one or more portions of the procedures described herein. The control circuit 510 may access the instructions from memory 520 for being executed to cause the control circuit 510 to operate as described herein, or to operate one or more other devices as described herein. The memory 520 may comprise computer-executable instructions for executing configuration software. For example, the operational characteristics stored in the memory 520 may be configured during a configuration procedure of the control device 500.

After adjustments of the present intensity levels L_{PRES}, the present color temperatures T_{PRES}, and/or the present color of the lighting loads, the control circuit 510 may be configured to return the respective lighting load to a previous state. For example, the control circuit 510 may be configured to transmit a message including a command (e.g., an undo command) to cause one or more of the lighting loads to return to the previous states in response to an actuation of one of the actuators of the touch sensitive surface (e.g., an undo actuator, such as the undo actuator 228). Upon receiving the message including the undo command, each of the load control devices may be configured to revert to the previous state. In some examples, each of the load control devices may be configured to store the previous state of the respective lighting load (e.g., a stored intensity level L_{STRD}, a stored color temperature T_{STRD}, and/or a stored color, for example, as defined by a stored x-chromaticity coordinate X_{STRD} and a stored y-chromaticity coordinate Y_{STRD}). In addition, the control circuit 510 may be configured to store a last selected scene in the memory 520, and to transmit a message having a scene command including an indication of a selected scene in response to an actuation of the undo actuator.

Further, the control circuit 510 may be configured to store in the memory 520 the previous state for each of the lighting loads, and transmit messages including respective commands for controlling the lighting loads to the appropriate levels to restore the lighting loads to the previous states in response to an actuation of the undo actuator. The control circuit 510 may be configured to store in the memory 520, for example, a stored intensity level L_{STRD}, a stored color temperature T_{STRD}, and/or a stored color (e.g., as defined by a stored x-chromaticity coordinate X_{STRD} and a stored y-chromaticity coordinate Y_{STRD}) for each of the lighting loads. For example, the control circuit 510 may be configured to store the last stable state of each of the lighting loads in the memory 520. For example, the control circuit 510 may be configured to store in the memory 520 the last stable state of each of the lighting loads after which the present intensity level L_{PRES}, the present color temperature T_{PRES}, and/or the present color (e.g., full color) of each of the lighting loads was not changed for a predetermined undo timeout period T_{UNDO}.

The control circuit 510 may be configured to maintain an undo timer to determine when an end of the undo timeout period T_{UNDO} has occurred. The control circuit 510 may be configured to reset the undo timer (e.g., start over the undo timeout period T_{UNDO}) whenever a change is made to the present intensity level L_{PRES}, the present color temperature T_{PRES}, and/or the present color (e.g., full color) of the respective lighting load (e.g., whenever the control circuit 510 transmits a message including a command to control the lighting loads). At the end of the undo timeout period T_{UNDO} (e.g., when the undo timer expires), the control circuit 510 may be configured to store the present intensity level L_{PRES}, the present color temperature T_{PRES}, and/or the present color (e.g., full color) of each of the lighting loads in the memory 520 to be recalled later in response to an actuation of the undo actuator 228. For example, the control circuit 510 may be configured to store the present intensity level L_{PRES}, the present color temperature T_{PRES}, and/or the present color (e.g., full color) of each of the lighting loads as last controlled by the control circuit 510 in the memory 520 as the stored intensity level L_{STRD}, the stored color temperature T_{STRD}, and/or the stored color (e.g., as defined by the stored x-chromaticity coordinate X_{STRD} and the stored y-chromaticity coordinate Y_{STRD}) for each of the lighting loads.

The control device 500 may comprise a power source 522 for producing a power source voltage V_{PS}. For example, the power source 522 may comprise one or more batteries (e.g., the battery 343) and/or a photo-voltaic power source (e.g., a solar cell). In addition, the power source 522 may comprise one or more energy storage elements, such as super capacitors and/or rechargeable batteries. Further, the power source 522 may also be configured to receive power from an external power source, such as an external direct-current (DC) power source or an alternating-current (AC) power source. The control device 500 may also comprise a power supply 524 that may be configured to receive the power source voltage V_{PS} and generate a DC supply voltage V_{CC} for powering the control circuit 510 and other low-voltage circuitry of the control device 500. In some examples, the power source 522 may be configured to receive power from the external power source when the control device 500 is mounted to a base (e.g., such as the base 212), and the base may comprise a power supply (e.g., the power supply 524) and/or a charging circuit for charging the power source 522.

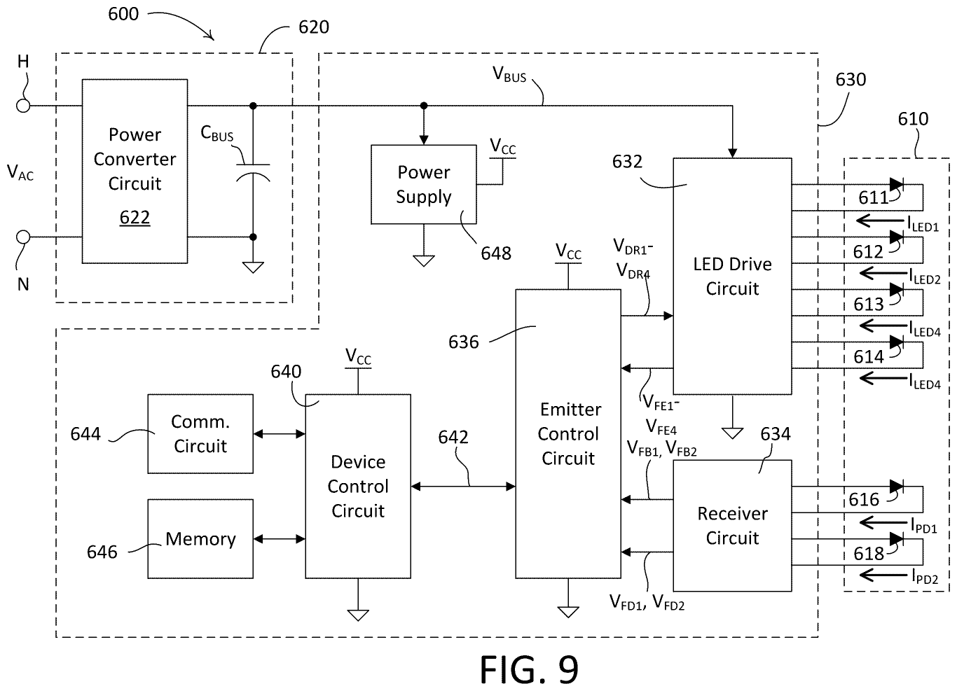

FIG. 9 is a simplified block diagram of an example load control device 600 (e.g., such as the LED driver 120 and/or the controllable light source 130 of the load control system 100 shown in FIG. 1). The load control device 600 may be configured to control a lighting load, e.g., an LED light source, such as, an emitter assembly 610 (e.g., the LED light source 122 controlled by the LED driver 120 and/or the LED light source of the controllable light source 130). The load control device 600 may comprise a power conversion stage 620 and a light-generation module stage 630. In some examples, the emitter assembly 610 may be external to the load control device 600 (e.g., external to a housing of the load control device 600) and installed in a lighting fixture with the load control device 600 (e.g., as with the LED driver 120 and the LED light source 122 installed in the lighting fixture 124). In addition, the emitter assembly 610 may be integral with the load control device 600 and installed in the same housing as the light-generation module stage 630 (e.g., as with the controllable light source 130). The emitter assembly 610 may be referred to as an emitter module.

The emitter assembly 610 may include, for example, one or more emitters 611, 612, 613, 614. Each of the emitters 611, 612, 613, 614 is shown in FIG. 30 as a single LED, but may each comprise a plurality of LEDs connected in series (e.g., a chain of LEDs), a plurality of LEDs connected in parallel, or a suitable combination thereof, depending on the particular lighting system. In addition, each of the emitters 611, 612, 613, 614 may comprise one or more organic light-emitting diodes (OLEDs). For example, the first emitter 611 may represent a chain of red LEDs, the second emitter 612 may represent a chain of blue LEDs, the third emitter 613 may represent a chain of green LEDs, and the fourth emitter 614 may represent a chain of white or amber LEDs. The emitters 611, 612, 613, 614 may be controlled to adjust a brightness (e.g., a luminous flux or an intensity level) and/or a color (e.g., a color temperature) of a cumulative light output of the emitter assembly 610 (e.g., a cumulative light output of the lighting fixture 124 and/or the controllable light source 130). The emitter assembly 610 may also comprise one or more detectors 616, 618 (e.g., photodiodes) that may produce respective photodiode currents I_{PD1}, I_{PD2} (e.g., detector signals) in response to incident light. For example, the first detector 616 may represent a single red, orange or yellow LED or multiple red, orange or yellow LEDs in parallel, and the second detector 618 may represent a single green LED or multiple green LEDs in parallel.

The power conversion stage 620 may comprise a power converter circuit 622, which may receive a source voltage, such as an AC mains line voltage V_{AC}, via a hot connection H and a neutral connection N. The power converter circuit 622 may generate a DC bus voltage V_{BUS} (e.g., approximately 15-20V) across a bus capacitor C_{BUS}. The power converter circuit 622 may comprise, for example, a boost converter, a buck converter, a buck-boost converter, a flyback converter, a single-ended primary-inductance converter (SEPIC), a Ćuk converter, or any other suitable power converter circuit for generating an appropriate bus voltage. The power converter circuit 622 may provide electrical isolation between the AC power source and the emitters 611, 612, 613, 614, and may operate as a power factor correction (PFC) circuit to adjust the power factor of the load control device 600 towards a power factor of one.

The light-generation module stage 630 may comprise a load control circuit, such as an LED drive circuit 632 for controlling (e.g., individually controlling) the power delivered to and the luminous flux of the light emitted of each of the emitters 611, 612, 613, 614 of the emitter assembly 610. The LED drive circuit 632 may receive the bus voltage V_{BUS} and may adjust magnitudes of respective LED drive currents I_{LED1}, I_{LED2}, I_{LED3}, I_{LED4} conducted through the emitters 611, 612, 613, 614. The LED drive circuit 632 may comprise one or more regulation circuits (e.g., four regulation circuits), such as switching regulators (e.g., buck converters) for controlling the magnitudes of the respective LED drive currents I_{LED1}-I_{LED4}. An example of the LED drive circuit 632 is described in greater detail in U.S. Pat. No. 9,485,813, issued Nov. 1, 2016, entitled ILLUMINATION DEVICE AND METHOD FOR AVOIDING AN OVER-POWER OR OVER-CURRENT CONDITION IN A POWER CONVERTER, the entire disclosure of which is hereby incorporated by reference. The light-generation module stage 630 may comprise a receiver circuit 634 that may be electrically coupled to the detectors 616, 618 of the emitter assembly 610 for generating respective optical feedback signals V_{FB1}, V_{FB2} in response to the photodiode currents I_{PD1}, I_{PD2}. The receiver circuit 634 may comprise one or more trans-impedance amplifiers (e.g., two trans-impedance amplifiers) for converting the respective photodiode currents I_{PD1}, I_{PD2} into the optical feedback signals V_{FB1}, V_{FB2}. For example, the optical feedback signals V_{FB1}, V_{FB2} may have DC magnitudes that indicate the magnitudes of the respective photodiode currents I_{PD1}, I_{PD2}.

The light-generation module stage 630 may comprise an emitter control circuit 636 for controlling the LED drive circuit 632 to control the intensities of the emitters 611, 612, 613, 614 of the emitter assembly 610. The emitter control circuit 636 may comprise, for example, a microprocessor, a microcontroller, a programmable logic device (PLD), an application specific integrated circuit (ASIC), a field-programmable gate array (FPGA), or any other suitable processing device or controller. The emitter control circuit 636 may generate one or more drive signals V_{DR1}, V_{DR2}, V_{DR3}, V_{DR4} for controlling the respective regulation circuits in the LED drive circuit 632. The emitter control circuit 636 may receive the optical feedback signals V_{FB1}, V_{FB2} from the receiver circuit 634 for determining the luminous flux LE of the light emitted by the emitters 611, 612, 613, 614.

The emitter control circuit 636 may receive a plurality of emitter forward-voltage feedback signals V_{FE1}, V_{FE2}, V_{FE3}, V_{FE4} from the LED drive circuit 632 and a plurality of detector forward-voltage feedback signals V_{FD1}, V_{FD2} from the receiver circuit 634. The emitter forward-voltage feedback signals V_{FE1}-V_{FE4} may be representative of the magnitudes of the forward voltages of the respective emitters 611, 612, 613, 614, which may indicate temperatures T_{E1}, T_{E2}, T_{E3}, T_{EA} of the respective emitters. If each emitter 611, 612, 613, 614 comprises multiple LEDs electrically coupled in series, the emitter forward-voltage feedback signals V_{FE1}-V_{FE4} may be representative of the magnitude of the forward voltage across a single one of the LEDs or the cumulative forward voltage developed across multiple LEDs in the chain (e.g., all of the series-coupled LEDs in the chain). The detector forward-voltage feedback signals V_{FD1}, V_{FD2} may be representative of the magnitudes of the forward voltages of the respective detectors 616, 618, which may indicate temperatures T_{D1}, T_{D2} of the respective detectors. For example, the detector forward-voltage feedback signals V_{FD1}, V_{FD2} may be equal to the forward voltages V_{FD} of the respective detectors 616, 618.

The light-generation module stage 630 may comprise a device control circuit 640 that may be electrically coupled to the emitter control circuit 636 via a communication bus 642 (e.g., an I²C communication bus). The device control circuit 640 may be configured to control the emitter assembly 610 to control the brightness (e.g., luminous flux) and/or the color (e.g., color temperature and/or full color) of the cumulative light emitted by the emitter assembly 610. The device control circuit 640 may comprise, for example, a microprocessor, a microcontroller, a programmable logic device (PLD), an application specific integrated circuit (ASIC), a field-programmable gate array (FPGA), or any other suitable processing device or controller. The device control circuit 640 may be configured to adjust (e.g., dim) a present intensity L_{PRES} (e.g., a present brightness) of the cumulative light emitted by the emitter assembly 610 towards a target intensity L_{TRGT} (e.g., a target brightness), which may range across a dimming range of the load control device 600, e.g., between a low-end intensity level L_{LE} (e.g., a minimum intensity level, such as approximately 0.1%-1.0%) and a high-end intensity level L_{HE} (e.g., a maximum intensity level, such as approximately 100%). The device control circuit 640 may be configured to adjust a present color temperature T_{PRES} of the cumulative light emitted by the emitter assembly 610 towards a target color temperature T_{TRGT}, which may range between a cool-white color temperature T_{CW} (e.g., approximately 3100-4500 K) and a warm-white color temperature T_{WW} (e.g., approximately 2000-3000 K). The device control circuit 640 may be configured to adjust a present color (e.g., as set by a present x-chromaticity coordinate and a present y-chromaticity coordinate).

The light-generation module stage 630 may comprise a communication circuit 644 coupled to the device control circuit 640. The communication circuit 644 may comprise a wireless communication circuit, such as, for example, a radio-frequency (RF) transceiver coupled to an antenna for transmitting and/or receiving RF signals. The wireless communication circuit may be an RF transmitter for transmitting RF signals, an RF receiver for receiving RF signals, or an infrared (IR) transmitter and/or receiver for transmitting and/or receiving IR signals. The communication circuit 644 may be coupled to the hot connection H and the neutral connection N of the load control device 600 for transmitting a control signal via the electrical wiring using, for example, a power-line carrier (PLC) communication technique. The device control circuit 640 may be configured to determine the target intensity L_{TRGT} for the emitter assembly 610 in response to messages (e.g., digital messages) received via the communication circuit 644.

The light-generation module stage 630 may comprise a memory 646 configured to store operational characteristics of the load control device 600, such as, association information (e.g., unique identifiers of remote control devices to which the load control device 600 is associated), present intensities levels and/or colors of the lighting loads controlled by the load control device 600, etc. The memory 646 may be implemented as an external integrated circuit (IC) or as an internal circuit of the device control circuit 640. The memory 646 may comprise a computer-readable storage media or machine-readable storage media that maintains computer-executable instructions for performing one or more procedure and/or functions as described herein. For example, the memory 646 may comprise computer-executable instructions or machine-readable instructions that when executed by the control circuit configure the control circuit to provide one or more portions of the procedures described herein. The device control circuit 640 may access the instructions from memory 646 for being executed to cause the device control circuit 640 to operate as described herein, or to operate one or more other devices as described herein. The memory 646 may comprise computer-executable instructions for executing configuration software. For example, the operational characteristics stored in the memory 646 may be configured during a configuration procedure of the load control device 600.

The light-generation module stage 630 may comprise a power supply 648 that may receive the bus voltage V_{BUS} and generate a supply voltage V_{CC} for powering the device control circuit 640 and other low-voltage circuitry of the lighting device.

The device control circuit 640 may be configured to operate in a color-temperature-control mode or a full-color-control mode to adjust either the present color temperature T_{PRES} or the present color (e.g., full color) of the cumulative light emitted by the emitter assembly 610. When operating in the color-temperature-control mode, the device control circuit 640 may be configured to adjust the present color temperature T_{PRES} in response to received color-temperature-adjustment commands and to ignore full-color-adjustment commands. When operating in the full-color-control mode, the device control circuit 640 may be configured to adjust the present color (e.g., as defined by the present x-chromaticity coordinate X_{PRES} and the present y-chromaticity coordinate Y_{PRES}) in response to received full-color-adjustment commands and to ignore color-temperature-adjustment commands. The device control circuit 640 may be configured to change color-control modes in response to receiving a message that includes a color-temperature-adjustment command or a full-color-adjustment command along with an indication that the load control device 600 should change between the color-temperature-control mode and the full-color-control mode. For example, in response to receiving a message that includes a color-temperature-adjustment command along with an indication that the load control device 600 should change from the full-color-control mode to the color-temperature-control mode when the device control circuit 640 is operating in the full-color-control mode, the device control circuit 640 may be configured to change from the full-color-control mode to the color-temperature-control mode and then adjust the present color temperature T_{PRES} of the cumulative light emitted by the emitter assembly 610. In addition, in response to receiving a message that includes a full-color-adjustment command along with an indication that the load control device 600 should change from the color-temperature-control mode to the full-color-control mode when the device control circuit 640 is operating in the color-temperature-control mode, the device control circuit 640 may be configured to change from the color-temperature-control mode to the full-color-control mode and then adjust the present color of the cumulative light emitted by the emitter assembly 610.

The device control circuit 640 may control the emitters 611, 612, 613, 614 of the emitter assembly 610 in response to receiving one or more intensity-adjustment commands. The device control circuit 640 may be configured to adjust the present intensity level L_{PRES} of the cumulative light emitted by the emitter assembly 610 in response to intensity-adjustment commands independent of the color-control mode in which the device control circuit 640 is presently operating (e.g., the device control circuit 640 may be configured to adjust the present intensity level L_{PRES} of the cumulative light emitted by the emitter assembly 610 in response to intensity-adjustment commands when the device control circuit 640 is operating in either the color-temperature-control mode or the full-color-control mode). The device control circuit 640 may be configured to limit the present intensity level L_{PRES} of the cumulative light emitted by the emitter assembly 610 to the low-end intensity level L_{LE} (e.g., the minimum intensity level) and the high-end intensity level L_{HE} (e.g., the maximum intensity level). The device control circuit 640 may be configured to maintain in the memory 646 a commanded intensity level L_{CMD}, which may be an intensity level determined from the received intensity-adjustment command (e.g., an intensity level to which the device control circuit 640 is commanded to control the present intensity level L_{PRES} of the cumulative light emitted by the emitter assembly 610). In addition, the device control circuit 640 may be configured to determine a controlled intensity level L_{CNTL}, which may be an intensity level to which the present intensity level L_{PRES} of the cumulative light emitted by the emitter assembly 610 is controlled (e.g., is actually controlled). The device control circuit 640 may be configured to determine the controlled intensity level L_{CNTL} based on the commanded intensity level L_{CMD}. The device control circuit 640 may be configured to set the controlled intensity level L_{CNTL} to be, for example, the same as the commanded intensity level L_{CMD}, but may limit the controlled intensity level L_{CNTL} to the high-end intensity level L_{HE} and the low-end intensity level L_{LE}.

The device control circuit 640 may control the emitters 611, 612, 613, 614 of the emitter assembly 610 in response to receiving one or more color-temperature-adjustment commands. The device control circuit 640 may be configured to limit the present color temperature T_{PRES} of the cumulative light emitted by the emitter assembly 610 to the cool-white color temperature T_{CW} and the warm-white color temperature T_{WW}. The device control circuit 640 may be configured to maintain in the memory 646 a commanded color temperature T_{CMD}, which may be a color temperature determined from the received color-temperature-adjustment command (e.g., a color temperature to which the device control circuit 640 is commanded to control the present color temperature T_{PRES} of the cumulative light emitted by the emitter assembly 610). In addition, the device control circuit 640 may be configured to determine a controlled color temperature T_{CNTL}, which may be a color temperature to which the present color temperature T_{PRES} of the cumulative light emitted by the emitter assembly 610 is controlled (e.g., is actually controlled). The device control circuit 640 may be configured to determine the controlled color temperature T_{CNTL} based on the commanded color temperature T_{CMD}. The device control circuit 640 may be configured to set the controlled color temperature T_{CNTL} to be, for example, the same as the commanded color temperature T_{CMD}, but may limit the controlled color temperature T_{CNTL} to the cool-white color temperature T_{CW} and the warm-white color temperature T_{WW}.

When the load control device 600 is on, the device control circuit 640 may be configured to control the emitter control circuit 636 to control the emitter assembly 610 to emit light substantially all of the time. The device control circuit 640 may be configured to control the emitter control circuit 636 to control the emitter assembly 610 to disrupt the normal emission of light to measure one or more operational characteristics of the emitter modules during periodic measurement intervals. For example, during the measurement intervals, the emitter control circuit 636 may be configured to individually turn on each of the different-colored emitters 611, 612, 613, 614 of the emitter assembly 610 (e.g., while turning off the other emitters) and measure the luminous flux of the light emitted by that emitter using one of the two detectors 616, 618. For example, the emitter control circuit 636 may turn on the first emitter 611 of the emitter assembly 610 (e.g., at the same time as turning off the other emitters 612, 613, 614 and determine the luminous flux L_{E} of the light emitted by the first emitter 611 in response to the first optical feedback signal V_{FB1} generated from the first detector 616. In addition, the emitter control circuit 636 may be configured to drive the emitters 611, 612, 613, 614 and the detectors 616, 618 to generate the emitter forward-voltage feedback signals V_{FE1}-V_{FE4} and the detector forward-voltage feedback signals V_{FD1}, V_{FD2} during the measurement intervals.

Methods of measuring the operational characteristics of emitter modules in a lighting device are described in greater detail in U.S. Pat. No. 9,332,598, issued May 3, 2016, entitled INTERFERENCE-RESISTANT COMPENSATION FOR ILLUMINATION DEVICES HAVING MULTIPLE EMITTER MODULES; U.S. Pat. No. 9,392,660, issued Jul. 12, 2016, entitled LED ILLUMINATION DEVICE AND CALIBRATION METHOD FOR ACCURATELY CHARACTERIZING THE EMISSION LEDS AND PHOTODETECTOR(S) INCLUDED WITHIN THE LED ILLUMINATION DEVICE; and U.S. Pat. No. 9,392,663, issued Jul. 12, 2016, entitled ILLUMINATION DEVICE AND METHOD FOR CONTROLLING AN ILLUMINATION DEVICE OVER CHANGES IN DRIVE CURRENT AND TEMPERATURE, the entire disclosures of which are hereby incorporated by reference.

Calibration values for the various operational characteristics of the load control device 600 and/or the emitter assembly 610 may be stored in the memory 646 as part of a calibration procedure performed during manufacturing of the load control device 600 and/or the emitter assembly 610. Calibration values may be stored for each of the emitters 611, 612, 613, 614 and/or the detectors 616, 618 of the emitter assembly 610. For example, calibration values may be stored for measured values of luminous flux (e.g., in lumens), X-chromaticity, Y-chromaticity, emitter forward voltage, photodiode current, and detector forward voltage. For example, the luminous flux, x-chromaticity, and y-chromaticity measurements may be obtained from the emitters 611, 612, 613, 614 using an external calibration tool, such as a spectrophotometer. The values for the emitter forward voltages, photodiode currents, and detector forward voltages may be measured internally to the load control device 600. The calibration values for each of the emitters 611, 612, 613, 614 and/or the detectors 616, 618 may be measured at a plurality of different drive currents, and/or at a plurality of different operating temperatures.

After installation, the device control circuit 640 may use the calibration values stored in the memory 646 to maintain a constant light output from the emitter assembly 610. The device control circuit 640 may determine target values for the luminous flux to be emitted from the emitters 611, 612, 613, 614 to achieve the target intensity L_{TRGT} and/or the target color temperature T_{TRGT} for the load control device 600. The device control circuit 640 may determine the magnitudes for the respective drive currents I_{LED1}-I_{LED4}. for the emitters 611, 612, 613, 614 based on the determined target values for the luminous flux to be emitted from the emitters 611, 612, 613, 614. When the age of the load control device 600 is zero, the magnitudes of the respective drive currents I_{LED1}-I_{LED4} for the emitters 611, 612, 613, 614 may be controlled to initial magnitudes I_{LED-INITIAL}.

The light output of the emitter assembly 610 may decrease as the emitters 611, 612, 613, 614 age. The device control circuit 640 may be configured to increase the magnitudes of the drive current I_{DR} for the emitters 611, 612, 613, 614 to adjusted magnitudes I_{LED-ADJUSTED} to achieve the determined target values for the luminous flux of the target intensity L_{TRGT} and/or the target color temperature T_{TRGT}. Methods of adjusting the drive currents of emitters to achieve a constant light output as the emitters age are described in greater detail in U.S. Pat. No. 9,769,899, issued Sep. 19, 2017, entitled ILLUMINATION DEVICE AND AGE COMPENSATION METHOD, the entire disclosure of which is hereby incorporated by reference.

After adjustments of the present intensity levels L_{PRES}, the present color temperatures T_{PRES}, and/or the emitter assembly 610, the device control circuit 640 may be configured to return the emitter assembly 610 to a previous state. For example, the device control circuit 640 may be configured to receive a message including a command (e.g., an undo command) and return the emitter assembly 610 to the previous state in response to receiving the message including the undo command. For example, the device control circuit 640 may be configured to store in the memory 646 the previous state of the respective lighting load (e.g., a stored intensity level L_{STRD}, a stored color temperature T_{STRD}, and/or a stored color, for example, as defined by a stored x-chromaticity coordinate X_{STRD} and a stored y-chromaticity coordinate Y_{STRD}). In response to receiving a message including an undo command, the device control circuit 640 may be configured to retrieve the stored intensity level L_{STRD}, the stored color temperature T_{STRD}, and/or the stored color (e.g., as defined by a stored x-chromaticity coordinate X_{STRD} and a stored y-chromaticity coordinate Y_{STRD}) from the memory 646 and cause the emitter control circuit 636 to control the cumulative light emitted by the emitter assembly 610 according to the stored intensity level L_{STRD}, the stored color temperature T_{STRD}, and/or the stored color.

The device control circuit 640 may be configured to store, for example, the last stable state the emitter assembly 610 in the memory 646 to be recalled when the device control circuit 640 receives a message including an undo command. For example, the device control circuit 640 may be configured to store in the memory 646 the last stable state of each of the lighting loads after which the present intensity level L_{PRES}, the present color temperature T_{PRES}, and/or the present color (e.g., full color) of each of the emitter assembly 610 was not changed for a predetermined undo timeout period T_{UNDO}. The device control circuit 640 may be configured to maintain an undo timer to determine when an end of the undo timeout period T_{UNDO} has occurred. The device control circuit 640 may be configured to reset the undo timer (e.g., start over the undo timeout period T_{UNDO}) whenever a change is made to the present intensity level L_{PRES}, the present color temperature T_{PRES}, and/or the present color (e.g., full color) of the emitter assembly 610. At the end of the undo timeout period T_{UNDO} (e.g., when the undo timer expires), the device control circuit 640 may be configured to store the present intensity level L_{PRES}, the present color temperature T_{PRES}, and/or the present color (e.g., full color) of each of the lighting loads in the memory 646 to be recalled later in response to receiving a message including an undo command. For example, the device control circuit 640 may be configured to store the present intensity level L_{PRES}, the present color temperature T_{PRES}, and/or the present color (e.g., full color) of each of the lighting loads as last controlled by the device control circuit 640 in the memory 646 as the stored intensity level L_{STRD}, the stored color temperature T_{STRD}, and/or the stored color (e.g., as defined by the stored x-chromaticity coordinate X_{STRD} and the stored y-chromaticity coordinate Y_{STRD}) for the emitter assembly 610.

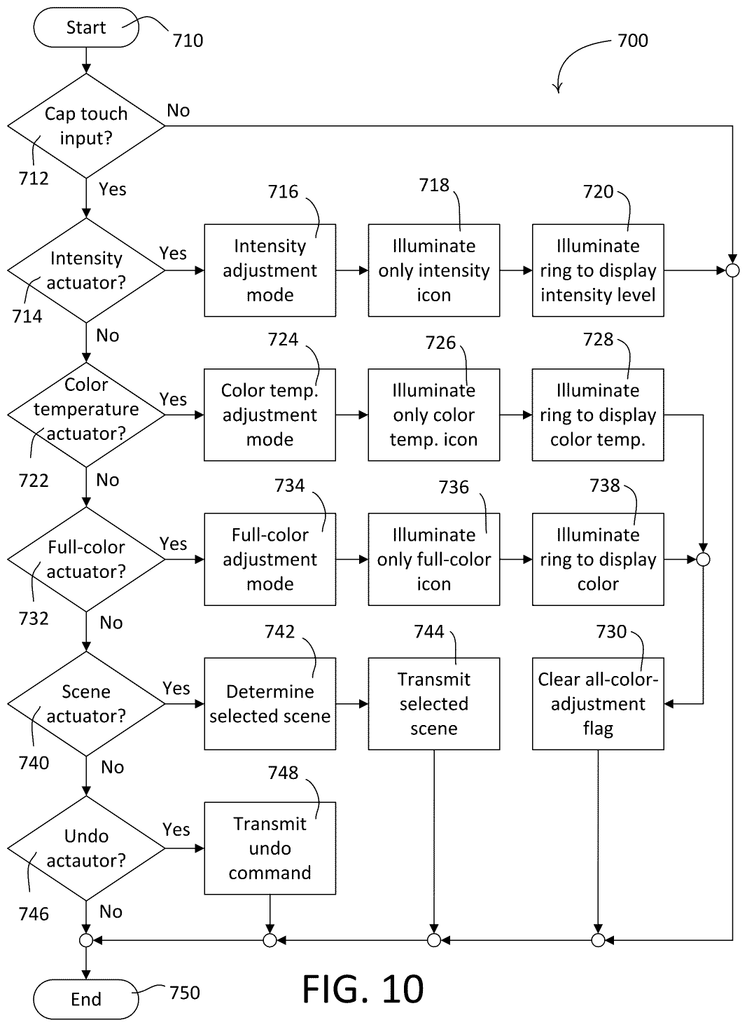

FIG. 10 is a flowchart of an example procedure 700 for receiving an input (e.g., a touch actuation) at a touch sensitive surface of a control device (e.g., such as the input control devices of FIG. 1, the remote control device 200 of FIGS. 2-3, and/or the remote control device 500 of FIG. 8). The control device may comprise a touch sensitive circuit (e.g., the touch sensitive circuit 512) for receiving the input from the touch sensitive surface (e.g., the user interface surface 220). The control device may also comprise a light bar (e.g., the light bar 240). The control procedure 700 may be executed by a control circuit of the control device (e.g., a control circuit of one of the input control devices of FIG. 1, a control circuit of the remote control device 200 of FIG. 2-3, and/or the control circuit 510 of the control device 500 of FIG. 8). For example, the control circuit may execute the control procedure 700 to process a touch actuation received by the touch sensitive surface. The control circuit may execute the control procedure 700 at 710 periodically, and/or in response to detecting a touch actuation of the touch sensitive surface. Prior to execution of the control procedure 700 and/or in response to the execution of the control procedure 700, the control circuit may be configured to identify one or more actuators (e.g., virtual actuators, such as the actuators 221-228) by illuminating one or more icons on the touch sensitive surface, e.g., such as an intensity icon (e.g., the intensity-adjustment mode icon 231), a color temperature icon (e.g., the color-temperature-adjustment mode icon 232), a full color icon (the full-color-adjustment mode icon 233), one or more scene icons (e.g., the first scene icon 234, the second scene icon 235, and/or the third scene icon 236), and an undo icon (e.g., the undo icon 238).

At 712, the control circuit may determine if a touch actuation (e.g., a tap) is presently occurring on the touch sensitive surface. If not, the control procedure 700 may end at 750. If a touch actuation is presently occurring at 712, the control circuit may determine if an intensity actuator (e.g., the intensity-adjustment mode actuator 221) is being actuated at 714. When the intensity actuator is being actuated at 714, the control circuit may enter an intensity-adjustment mode at 716 and illuminate only the intensity icon at 718 (e.g., by not illuminating the color temperature icon and the full color icon). In addition, the control circuit may illuminate the light bar to indicate an intensity level (e.g., the present intensity level L_{PRES} of the lighting load controlled by the load control devices associated with the remote control device) at 720, before the procedure 700 ends at 750. For example, the control circuit of the control unit 210 shown in FIG. 3 may illuminate a portion of the light bar 240 starting at the bottom-center point 244 of the light bar 240 and extending around the light bar 240 in a clockwise direction at 720, where the length of the illuminated portion of the light bar 240 indicates the present intensity level L_{PRES} of the one or more lighting loads.

If the intensity actuator is not being actuated at 714, the control circuit may determine if a color temperature actuator (e.g., the color-temperature-adjustment mode actuator 222) is being actuated at 722. When the color temperature actuator is being actuated at 722, the control circuit may enter a color-temperature-adjustment mode at 724 and illuminate only the color temperature icon at 726 (e.g., by not illuminating the intensity icon and the full color icon). In addition, the control circuit may illuminate the light bar to indicate a color temperature (e.g., the present color temperature T_{PRES} of the lighting load controlled by the load control devices associated with the remote control device) at 728. For example, the control circuit of the control unit 210 may illuminate a segment of the light bar 240 at 728, where the position of the illuminated segment around the circumference of the light bar 240 indicates the present color temperature T_{PRES}. At 740, the control circuit may clear an all-color-adjustment flag, before the procedure 700 ends at 750. When the control circuit is operating in the color-temperature-adjustment mode and the all-color-adjustment flag is not set, the control circuit may transmit commands (e.g., color-temperature-adjustment commands) that do not include an indication that the receiving load control device should respond to the command independent of the present color control mode of the load control device (e.g., only those load control devices presently operating in the color-temperature-control mode will respond to the transmitted command).

If the color temperature actuator is not being actuated at 722, the control circuit may determine if a full color actuator (e.g., the full-color-adjustment mode actuator 223) is being actuated at 732. When the full color actuator is being actuated at 732, the control circuit may enter a full-color-adjustment mode at 734 and illuminate only the full color icon at 736 (e.g., by not illuminating the intensity icon and the color temperature icon). In addition, the control circuit may illuminate the light bar to indicate a color (e.g., the present full color of the lighting load controlled by the load control devices associated with the remote control device as determined from a present x-chromaticity coordinate and a present y-chromaticity coordinate) at 738. For example, the control circuit of the control unit 210 may illuminate the entire length of the light bar 240 the present color (e.g., as set by the present x-chromaticity coordinate and the present y-chromaticity coordinate) at 738. At 740, the control circuit may clear an all-color-adjustment flag, before the procedure 700 ends at 750. When the control circuit is operating in the full-color-adjustment mode and the all-color-adjustment flag is not set, the control circuit may transmit commands (e.g., full-color-adjustment commands) that do not include an indication that the receiving load control device should respond to the command independent of the present color control mode of the load control device (e.g., only those load control devices presently operating in the full-color-control mode will respond to the transmitted command).

If the full color actuator is not being actuated at 732, the control circuit may determine if one of a plurality of scene actuators (e.g., the first scene actuator 224, the second scene actuator 225, or the third scene actuator 226) is being actuated at 740. When one of the scene actuators is being actuated at 740, the control circuit may determine the selected scene at 742 (e.g., which of the first scene actuator 224, the second scene actuator 225, and the third scene actuator 226 is being actuated). At 744, the control circuit may transmit a message including a scene command indicating the selected scene at 746, before the procedure 700 ends at 750. If one of the scene actuators is not being actuated at 740, the control circuit may determine if an undo actuator (e.g., the undo actuator 228) is being actuated at 746. When the undo actuator is being actuated at 746, the control circuit may transmit a message including an indication of the actuation of the undo actuator at 748, before the procedure 700 ends at 750. In some examples, the determinations of the actuator that is presently being actuated at 714, 722, 732, 740, 746 may be executed in a different order.

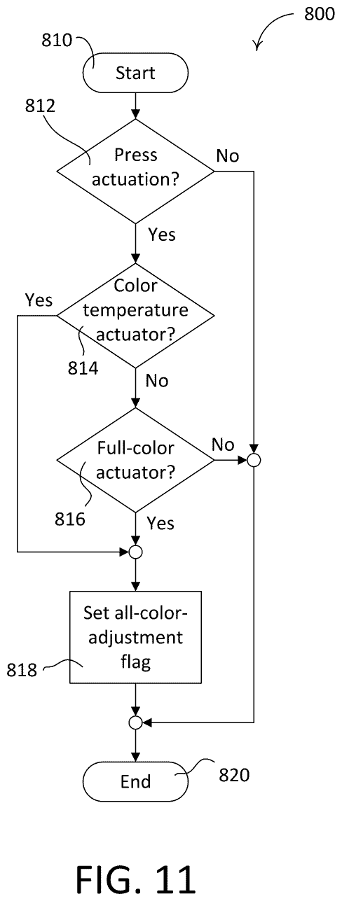

FIG. 11 is a flowchart of an example procedure 800 for receiving an input (e.g., a press actuation) of a touch sensitive surface of a control device (e.g., such as the input control devices of FIG. 1, the remote control device 200 of FIGS. 2-3, and/or the remote control device 500 of FIG. 8). The control device may comprise a touch sensitive circuit (e.g., the touch sensitive circuit 512) for receiving the input from the touch sensitive surface (e.g., the user interface surface 220). The control device may also comprise a light bar (e.g., the light bar 240). The control procedure 800 may be executed by a control circuit of the control device (e.g., a control circuit of one of the input control devices of FIG. 1, a control circuit of the remote control device 200 of FIG. 2-3, and/or the control circuit 510 of the control device 500 of FIG. 8). The control circuit may execute the control procedure 800 to process a press actuation received by the touch sensitive surface. For example, the control circuit may be configured to detect the press actuation by detecting a press-and-hold actuation of one of the actuators on the touch sensitive surface and/or by detecting an actuation (e.g., a tactile actuation) of the touch sensitive surface that causes the touch sensitive surface to move (e.g., pivot and/or be depressed towards the base 212). The control circuit may execute the control procedure 800 at 810 periodically, and/or in response to detecting a press actuation of the touch sensitive surface. Prior to execution of the control procedure 800 and/or in response to the execution of the control procedure 800, the control circuit may be configured to identify one or more actuators (e.g., virtual actuators, such as the actuators 221-228) by illuminating one or more icons on the touch sensitive surface, e.g., such as an intensity icon (e.g., the intensity-adjustment mode icon 231), a color temperature icon (e.g., the color-temperature-adjustment mode icon 232), a full color icon (the full-color-adjustment mode icon 233), one or more scene icons (e.g., the first scene icon 234, the second scene icon 235, and/or the third scene icon 236), and an undo icon (e.g., the undo icon 238). In addition, the control circuit may execute (e.g., always execute) the procedure 800 to detect a press actuation after executing the procedure 700 to detect a touch actuation of the touch sensitive surface (e.g., since the touch actuation of the touch sensitive surface will occur before the press actuation occurs).

At 812, the control circuit may determine if a press actuation has occurred on the touch sensitive surface. If not, the control procedure 800 may end at 820. If a press actuation has occurred at 812, the control circuit may determine if a color temperature actuator (e.g., the color-temperature-adjustment mode actuator 222) has been actuated at 814. When the control circuit detects a press actuation of the color temperature actuator at 814, the control circuit may set an all-color-adjustment flag at 818, before the procedure 800 ends at 820. When the control circuit is operating in the color-temperature-adjustment mode and the all-color-adjustment flag is set, the control circuit may transmit commands (e.g., color-temperature-adjustment commands) that include an indication that the receiving load control device should respond to the command independent of the present color control mode of the load control device (e.g., all load control devices-even those presently operating in the full-color-control mode-will respond to the transmitted command).

If the color temperature actuator is not being actuated at 814, the control circuit may determine if a full color actuator (e.g., the full-color-adjustment mode actuator 223) is being actuated at 816. When the control circuit detects a press actuation of the full color actuator at 816, the control circuit may set the all-color-adjustment flag at 818, before the procedure 800 ends at 820. When the control circuit is operating in the full-color-adjustment mode and the all-color-adjustment flag is set, the control circuit may transmit commands (e.g., full-color-adjustment commands) that include an indication that the receiving load control device should respond to the command independent of the present color control mode of the load control device (e.g., all load control devices—even those presently operating in the color-temperature-control mode—will respond to the transmitted command).

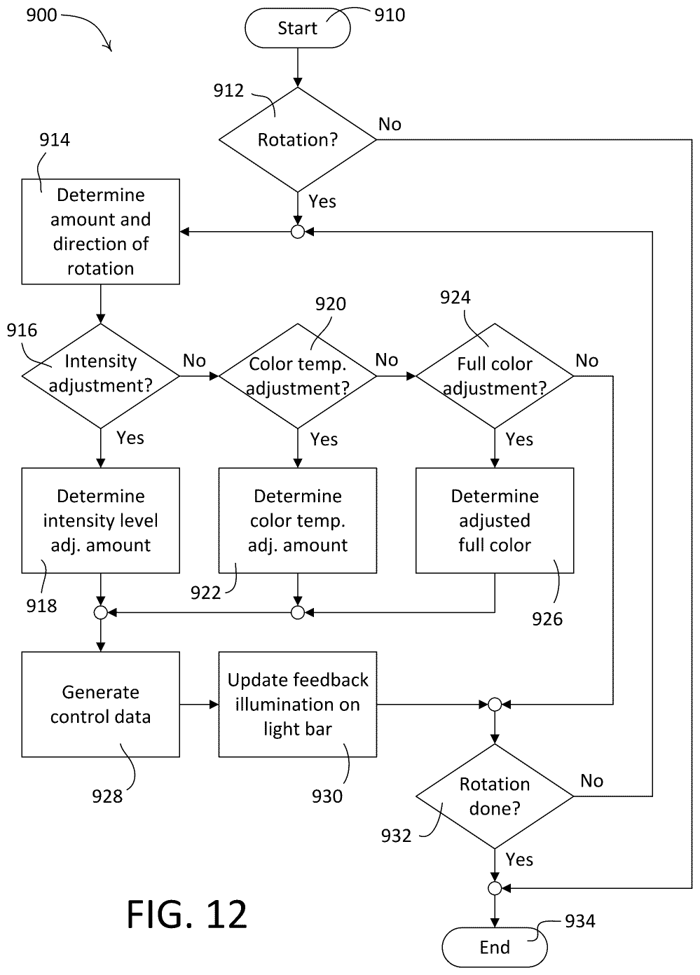

FIG. 12 is a flowchart of an example procedure 900 for receiving an input from a rotatable member (e.g., a rotary knob) of a control device (e.g., such as the input control devices of FIG. 1, the remote control device 200 of FIGS. 2-3 and/or the remote control device 500 of FIG. 8). The control device may comprise a rotational sensing circuit (e.g., rotational sensing circuit 515) for receiving the input from the rotatable member (e.g., the rotatable member 230). The control device may also comprise a light bar (e.g., the light bar 240). The control procedure 900 may be executed by a control circuit of the control device (e.g., a control circuit of one of the input control devices of FIG. 1, a control circuit of the remote control device 200 of FIGS. 2-3, and/or the control circuit 510 of the control device 500 of FIG. 8). For example, the control circuit may execute the control procedure 900 to process rotations of the rotatable member. The control circuit may execute the control procedure 900 at 910 periodically, and/or in response to detecting a rotation of the rotatable member.

At 912, the control circuit may determine if a rotation of the rotatable member of the touch sensitive surface is presently occurring. If not, the control procedure 900 may end at 934. If a rotation of the rotatable member is presently occurring at 912, the control circuit may determine a direction and/or an amount of rotation of the rotatable member at 914. For example, the control circuit may determine the amount of rotation since the start of the rotation of the rotatable member at 914. When the control circuit is operating in the intensity-adjustment mode at 916, the control circuit may be configured to determine an intensity-adjustment amount ΔL for controlling a present intensity level L_{PRES} of the one or more lighting loads at 918 based on the direction and/or the amount of rotation of the rotatable member determined at 914. When the control circuit is operating in the color-temperature-adjustment mode at 920, the control circuit may be configured to determine a color-temperature-adjustment amount ΔT for controlling a present color temperature T_{PRES} of the one or more lighting loads at 922 based on the direction and/or the amount of rotation of the rotatable member determined at 914. When the control circuit is operating in the full-color-adjustment mode at 924, the control circuit may be configured to determine an adjusted color (e.g., as defined by an adjusted x-chromaticity coordinate and an adjusted y-chromaticity coordinate) at 926 based on the direction and/or the amount of rotation of the rotatable member determined at 914.

At 928, the control circuit may generate control data for the adjustment amount determined at 918 or 922, or the adjusted color determined at 926. For example, when in the intensity-adjustment mode, the control circuit may at 928 generate an intensity-adjustment command including the intensity-adjustment amount ΔL as determined at 918. In addition, when in the color-temperature-adjustment mode, the control circuit may at 928 generate a color-temperature-adjustment command including the color-temperature-adjustment amount ΔT as determined at 922. Further, when in the full-color-adjustment mode, the control circuit may at 928 generate a full-color-adjustment command including the adjusted x-chromaticity coordinate and an adjusted y-chromaticity coordinate of the adjusted color as determined at 926. The control circuit may also transmit a message including the determined command (e.g., the intensity-adjustment command, the color-temperature-adjustment command, and/or the full-color-adjustment command) at 926.

At 930, the control circuit may update the indication of the present intensity level L_{PRES}, the present color temperature L_{PRES}, or the present color provided on the light bar. For example, when in the intensity-adjustment mode, the control unit 210 may adjust a length of an illuminated portion of the light bar 240 that starts at the bottom-center point 244 of the light bar 240 and extending around the light bar 240 in the clockwise direction to indicate the present intensity level L_{PRES} of the one or more lighting loads at 930. In addition, when in the color-temperature-adjustment mode, the control unit 210 may adjust a position of an illuminated segment on the light bar 240 around to the circumference of the light bar 240 to indicate the present color temperature T_{PRES} of the one or more lighting loads at 930. Further, when in the full-color-adjustment mode, the control unit 210 may adjust the color to which the light bar 240 is illuminated (e.g., as defined by the adjusted x-chromaticity coordinate and the adjusted y-chromaticity coordinate) at 930.

At 932, the control circuit may determine if the rotation of the rotatable member has stopped at 934. If the rotation of the rotatable member is still occurring (e.g., the rotation has not stopped) at 934, the control circuit may again determine the direction and/or the amount of rotation of the rotatable member at 914, generate the control data at 928, and update the illumination of the light bar at 930. For example, during subsequent determinations of the amount of rotation at 914 (e.g., after the first determination of the amount of rotation), the control circuit may be configured to determine the amount of rotation since the last determination of the direction at 914 and/or the amount of rotation and/or since the last generation of control data at 928. The control circuit may continue to transmit messages including commands (e.g., as determined at 928) while the rotation of the rotatable member continues. When the rotation of the rotatable member has stopped at 932, the procedure 900 may end at 934.

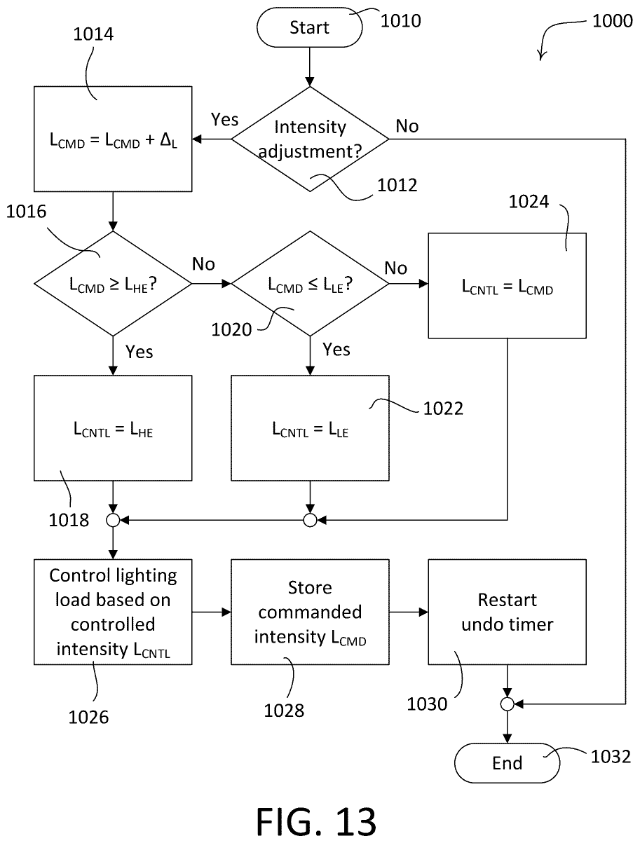

FIG. 13 is a flowchart of an example procedure 1000 for controlling a lighting load at a load control device (e.g., one of the load control devices of FIG. 1, such as the dimmer switch 110, the LED driver 120, and/or the controllable light source 130, and/or the load control device 600 of FIG. 9). The control procedure 1000 may be executed by a control circuit of the load control device (e.g., a control circuit of one of the load control devices of FIG. 1, and/or the device control circuit 640 of the load control device 600 of FIG. 9). For example, the control circuit may execute the control procedure 1000 to adjust a present intensity level L_{PRES} of the lighting load in response to a received message including an adjustment amount (e.g., a message comprising an intensity-adjustment command having an intensity-adjustment amount ΔL). During the procedure 1000, the control circuit may determine and maintain a commanded intensity level L_{CMD}, which may be an intensity level determined from the received message including the adjustment amount, and a controlled intensity level L_{CNTL}, which may be an intensity level to which the lighting load is controlled (e.g., is actually controlled). The control circuit may execute the control procedure 1000 at 1010 periodically and/or in response to receiving the message comprising an intensity-adjustment command having an intensity-adjustment amount ΔL.

At 1012, the control circuit may determine if a message including a command to adjust the present intensity level L_{PRES} (e.g., an intensity-adjustment command having an intensity-adjustment amount ΔL) has been received. If not, the control procedure 1000 may end at 1032. If a message including a command to adjust the present intensity level L_{PRES} has been received at 1012, the control circuit may determine the commanded intensity level L_{CMD} at 1014. For example, the control circuit may be configured to determine the commanded intensity level L_{CMD} at 1014 based on the intensity-adjustment amount ΔL and/or the present value of the commanded intensity level L_{CMD}). The intensity-adjustment amount ΔL may be, for example, positive to increase the present intensity level L_{PRES} of the lighting loads and negative to decrease the present intensity level L_{PRES} of the lighting load. For example, at 1014, the control circuit may be configured to calculate the commanded intensity level L_{CMD} by adding the intensity-adjustment amount ΔL to the present value of the commanded intensity level L_{CMD}, e.g., L_{CMD}=L_{CMD}+ΔL.

At 1016, the control circuit may be configured to determine whether the commanded intensity level L_{CMD} is greater than (e.g., greater than or equal to) a high-end intensity level L_{HE} (e.g., a maximum intensity level, such as approximately 100%). When the commanded intensity level L_{CMD} is greater than (e.g., greater than or equal to) the high-end intensity level L_{HE} at 1016, the control circuit may set the controlled intensity level L_{CNTL} to the high-end intensity level L_{HE} at 1018. When the commanded intensity level L_{CMD} is less than the high-end intensity level L_{HE} at 1016, the control circuit may be configured to determine at 1020 whether the commanded intensity level L_{CMD} is less than (e.g., less than or equal to) a low-end intensity level L_{HE} (e.g., a minimum intensity level, such as approximately 1%). When the commanded intensity level L_{CMD} is less than (e.g., less than or equal to) the low-end intensity level L_{LE} at 1020, the control circuit may set the controlled intensity level L_{CNTL} to the low-end intensity level L_{LE} at 1022. When the commanded intensity level L_{CMD} is greater than the low-end intensity level L_{LE} at 1020 (e.g., the commanded intensity level L_{CMD} is not greater than or equal to the high-end intensity level L_{HE} at 1016 and is not less than or equal to the low-end intensity level L_{LE} at 1020), the control circuit may set the controlled intensity level L_{CNTL} to the commanded intensity level L_{CMD} at 1024.

At 1026, the control circuit may be configured to control the present intensity level L_{PRES} of the lighting load based on the controlled intensity level L_{CNTL}. At 1028, the control circuit may be configured to store in memory (e.g., such as the memory 520) the controlled intensity level L_{CNTL} (e.g., for use when determining the commanded intensity level L_{CMD} at 1014 during a subsequent execution of the procedure 1000). At 1030, the control circuit may be configured to restart an undo timer, before the procedure 1000 ends at 1032. For example, the control circuit may set the undo timer to a maximum undo timer value (e.g., approximately three minutes) and start the undo timer counting down with respect to time at 1030. When the undo timer expires, the control circuit may be configured to set a previous intensity level L_{PREV} to the presently-stored commanded intensity level L_{CMD} (e.g., as stored at 1028). The control circuit may be configured to reset the undo timer whenever the control circuit adjusts the commanded intensity level L_{CMD} at 1014. The control circuit may be configured to adjust the commanded intensity level L_{CMD} to the previous intensity level LP_{REV} in response to receiving a message including an undo command (e.g., which may be transmitted by the control unit 210 of the remote control device 200 in response to detecting a touch actuation of the undo actuator 228). When the undo timer expires, the control circuit may be configured to set a stored intensity level L_{STRD} to the commanded intensity level L_{CMD} (e.g., as stored at 1026). The control circuit may be configured to reset the undo timer whenever the control circuit adjusts the commanded intensity level L_{CMD} at 1024. The control circuit may be configured to adjust the commanded intensity level LC_{MD} to the stored intensity level L_{STRD} in response to receiving a message including an undo command (e.g., which may be transmitted by the control unit 210 of the remote control device 200 in response to detecting a touch actuation of the undo actuator 228).

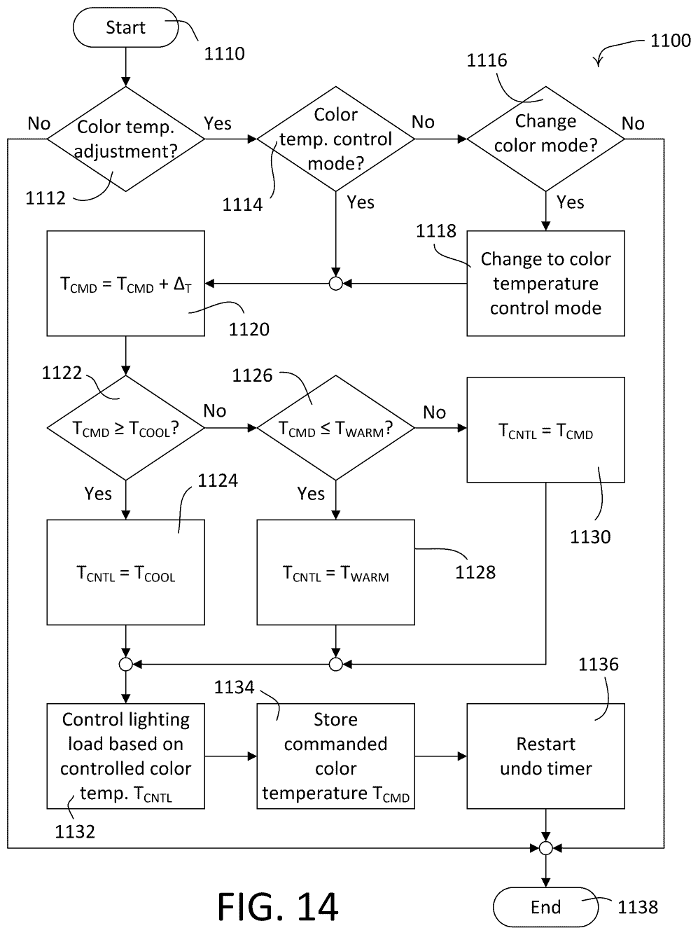

FIG. 14 is a flowchart of an example procedure 1100 for controlling a lighting load at a load control device (e.g., one of the load control devices of FIG. 1, such as the dimmer switch 110, the LED driver 120, and/or the controllable light source 130, and/or the load control device 600 of FIG. 9). The control procedure 1100 may be executed by a control circuit of the load control device (e.g., a control circuit of one of the load control devices of FIG. 1, and/or the device control circuit 640 of the load control device 600 of FIG. 9). For example, the control circuit may execute the control procedure 1100 to adjust a present color temperature T_{PRES} of the lighting load in response to a received message including an adjustment amount (e.g., a message comprising a color-temperature-adjustment command having a color-temperature-adjustment amount ΔT). During the procedure 1100, the control circuit may determine and maintain a commanded color temperature T_{CMD}, which may be a color temperature determined from the received message including the adjustment amount, and a controlled color temperature T_{CNTL}, which may be a color temperature to which the lighting load is controlled (e.g., is actually controlled). The control circuit may execute the control procedure 1100 at 1110 periodically and/or in response to receiving the message comprising a color-temperature-adjustment command having a color-temperature-adjustment amount ΔT.

At 1112, the control circuit may determine if a message including a command to adjust the present color temperature T_{PRES} (e.g., a color-temperature-adjustment command having a color-temperature-adjustment amount ΔT) has been received. If not, the control procedure 1100 may end at 1138. If a message including a command to adjust the present color temperature T_{PRES} has been received at 1112, the control circuit may determine if the control circuit is presently operating in the color-temperature-control mode at 1114. If not, the control circuit may determine if the message includes an indication to change color modes (e.g., to the color-temperature-control mode) at 1116. If the control circuit is not presently operating in the color-temperature-control mode at 1114 and the message does not include an indication to change color modes at 1116, the procedure 1100 may end at 1138. When the control circuit is not presently operating in the color-temperature-control mode at 1114 and the message includes an indication to change color modes at 1116, the control circuit may change to the color-temperature-control mode at 1118.

When the control circuit is presently operating in the color-temperature-control mode at 1114 or the message includes an indication to change color modes at 1116, the control circuit may determine the commanded color temperature T_{CMD} at 1120. For example, the control circuit may be configured to determine the commanded color temperature T_{CMD} at 1120 based on the color-temperature-adjustment amount ΔT and/or the present value of the commanded color temperature T_{CMD}. The color-temperature-adjustment amount ΔT may be, for example, positive to increase the present color temperature T_{PRES} of the lighting loads and negative to decrease the present color temperature T_{PRES} of the lighting load. For example, at 1120, the control circuit may be configured to calculate the commanded color temperature T_{CMD} by adding the color-temperature-adjustment amount ΔT to the present value of the commanded color temperature T_{CMD}, e.g., T_{CMD}=T_{CMD}+ΔT.

At 1122, the control circuit may be configured to determine whether the commanded color temperature T_{CMD} is greater than (e.g., greater than or equal to) a cool-white color temperature T_{CW} (e.g., approximately 7000 K). When the commanded intensity level L_{CMD} is greater than (e.g., greater than or equal to) the cool-white color temperature T_{CW} at 1122, the control circuit may set the controlled color temperature T_{CNTL} to the cool-white color temperature T_{CW} at 1124. When the commanded color temperature T_{CMD} is less than the cool-white color temperature T_{CW} at 1122, the control circuit may be configured to determine at 1126 whether the commanded color temperature T_{CMD} is less than (e.g., less than or equal to) a warm-white color temperature T_{WW} (e.g., approximately 1500 K). When the commanded intensity level L_{CMD} is less than (e.g., less than or equal to) the warm-white color temperature T_{WW} at 1126, the control circuit may set the controlled color temperature T_{CNTL} to the warm-white color temperature T_{WW} at 1128. When the commanded color temperature T_{CMD} is greater than the warm-white color temperature T_{WW} at 1126 (e.g., the commanded color temperature T_{CMD} is not greater than or equal to the cool-white color temperature T_{CW} at 1122 and is not less than or equal to the warm-white color temperature T_{WW} at 1126), the control circuit may set the controlled color temperature T_{CNTL} to the commanded color temperature T_{CMD} at 1130.

At 1132, the control circuit may be configured to control the present color temperature T_{PRES} of the lighting load based on the controlled color temperature T_{CNTL}. At 1134, the control circuit may be configured to store in memory (e.g., such as the memory 646) the commanded color temperature T_{CMD} (e.g., for use when determining the commanded color temperature T_{CMD} at 1120 during a subsequent execution of the procedure 1100). At 1136, the control circuit may be configured to restart an undo timer, before the procedure 1100 ends at 1138. For example, the control circuit may set the undo timer to a maximum undo timer value (e.g., approximately three minutes) and start the undo timer counting down with respect to time at 1136. When the undo timer expires, the control circuit may be configured to set a stored color temperature T_{STRD} to the commanded color temperature T_{CMD} (e.g., as stored at 1134). The control circuit may be configured to reset the undo timer whenever the control circuit adjusts the commanded color temperature T_{CMD} at 1120. The control circuit may be configured to adjust the commanded color temperature T_{CMD} to the stored color temperature T_{STRD} in response to receiving a message including an undo command (e.g., which may be transmitted by the control unit 210 of the remote control device 200 in response to detecting a touch actuation of the undo actuator 228).

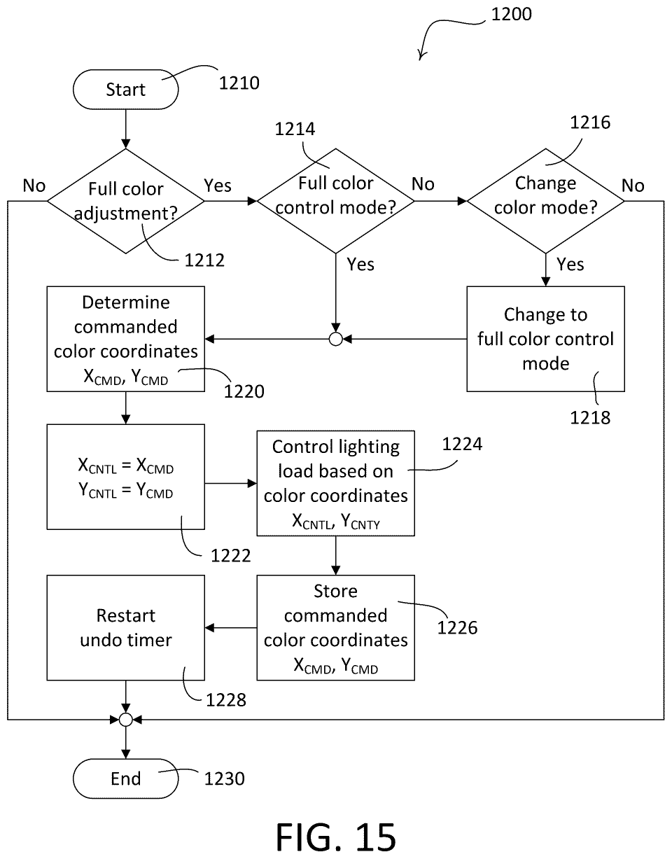

FIG. 15 is a flowchart of an example procedure 1200 for controlling a lighting load at a load control device (e.g., one of the load control devices of FIG. 1, such as the dimmer switch 110, the LED driver 120, and/or the controllable light source 130, and/or the load control device 600 of FIG. 9). The control procedure 1200 may be executed by a control circuit of the load control device (e.g., a control circuit of one of the load control devices of FIG. 1, and/or the device control circuit 640 of the load control device 600 of FIG. 9). For example, the control circuit may execute the control procedure 1200 to adjust a present color (e.g., full color as defined by a present x-chromaticity coordinate and present y-chromaticity coordinate) of the lighting load in response to a received message including an adjustment amount (e.g., a message comprising a full-color-adjustment command having an adjusted x-chromaticity coordinate and an adjusted y-chromaticity coordinate). The control circuit may execute the control procedure 1200 at 1210 periodically and/or in response to receiving the message comprising a full-color-adjustment command having an adjusted x-chromaticity coordinate and an adjusted y-chromaticity coordinate.

At 1212, the control circuit may determine if a message including a command to adjust the present color (e.g., a full-color-adjustment command having an adjusted x-chromaticity coordinate and an adjusted y-chromaticity coordinate) has been received. If not, the control procedure 1200 may end at 1230. If a message including a command to adjust the present color has been received at 1212, the control circuit may determine if the control circuit is presently operating in the full-color-control mode at 1214. If not, the control circuit may determine if the message includes an indication to change color modes (e.g., to the full-color-control mode) at 1216. If the control circuit is not presently operating in the full-color-control mode at 1214 and the message does not include an indication to change color modes at 1216, the procedure 1200 may end at 1230. When the control circuit is presently operating in the full-color-control mode at 1214 or the message includes an indication to change color modes at 1216, the control circuit may determine the commanded x-chromaticity coordinate X_{CMD} and the commanded y-chromaticity coordinate Y_{CMD} at 1220. For example, the control circuit may be configured to determine (e.g., retrieve) the commanded x-chromaticity coordinate X_{CMD} and the commanded y-chromaticity coordinate Y_{CMD} from the received message at 1120 (e.g., the received message may include the commanded x-chromaticity coordinate X_{CMD} and the commanded y-chromaticity coordinate Y_{CMD}). When the control circuit is not presently operating in the color-temperature-control mode at 1214 and the message includes an indication to change color modes at 1216, the control circuit may change to the full-color-control mode at 1218, and the control circuit may determine the commanded x-chromaticity coordinate X_{CMD} and the commanded y-chromaticity coordinate Y_{CMD} at 1220.

At 1222, the control circuit may be configured to set a controlled x-chromaticity coordinate X_{CNTL} equal to the commanded x-chromaticity coordinate X_{CMD} and a controlled y-chromaticity coordinate Y_{CNTL} equal to the commanded y-chromaticity coordinate Y_{CMD}. At 1224, the control circuit may be configured to control the present color of the lighting load based on the controlled x-chromaticity coordinate X_{CNTL} and the controlled y-chromaticity coordinate Y_{CNTL}. At 1226, the control circuit may be configured to store in memory (e.g., such as the memory 646) the commanded x-chromaticity coordinate X_{CMD} and the commanded y-chromaticity coordinate Y_{CMD}.

At 1228, the control circuit may be configured to restart an undo timer, before the procedure 1200 ends at 1230. For example, the control circuit may set the undo timer to a maximum undo timer value (e.g., approximately three minutes) and start the undo timer counting down with respect to time at 1228. When the undo timer expires, the control circuit may be configured to set a stored x-chromaticity coordinate X_{STRD} to the commanded x-chromaticity coordinate X_{CMD} (e.g., as stored at 1226) and set a stored y-chromaticity coordinate Y_{STRD} to the commanded y-chromaticity coordinate Y_{CMD} (e.g., as stored at 1226). For example, at 1226, the control circuit may store (e.g., temporarily store) the commanded x-chromaticity coordinate X_{CMD} and the commanded y-chromaticity coordinate Y_{CMD} in memory. Then, if the undo timer expires, the control circuit may store the commanded x-chromaticity coordinate X_{CMD} as the stored x-chromaticity coordinate X_{STRD} and store the commanded x-chromaticity coordinate Y_{CMD} as the stored y-chromaticity coordinate Y_{STRD}. Further, the control circuit may be configured to reset the undo timer whenever the control circuit adjusts the commanded x-chromaticity coordinate X_{CMD} and the commanded y-chromaticity coordinate Y_{CMD} at 1120. The control circuit may be configured to adjust the commanded x-chromaticity coordinate X_{CMD} and the commanded y-chromaticity coordinate Y_{CMD} to the stored x-chromaticity coordinate X_{STRD} and the stored y-chromaticity coordinate Y_{STRD}, respectively, in response to receiving a message including an undo command (e.g., which may be transmitted by the control unit 210 of the remote control device 200 in response to detecting a touch actuation of the undo actuator 228).

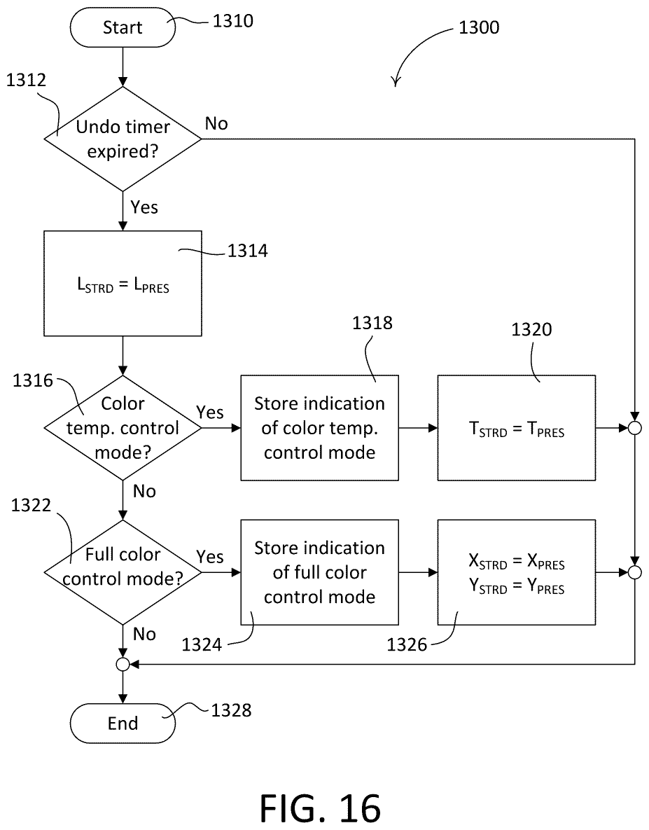

FIG. 16 is a flowchart of an example procedure 1300 for controlling a lighting load at a load control device (e.g., one of the load control devices of FIG. 1, such as the dimmer switch 110, the LED driver 120, and/or the controllable light source 130, and/or the load control device 600 of FIG. 9). The control procedure 1300 may be executed by a control circuit of the load control device (e.g., a control circuit of one of the load control devices of FIG. 1, and/or the device control circuit 640 of the load control device 600 of FIG. 9). The control circuit may be configured to adjust a present intensity level L_{PRES}, a present color temperature T_{PRES}, and/or a present color (e.g., as defined by a present x-chromaticity coordinate X_{PRES} and a present y-chromaticity coordinate Y_{PRES}) of the lighting load. The control circuit may execute the control procedure 1300 to restore the lighting load to a previous state. For example, the control circuit may be configured to store in memory (e.g., such as the memory 646) the previous state of the lighting load (e.g., a stored intensity level L_{STRD}, a stored color temperature T_{STRD}, and/or a stored color, for example, as defined by a stored x-chromaticity coordinate X_{STRD} and a stored y-chromaticity coordinate Y_{STRD}). The control circuit may be configured to run an undo timer to determine when an end of a predetermined undo timeout period T_{UNDO} since the last adjustment of the present intensity level L_{PRES}, the present color temperature T_{PRES}, and/or the present color has occurred. The control circuit may execute the control procedure 1300 at 1310 periodically and/or in response to receiving a message including an undo command.

At 1312, the control circuit may determine if the undo timer has expired. For example, whenever the control circuit adjusts the present intensity level L_{PRES}, the present color temperature T_{PRES}, and/or the present color of the lighting load, the control circuit may be configured to restart the undo timer, for example, by initializing the undo timer to a value corresponding to the predetermined undo timeout period T_{UNDO} and starting the undo timer counting down with respect to time (e.g., as at 1028 of the procedure 1000, at 1136 of the procedure 1100, and/or at 1228 of the procedure 1200). If the undo times has not expired (e.g., has not reached zero) at 1312, the procedure 1300 may end at 1328. When the undo timer has expired (e.g., has reached zero) at 1312, the control circuit may set the stored intensity level L_{STRD} equal to the present intensity level L_{PRES} at 1314. For example, the control circuit may store the present intensity level L_{PRES} in memory as the stored intensity level L_{STRD} at 1314, such that the control circuit is able to control the lighting load to the stored intensity level L_{STRD} in response to subsequently receiving a message including an undo command.

At 1316, the control circuit may determine if the load control device is presently operating in the color-temperature-control mode. If so, the control circuit may store an indication of the color-temperature-control mode in memory at 1318, and set the stored color temperature T_{STRD} equal to the present color temperature T_{PRES} at 1320, before the procedure 1300 ends at 1328. For example, the control circuit may store the present color temperature T_{PRES} in memory as the stored color temperature T_{STRD} at 1320. In response to subsequently receiving a message including an undo command, the control circuit may be configured to operate in the color-temperature-control mode (e.g., as stored in memory at 1318) and control the lighting load to the stored color temperature T_{STRD} (e.g., as stored in memory at 1320).

If the load control device is not operating in the color-temperature-control mode at 1316, the control circuit may determine if the load control device is presently operating in the full-color-control mode at 1322. If not (e.g., if the load control device is not color control capable), the procedure 1300 may end at 1328. If the load control device is presently operating in the full-color-control mode at 1322, the control circuit may store an indication of the full-color-control mode in memory at 1324, and set the stored color equal to the present color at 1326 (e.g., by setting the stored x-chromaticity coordinate X_{STRD} and the stored y-chromaticity coordinate Y_{STRD} equal to the present x-chromaticity coordinate X_{PRES} and the present y-chromaticity coordinate Y_{PRES}, respectively), before the procedure 1300 ends at 1328. For example, the control circuit may store the present x-chromaticity coordinate X_{PRES} and the present y-chromaticity coordinate Y_{PRES} in memory as the stored x-chromaticity coordinate X_{STRD} and the stored y-chromaticity coordinate Y_{STRD}, respectively, at 1326. In response to subsequently receiving a message including an undo command, the control circuit may be configured to operate in the full-color-control mode (e.g., as stored in memory at 1324) and control the lighting load to the stored color (e.g., as stored in memory at 1326).

What is claimed is:

1. A remote control device for use in a load control system comprising one or more load control devices for controlling one or more respective lighting loads, the remote control device comprising:
a touch sensitive surface configured to received touch actuations by a user;
a rotatable member having a circular shape and surrounding the touch sensitive surface, wherein the rotatable member is configured to be rotated by the user; and
a control circuit responsive to the touch actuations of the touch sensitive surface and rotations of the rotatable member, the control circuit configured to operate in one of a plurality of adjustment modes in response to a touch actuation of the touch sensitive surface, the plurality of adjustment modes comprising an intensity-adjustment mode and a color-temperature-adjustment mode;
wherein the control circuit is configured to:
when operating in the intensity-adjustment mode, generate first control data for adjusting a present intensity level of each of the one or more lighting loads in response to rotations of the rotatable member; and
when operating in the color-temperature-adjustment mode, generate second control data for adjusting a present color temperature of each of the one or more lighting loads in response to rotations of the rotatable member.

2. The remote control device of claim 1, wherein the plurality of adjustment modes comprise a full-color-adjustment mode, and the control circuit is configured to, when operating in the full-color-adjustment mode, generate third control data for adjusting a present color of each of the one or more lighting loads.

3. The remote control device of claim 2, wherein one or more of the load control devices of the load control system are configured to operate in one of a plurality of color control modes, the color control modes comprising a color-temperature-control mode and a full-color-control mode; and
wherein the control circuit is configured to:
when operating in the intensity-adjustment mode, transmit a first command for adjusting the present intensity level of each of the one or more lighting loads in response to the generated first control data;
when operating in the color-temperature-adjustment mode, transmit a second command for adjusting the present color temperature of each of the one or more lighting loads in response to the generated second control data; and
where operating in the full-color-adjustment mode, transmit a third command for adjusting the present color of each of the one or more lighting loads in response to the generated third control data.

4. The remote control device of claim 3, wherein the control circuit is configured to:
detect a press actuation of the touch sensitive surface;
in response to detecting a press actuation of the touch sensitive surface to select the color-temperature-adjustment mode, enter the color-temperature-adjustment mode and transmit the second command for adjusting the present color temperature of each of the one or more lighting loads independent of the color control mode of each of the load control devices that receives the second command; and
in response to detecting a press actuation of the touch sensitive surface to select the full-color-adjustment mode, enter the full-color-adjustment mode and transmit the third command for adjusting the present color of each of the one or more lighting loads independent of the color control mode of each of the load control devices that receives the second command.

5. The remote control device of claim 4, wherein the control circuit is configured to:
in response to detecting a press actuation of the touch sensitive surface to select the color-temperature-adjustment mode, transmit the second command with an indication that the load control devices that receives the second command should change to the color-temperature-control mode; and
in response to detecting a press actuation of the touch sensitive surface to select the full-color-adjustment mode, transmit the third command with an indication that the load control devices that receives the second command should change to the full-color-control mode.

6. The remote control device of claim 4, wherein the press actuation of the touch sensitive surface comprises a press-and-hold actuation of the touch sensitive surface.

7. The remote control device of claim 4, wherein the touch actuation of the touch sensitive surface comprises an actuation of the touch sensitive surface that does not cause the touch sensitive surface to move, and the press actuation of the touch sensitive surface comprises an actuation of the touch sensitive surface that causes the touch sensitive surface to move.

8. The remote control device of claim 3, wherein the control circuit is configured to:
in response to detecting a touch actuation of the touch sensitive surface to select the color-temperature-adjustment mode, enter the color-temperature-adjustment mode and transmit the second command for adjusting the present color temperature of each of the one or more lighting loads when the color control mode of each of the load control devices is the color-temperature-control mode; and
in response to detecting a touch actuation of the touch sensitive surface to select the full-color-adjustment mode, enter the full-color-adjustment mode and transmit the third command for adjusting the present color of each of the one or more lighting loads in response to the generated control data independent of the color control mode of each of the load control devices that receives the second command.

9. The remote control device of claim 2, wherein the present color is defined by a present x-chromaticity coordinate and a present y-chromaticity coordinate.

10. The remote control device of claim 1, wherein the touch sensitive surface comprises one or more portions that operate as actuators for receiving the touch actuations using touch sensitive surface, the control circuit configured to operate in the intensity-adjustment mode in response to a touch actuation of a first one of the actuators on the touch sensitive surface and to operate in the color-temperature-adjustment mode in response to a touch actuation of a second one of the actuators on the touch sensitive surface.

11. The remote control device of claim 10, wherein the actuators on the touch sensitive surface comprise respective icons for indicating positions of the actuators on the touch sensitive surface.

12. The remote control device of claim 11, further comprising:
one or more light sources for illuminating respective ones of the icons on the touch sensitive surface.

13. The remote control device of claim 12, wherein, when each of the icons is not illuminated, the respective icons is configured to disappear.

14. The remote control device of claim 10, wherein the actuators of the touch sensitive surface comprise an undo actuator, and the control circuit is configured to generate third control data for causing the lighting load to revert to a previous state in response to an actuation of the undo actuator.

15. The remote control device of claim 14, further comprising:
a communication configured to transmit messages, the control circuit communicatively coupled to the control circuit;
wherein the control circuit is configured to transmit a third command for causing the lighting load to revert to the previous state in response to the generated third control data.

16. The remote control device of claim 14, further comprising:
a memory configured to store at least one of a stored intensity level or a stored color temperature;
wherein, in response to the generated third control data, the control circuit is configured to transmit a third command for adjusting the at least one of the intensity level or the color temperature of the lighting load to at least one of the stored intensity level or a stored color temperature, respectively.

17. The remote control device of claim 1, further comprising:
a light bar extending around the touch sensitive surface between the touch sensitive surface and the rotatable member;
wherein the control circuit is configured to illuminate the light bar to indicate at least one of the present intensity level or the present color temperature of the one or more lighting loads.

18. The remote control device of claim 17, wherein, when in the color-temperature-adjustment mode, the control circuit is configured to:
generate the second control data for adjusting the present color temperature of each of the one or more lighting loads across a range from a warm-white color temperature to a cool-white color temperature;
illuminate a segment of the light bar to indicate the present color temperature of the one or more lighting loads; and
adjust a position of the segment around a circumference of the light bar based on the present color temperature within the range from the warm-white color temperature to the cool-white color temperature.

19. The remote control device of claim 18, wherein, when in the color-temperature-adjustment mode, the control circuit is configured to:
illuminate the light bar to a gradient of colors starting at a point on the light bar and ending at the point on the light bar, the gradient of colors starting at a first color and ending at a second color to represent the range of color temperatures between the warm-white color temperature and the cool-white color temperature; and
illuminate the segment of the light bar a third color overtop of the gradient of colors to indicate the present color temperature of the one or more lighting loads.

20. The remote control device of claim 19, wherein the first color comprises a red color, the second color comprises a blue color, and the third color comprises a white color.

21. The remote control device of claim 19, wherein, when in the intensity-adjustment mode, the control circuit is configured to illuminate a portion of the light bar that starts at the point on the light bar extends for a length around the circumference of the light bar in a clockwise direction, where the length of the illuminated portion indicates the present intensity level of the one or more lighting loads.

22. The remote control device of claim 17, further comprising:
a plurality of light sources surrounding a perimeter of the touch sensitive surface for illuminating the light bar.

23. The remote control device of claim 1, further comprising:
a communication configured to transmit messages, the control circuit communicatively coupled to the control circuit;
wherein the control circuit is configured to:
when operating in the intensity-adjustment mode, transmit a first command for adjusting the present intensity level of each of the one or more lighting loads in response to the generated control data; and
when operating in the color-temperature-adjustment mode, transmit a second command for adjusting the present color temperature of each of the one or more lighting loads in response to the generated control data.

24. The remote control device of claim 1, wherein the lighting load is configured be controlled between a low-end intensity level and a high-end intensity level, and the control circuit is configured to generate the first control data for controlling at least one of the one or more lighting loads by:
determine a commanded intensity level in response to the rotations of the rotatable member;
determine a controlled intensity level that is based on the commanded intensity level and is limited by the low-end intensity level and the high-end intensity level; and
transmit a command including a command for adjusting the present intensity level of the least one of the load control devices the lighting load to the controlled intensity level.
